(19) United States
(12) Patent Application Publication
(10) Pub. No.: US 2026/0118763 A1
(43) Pub. Date: Apr. 30, 2026

(54) PREPARATION OF POLYMER, PREPARATION OF CHEMICALLY AMPLIFIED RESIST COMPOSITION, RESIST PATTERN FORMING PROCESS, POLYMER, AND CHEMICALLY AMPLIFIED RESIST COMPOSITION

(71) Applicant: Shin-Etsu Chemical Co., Ltd., Tokyo (JP)

(72) Inventors: Masayoshi Sagehashi, Joetsu-shi (JP); Shuhei Kobayashi, Joetsu-shi (JP); Yoshihiro Tsuji, Joetsu-shi (JP)

(73) Assignee: Shin-Etsu Chemical Co., Ltd., Tokyo (JP)

(21) Appl. No.: 19/482,458

(22) PCT Filed: May 13, 2025
(86) PCT No.: PCT/JP2025/017373

§ 371 Date: Nov. 7, 2025

(30) Foreign Application Priority Data
May 17, 2024 (WO) PCT/JP2024/018280

(51) Int. Cl. G03F 7/039; C08F 293/00; G03F 7/00; G03F 7/20

(52) U.S. Cl. CPC G03F 7/0397; C08F 293/005; C08F 2438/03; G03F 7/2004; G03F 7/70033

(57) ABSTRACT

A method for preparing a polymer is provided, the method comprising the steps of (1) polymerizing starting monomers including the predetermined monomers through living radical polymerization using a radical initiator and a RAFT agent, to form a polymer P-1 having a sulfur-containing end structure derived from the RAFT agent, (2) adding a radical generator and a thiol compound to the solution containing polymer P-1, and heating the solution to remove the end structure, and (3) mixing the polymer-containing solution with a poor solvent and allowing the polymer to precipitate for purification.

### TECHNICAL FIELD

This invention relates to a method for preparing a polymer, a method for preparing a chemically amplified resist composition, a resist pattern forming process, a polymer, and a chemically amplified resist composition.

### BACKGROUND ART

To meet the recent demand for higher integration density and operating speed of LSIs, the effort to reduce the pattern feature size is in rapid progress. As the advanced miniaturization technology, the manufacture of microelectronic devices is performed in a large scale by the ArF immersion lithography including the exposure step with a liquid, typically water held between the projection lens and the substrate. Attempts are made to apply multi-patterning of ArF lithography and lithography using EUV of wavelength 13.5 nm.

As the base polymer in chemically amplified resist compositions adapted for the EUV lithography, polymers comprising repeat units of vinyl phenols such as 4-hydroxystyrene are now the mainstream for the purpose of controlling the sensitivity and solubility of resist films. Polymers comprising acid-generator units are quite useful in the EUV lithography because the acid-generating units incorporated in polymer side chains are effective for suppressing acid diffusion and forming patterns at a high resolution. Several polymers for these resist compositions are proposed, for example, in Patent Documents 1 to 4.

The main method for preparing polymers as the base polymer for the EUV lithography resist compositions is random polymerization using radical initiators as commonly used in the preparation of base polymers for ArF lithography resist compositions. For the random polymerization, a dropwise addition polymerization method including furnishing a radical initiator and a monomer as a single solution or independent solutions, and adding dropwise to the heated solution is most favorably chosen. The preparation method with high precision covering from the step of polymerization reaction to the step of obtaining a polymer solution in high purity has been established. See Patent Document 5.

To comply with the recent advance of the EUV lithography, the requirements on resist materials with better properties including resolution, roughness, and etching selectivity between exposed and unexposed regions become more strict. For satisfying these required properties, it is demanded to prepare a polymer having a lower molecular weight and a narrower dispersity. It is then possible to form a pattern from a resist composition containing a homogeneous base polymer with little variation. As to the base polymer comprising acid-generating units which have been acknowledged to be useful in the EUV lithography, it is expected that further improvements in resist properties are achieved using the polymer having a uniform molecular weight and narrow dispersity.

The method for obtaining polymers with a narrow dispersity is generally divided into two approaches. One purifying method includes, after a polymer product is obtained from random polymerization, the step of removing a polymer fraction having a low degree of polymerization and unreacted monomers from the polymer product by re-precipitation. The other method includes the step of controlling the degree of polymerization during polymerization reaction uniform for obtaining a polymer with a narrow dispersity.

The purifying method of removing a polymer fraction having a low degree of polymerization and unreacted monomers from the polymer product obtained from random polymerization, by re-precipitation or liquid-liquid fractionation is most often used. As to the base polymer comprising acid-generating units which have been acknowledged to be useful in the EUV lithography, the acid-generating monomer is generally less soluble in solvents because of its salt structure consisting of an organic acid anion and an organic cation. It is then quite difficult to remove a polymer fraction having a low degree of polymerization and unreacted acid-generator monomer. The achievement of a narrow dispersity by enhancement of the purifying step encounters a certain limit.

With respect to the other method including the reaction step of obtaining a polymer with a narrow dispersity as the base polymer for resist compositions, a method utilizing living radical polymerization, especially using a reversible addition-fragmentation chain transfer agent (referred to as RAFT agent, hereinafter) has been proposed (Patent Documents 6, 7 and 8).

These patent documents refer to narrowing the dispersity of a polymer as the base polymer for resist compositions and the removal of sulfur atoms at the dithioester end or trithiocarbonate end originating from the RAFT agent, created in the living radical polymerization step. However, some problems must be overcome before these methods can be used for the mass-scale manufacture of polymers for the base polymer.

One exemplary problem in the living radical polymerization using a prior art RAFT agent is discussed with reference to Example 4 of Patent Document 7. After the step of adding a thiol compound and removing sulfur-containing end groups originating from the RAFT agent, the polymer has an end conversion rate which is as low as 63%. In this situation, even when the polymer is purified by re-precipitation, the sulfur-containing end groups which are concerned about stability are left behind. There is a risk that coloring and decomposition occur with the lapse of time. Since the end removal rate exceeds 90% in none of Examples of Patent Document 7, the method is not regarded satisfactory. In Example 1 of Patent Document 8, a thermal radical generator is added in an amount which is 10 times greater than the amount of the RAFT agent used in the polymerization step, for the purpose of reducing thiocarbonylthio end groups originating from the RAFT agent. In none of Examples, sulfur-containing end groups are completely removed.

When a polymer suitable as the base polymer for the advanced EUV lithography is prepared, it is difficult to apply the prior art method. There remain some problems. Specifically, one problem is the concentration of the product of living radical polymerization using a RAFT agent. Referring to Example 4 of Patent Document 7 again, the solution of all monomers in a polymerization solvent, 1-methoxy-2-propanol at the start of polymerization is prepared to a concentration of 77% by weight. The concentration is about 60% by weight at the late stage of polymerization when all the initiator solution has been added. The reaction system remains in a very high concentration. It is presumed that the reaction system is set at a high concentration in order that the monomers be polymerized and consumed in a short time and a high efficiency within the bounds of possibility. The aforementioned units having an acid-generator structure of salt structure are less soluble in some of the solvents commonly used in polymerization. It is forecasted that even if a solvent in which the aforementioned units are highly soluble is chosen, trouble arises when a solution containing an acid-generating monomer in a high concentration of more than 60% by weight is prepared.

### PRIOR ART DOCUMENTS

### Patent Documents

Patent Document 1: JP-A 2011-070033
Patent Document 2: JP-A 2012-048075
Patent Document 3: WO 2013/111667
Patent Document 4: JP-A 2011-033839
Patent Document 5: JP-A 2020-070399
Patent Document 6: JP-A 2005-156725
Patent Document 7: WO 2019/189276
Patent Document 8: WO 2012/165473

### SUMMARY OF INVENTION

### Technical Problem

In the design of a base polymer for a resist composition which meets the demand for improvements in various properties toward high resolution, low roughness and high etching selectivity, it is supposed effective to narrow the dispersity of the polymer. With respect to the base polymer containing acid-generating units for resist use, the removal of the acid-generator monomer having a low solvent solubility and a polymer having a low degree of polymerization by purification encounters a certain limit. There has not been established a superior preparation method which is compatible with both the dispersity narrowing by living radical polymerization using a RAFT agent and appropriate removal of sulfur-containing end groups intended for stability with time.

An object of the invention, which has been made under the above-mentioned circumstances, is to provide a method for preparing a polymer comprising acid generator units by living radical polymerization using a RAFT agent, the polymer having a narrow dispersity because the amounts of remaining monomers are minimized and a high purity because sulfur-containing end groups originating from the RAFT agent are fully removed. Another object is to provide a method for preparing a chemically amplified resist composition comprising the polymer, and a resist pattern forming process using the chemically amplified resist composition.

### Solution to Problem

Making extensive investigations to attain the above object, the inventors have found that although living radical polymerization using a RAFT agent and subsequent terminal treatment as proposed in the prior art are insufficient, living radical polymerization can be performed in a high efficiency and sulfur-containing end groups originating from the RAFT agent can be readily removed in a high efficiency by carrying out steps (1) to (3) to be described below, and a high purity polymer is obtainable by subjecting the polymer from which the end groups have been removed to purification. Using a chemically amplified resist composition comprising the resulting polymer as a base polymer, there is obtained a resist pattern of satisfactory profile having improved lithography properties. The invention is predicated on this finding.

The invention provides a method for preparing a polymer, a method for preparing a chemically amplified resist composition, a resist pattern forming process, a polymer, and a chemically amplified resist composition, as defined below.
1. A method for preparing a polymer comprising repeat units (A) derived from a monomer (A) structured so as to generate an acid upon light exposure, represented by any one of the formulae (A1) to (A6), repeat units (B) derived from a monomer (B) having a phenolic hydroxy group, represented by the formula (B1), and repeat units (C) derived from a monomer (C) which is decomposed under the action of acid, the method comprising the steps of:
   (1) polymerizing starting monomers including monomer (A), monomer (B) and monomer (C) in a solution through living radical polymerization using a radical initiator and a reversible addition-fragmentation chain transfer agent (RAFT agent), to form a polymer P-1 having an end structure selected from structures having the formulae (X-1) and (X-2) derived from the RAFT agent at the end of the backbone,
   (2) adding a radical generator and a thiol compound to the solution containing polymer P-1, and heating the solution to remove the end structure from the backbone of polymer P-1 to form a polymer P, and
   (3) mixing the solution containing polymer P with a poor solvent and allowing polymer P to precipitate as solids for purification,

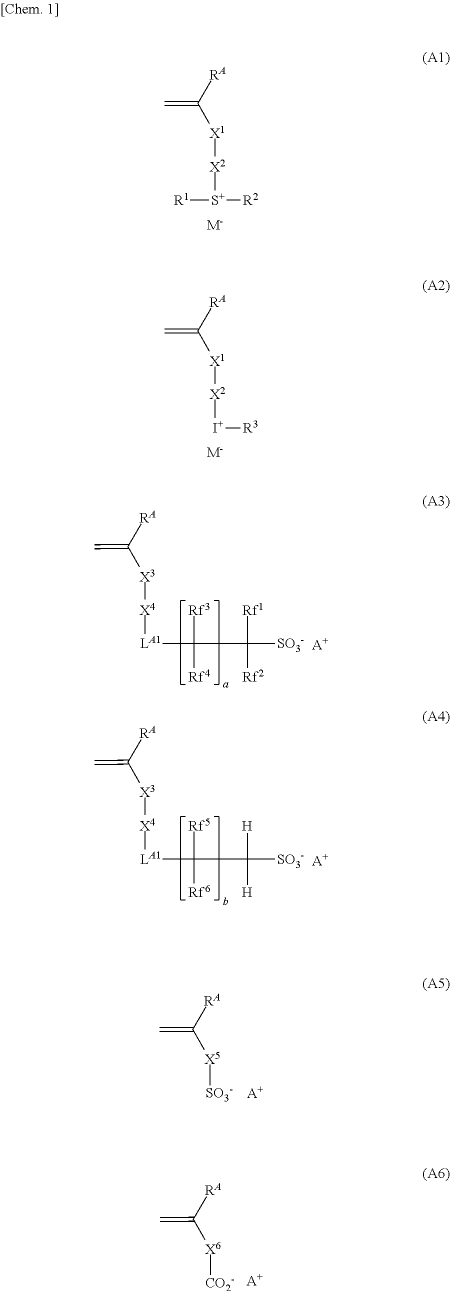

wherein R^{A} is each independently hydrogen, fluorine, methyl or trifluoromethyl,
   R¹, R² and R³ are each independently a C₁-C₂₀ hydrocarbyl group which may contain a heteroatom, R¹ and R² may bond together to form a ring with the sulfur atom to which they are attached,
   X¹ is each independently a single bond or phenylene group,
   X² is each independently *—C(═O)—O—X²¹—, *—C(═O)—NH—X²¹— or *—O—X²¹—, X²¹ is a C₁-C₆ aliphatic hydrocarbyl group, phenylene or a divalent group obtained by combining the foregoing, which may contain at least one moiety selected from carbonyl, ester bond, ether bond and hydroxy,
   X³ is each independently a single bond, a phenylene group which may be substituted with at least one moiety selected from halogen and a hydrocarbylcarbonyloxy moiety which may contain a heteroatom, a naphthylene group which may be substituted with at least one moiety selected from halogen and a hydrocarbylcarbonyloxy moiety which may contain a heteroatom, or *—C(═O)—O—X³¹—, X³¹ is a C₁-C₂₀ aliphatic hydrocarbylene group which may contain at least one moiety selected from hydroxy, ether bond, ester bond and lactone ring, an optionally halogenated phenylene group, or an optionally halogenated naphthylene group,
   X⁴ is each independently a single bond, —X⁴¹—C(═O)—O—, or —O—X⁴¹—O—C(═O)—, X⁴¹ is a C₁-C₂₀ aliphatic hydrocarbylene group which may contain a heteroatom, optionally halogenated phenylene group or optionally halogenated naphthylene group,
   X⁵ is a single bond, methylene group, ethylene group, optionally halogenated phenylene group, optionally halogenated naphthylene group, *—C(═O)—O—X⁵¹—, *—C(═O)—N(H)—X⁵¹— or *—O—X⁵¹—, X⁵¹ is a C₁-C₂₀ aliphatic hydrocarbylene group which may contain at least one moiety selected from carbonyl, ester bond, ether bond and hydroxy, optionally halogenated phenylene group or optionally halogenated naphthylene group, * designates a point of attachment to the carbon atom in the backbone,
   X⁶ is a single bond, methylene group, ethylene group, a phenylene group which may be substituted with at least one moiety selected from halogen and hydrocarbylcarbonyloxy moiety which may contain a heteroatom, a naphthylene group which may be substituted with at least one moiety selected from halogen and hydrocarbylcarbonyloxy moiety which may contain a heteroatom, *—C(═O)—O—X⁶¹—*—C(═O)—N(H)—X⁶¹— or *—O—X⁶¹—, X⁶¹ is a C₁-C₂₀ aliphatic hydrocarbylene group which may contain at least one moiety selected from carbonyl, ester bond, ether bond and hydroxy, optionally halogenated phenylene group or optionally halogenated naphthylene group, * designates a point of attachment to the carbon atom in the backbone,
   L^{A1} is each independently a single bond, ether bond, ester bond, carbonyl group, sulfonate ester bond, carbonate bond or carbamate bond,
   Rf¹ and Rf² are each independently fluorine or a C₁-C₆ fluorinated alkyl group, Rf³ and Rf⁴ are each independently hydrogen, fluorine or a C₁-C₆ fluorinated alkyl group,
   Rf⁵ and Rf⁶ are each independently hydrogen, fluorine or a C₁-C₆ fluorinated alkyl group, excluding that all Rf⁵ and Rf⁶ are hydrogen at the same time,
   M⁻ is each independently a non-nucleophilic counter ion,
   A⁺ is each independently an onium cation, and
   a and b are each independently 0, 1, 2 or 3.

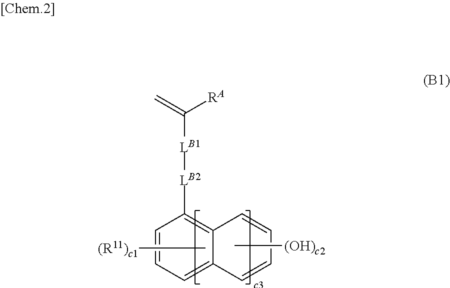

wherein R^{A} is hydrogen, fluorine, methyl or trifluoromethyl,
   R¹¹ is halogen or a C₁-C₆ saturated hydrocarbyl group which may contain at least one moiety selected from ether bond and carbonyl,
   L^{B1} is a single bond, cabonyloxy group or amide group,
   L^{B2} is a single bond or a C₁-C₇ alkanediyl group which may contain at least one moiety selected from ether bond and carbonyl,
   c1 is an integer meeting 0≤c1≤5+2(c3)−c2,
   c2 is 1, 2, 3, 4 or 5,
   c3 is 0, 1 or 2,

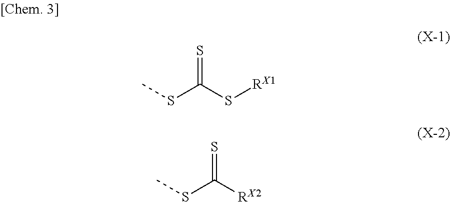

wherein R^{X1} and R^{X2} are each independently a C₂-C₂₀ saturated hydrocarbyl group which may contain a heteroatom, C₇-C₂₀ aralkyl group, or C₆-C₂₀ aryl group, the broken line designates a point of attachment to the carbon atom in the backbone.
2. The method of 1 wherein the amounts of monomer (A), monomer (B), and monomer (C) remaining in the polymer P-1 solution resulting from step (1) are less than 2% by weight, less than 1% by weight, and less than 2% by weight based on the total weight of the monomers charged, respectively.
3. The method of 1 or 2 wherein the thiol compound used in step (2) is a compound having the formula (SH-1) or (SH-2):

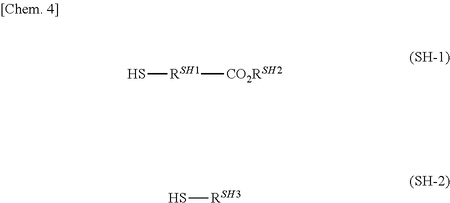

wherein R^{SH1} is a C₁-C₃ hydrocarbylene group,
   R^{SH2} is a C₄-C₈ aliphatic hydrocarbyl group which may contain a heteroatom, C₇-C₁₈ aralkyl group or C₆-C₁₈ aryl group, and
   R^{SH3} is a C₆-C₂₀ saturated hydrocarbyl group which may contain a heteroatom, C₇-C₁₈ aralkyl group or C₆-C₁₈ aryl group.
4. The method of any one of 1 to 3 wherein the amounts of monomer (A), monomer (B), and monomer (C) remaining in the polymer P-1 solution resulting from step (2) are less than 0.05% by weight, less than 0.01% by weight, and less than 0.05% by weight based on the total weight of the monomers charged.
5. The method of any one of 1 to 4 wherein the molar fractions of the structure having formula (X-1) and the structure having formula (X-2) in the polymer are each less than 1%.
6. The method of any one of 1 to 5 wherein in step (1), the living radical polymerization is carried out by mixing monomer (A), monomer (B), monomer (C), the radical initiator, and the RAFT agent into a single solution, and then heating the solution.
7. The method of any one of 1 to 5 wherein in step (1), the living radical polymerization is carried out by preparing monomer (A), monomer (B), monomer (C), and the radical initiator into a single solution or independent solutions, and then adding the solution or solutions to a preheated solution of the RAFT agent.
8. The method of any one of 1 to 7 wherein in step (1), the amount of the radical initiator charged is 0.5 to 5 moles and the amount of the RAFT agent charged is 0.5 to 20 moles per 100 moles of all the monomers charged.
9. A method for preparing a polymer solution comprising the steps of dissolving the polymer obtained from the method of any one of 1 to 8 in a solvent containing at least propylene glycol monomethyl ether acetate and filtrating the solution through a filter.
10. A method for preparing a chemically amplified resist composition comprising the step of dissolving in an organic solvent a raw material comprising a base polymer containing the polymer obtained from the method of any one of 1 to 8.
11. The method of 10 wherein the raw material further contains a quencher of onium salt type.
12. A pattern forming process comprising the steps of applying the chemically amplified resist composition obtained from the method of 10 or 11 onto a substrate to form a resist film thereon, exposing the resist film to high-energy radiation, and developing the exposed resist film in a developer.
13. The pattern forming process of 12 wherein the high-energy radiation is EUV of wavelength 3 to 15 nm or EB.
14. A polymer obtained from living radical polymerization using a reversible addition-fragmentation chain transfer agent (RAFT agent), wherein
   said polymer comprises repeat units (A) derived from a monomer (A) structured so as to generate an acid upon light exposure, represented by any one of the formulae (A1) to (A6), repeat units (B) derived from a monomer (B) having a phenolic hydroxy group, represented by the formula (B1), and repeat units (C) derived from a monomer (C) which is decomposed under the action of acid,
   at least 98% of the end structure in the polymer, selected from structures having the formulae (X-1) and (X-2) derived from the RAFT agent has been converted to hydrogen,
   the amount of monomer (A) remaining in the polymer is up to 0.05% by weight, the amount of monomer (B) remaining in the polymer is up to 0.01% by weight, and the amount of monomer (C) remaining in the polymer is up to 0.05% by weight,
   the polymer has a dispersity of up to 1.5,

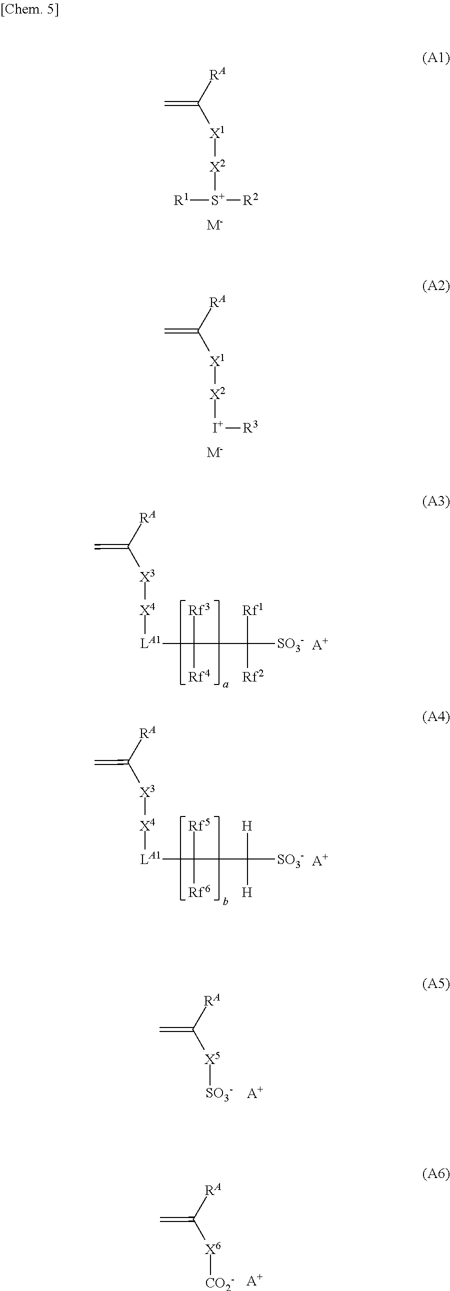

wherein R^{A} is each independently hydrogen, fluorine, methyl or trifluoromethyl,
   R¹, R² and R³ are each independently a C₁-C₂₀ hydrocarbyl group which may contain a heteroatom, R¹ and R² may bond together to form a ring with the sulfur atom to which they are attached,
   X¹ is each independently a single bond or phenylene group,
   X² is each independently *—C(═O)—O—X²¹—, *—C(═O)—NH—X²¹— or *—O—X²¹—, X²¹ is a C₁-C₆ aliphatic hydrocarbyl group, phenylene or a divalent group obtained by combining the foregoing, which may contain at least one moiety selected from carbonyl, ester bond, ether bond and hydroxy,
   X³ is each independently a single bond, a phenylene group which may be substituted with at least one moiety selected from halogen and a hydrocarbylcarbonyloxy moiety which may contain a heteroatom, a naphthylene group which may be substituted with at least one moiety selected from halogen and a hydrocarbylcarbonyloxy moiety which may contain a heteroatom, or *—C(═O)—O—X³¹—, X³¹ is a C₁-C₂₀ aliphatic hydrocarbylene group which may contain at least one moiety selected from hydroxy, ether bond, ester bond and lactone ring, an optionally halogenated phenylene group, or an optionally halogenated naphthylene group,
   X⁴ is each independently a single bond, —X⁴¹—C(═O)—O—, or —O—X⁴¹—O—C(═O)—, X⁴¹ is a C₁-C₂₀ aliphatic hydrocarbylene group which may contain a heteroatom, optionally halogenated phenylene group or optionally halogenated naphthylene group,
   X⁵ is a single bond, methylene group, ethylene group, optionally halogenated phenylene group, optionally halogenated naphthylene group, *—C(═O)—O—X⁵¹—, *—C(═O)—N(H)—X⁵¹— or *—O—X⁵¹—, X⁵¹ is a C₁-C₂₀ aliphatic hydrocarbylene group which may contain at least one moiety selected from carbonyl, ester bond, ether bond and hydroxy, optionally halogenated phenylene group or optionally halogenated naphthylene group, * designates a point of attachment to the carbon atom in the backbone,
   X⁶ is a single bond, methylene group, ethylene group, a phenylene group which may be substituted with at least one moiety selected from halogen and hydrocarbylcarbonyloxy moiety which may contain a heteroatom, a naphthylene group which may be substituted with at least one moiety selected from halogen and hydrocarbylcarbonyloxy moiety which may contain a heteroatom, *—C(═O)—O—X⁶¹—, *—C(═O)—N(H)—X⁶¹— or *—O—X⁶¹—X⁶¹ is a C₁-C₂₀ aliphatic hydrocarbylene group which may contain at least one moiety selected from carbonyl, ester bond, ether bond and hydroxy, optionally halogenated phenylene group or optionally halogenated naphthylene group, * designates a point of attachment to the carbon atom in the backbone,
   L^{A1} is each independently a single bond, ether bond, ester bond, carbonyl group, sulfonate ester bond, carbonate bond or carbamate bond,
   Rf¹ and Rf² are each independently fluorine or a C₁-C₆ fluorinated alkyl group, Rf³ and Rf⁴ are each independently hydrogen, fluorine or a C₁-C₆ fluorinated alkyl group,
   Rf⁵ and Rf⁶ are each independently hydrogen, fluorine or a C₁-C₆ fluorinated alkyl group, excluding that all Rf⁵ and Rf⁶ are hydrogen at the same time,
   M⁻ is each independently a non-nucleophilic counter ion,
   A⁺ is each independently an onium cation, and
   a and b are each independently 0, 1, 2 or 3.

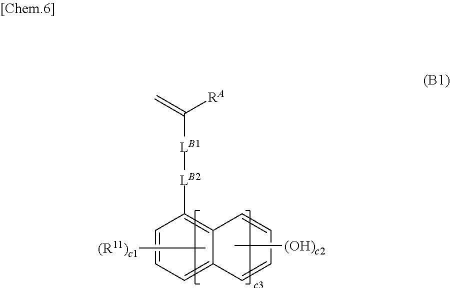

wherein R^{A} is hydrogen, fluorine, methyl or trifluoromethyl,
   R¹¹ is halogen or a C₁-C₆ saturated hydrocarbyl group which may contain at least one moiety selected from ether bond and carbonyl,
   L^{B1} is a single bond, cabonyloxy group or amide group,
   L^{B2} is a single bond or a C₁-C₇ alkanediyl group which may contain at least one moiety selected from ether bond and carbonyl,
   c1 is an integer meeting 0≤c1≤5+2(c3)−c2,
   c2 is 1, 2, 3, 4 or 5,
   c3 is 0, 1 or 2,

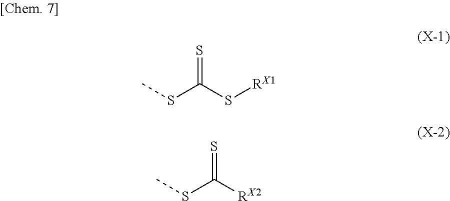

wherein R^{X1} and R^{X2} are each independently a C₂-C₂₀ saturated hydrocarbyl group which may contain a heteroatom, C₇-C₂₀ aralkyl group, or C₆-C₂₀ aryl group, the broken line designates a point of attachment to the carbon atom in the backbone.
15. A chemically amplified resist composition comprising a base polymer containing the polymer of 14.
16. The chemically amplified resist composition of 15, further comprising an onium salt type quencher.

### Advantageous Effects of Invention

By the inventive method, there is obtained a polymer containing minimal amounts of residual monomers, having a uniform molecular weight and dispersity, and suited for use in the EB or EUV lithography. It is expected that a resist composition comprising the polymer as a base polymer is improved in various properties such as high resolution, low roughness, and high etching selectivity.

### BRIEF DESCRIPTION OF DRAWINGS

FIG. 1 illustrates the results of HPLC analysis at the end of each step in Example 1-3.

### DESCRIPTION OF EMBODIMENTS

Now the invention is described in detail. It is understood that for some structures represented by chemical formulae, there can exist enantiomers and diastereomers. In such a case, a single formula collectively represents all such stereoisomers unless otherwise stated. The stereoisomers may be used alone or in admixture.

One embodiment of the invention is a method for preparing a polymer (referred to as polymer P, hereinafter) comprising repeat units (A) derived from a monomer (A) structured so as to generate an acid upon light exposure, repeat units (B) derived from a monomer (B) having a phenolic hydroxy group, and repeat units (C) derived from a monomer (C) which is decomposed under the action of acid, the method comprising the steps (1) to (3):
(1) polymerizing starting monomers including monomer (A), monomer (B) and monomer (C) in a solution through living radical polymerization using a radical initiator and a reversible addition-fragmentation chain transfer agent (RAFT agent), to form a polymer P-1 having an end structure selected from structures having the formulae (X-1) and (X-2) derived from the RAFT agent at the end of the backbone,
(2) adding a radical generator and a thiol compound to the solution containing polymer P-1, and heating the solution to remove the end structure from the backbone of polymer P-1 to form a polymer P, and
(3) mixing the solution containing polymer P with a poor solvent and allowing polymer P to precipitate as solids for purification,

The living radical polymerization using a radical initiator and a RAFT agent may be performed with reference to the methods of JP 3639859, JP-A 2006-002096, Patent Documents 6 and 7. Particularly for the purpose of obtaining a polymer comprising repeat units capable of generating an acid upon light exposure in a high efficiency and high purity, any of the aforementioned prior art methods has many outstanding problems as discussed above. It now becomes evident through the inventors' investigation that optimization of conditions in each of steps (1) to (3) and combination of these steps are quite effective. Below steps (1) to (3) are described in order.

### [Step (1)]

Step (1) is to polymerize starting monomers including monomer (A), monomer (B) and monomer (C) in a solution through living radical polymerization using a radical initiator and a RAFT agent, to form a polymer P-1 having an end structure selected from structures having the formulae (X-1) and (X-2) derived from the RAFT agent at the end of the backbone.

### <Monomers>

Monomer (A) has any one of the formulae (A1) to (A6).

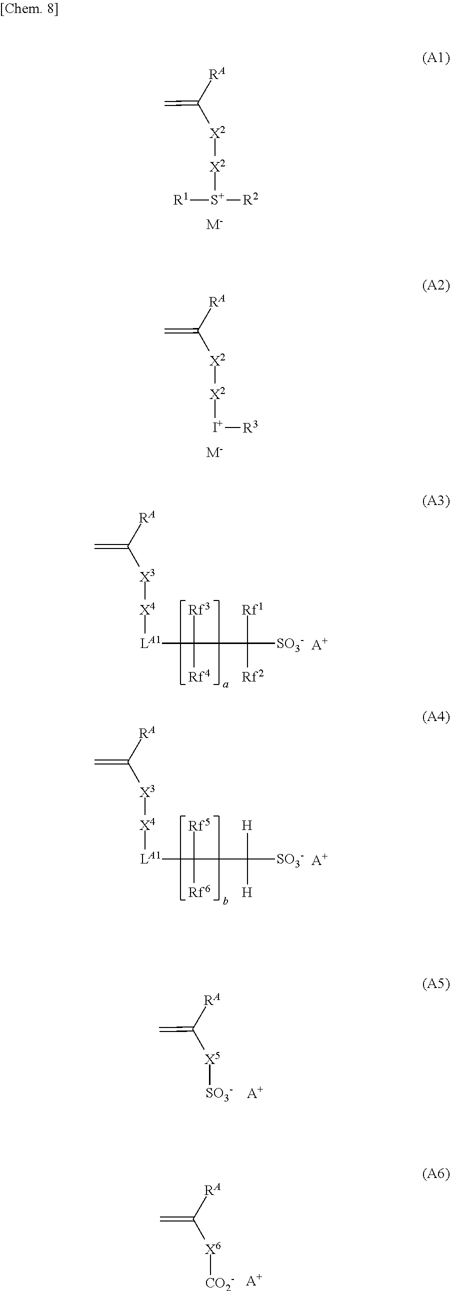

In formulae (A1) to (A6), R^{A} is each independently hydrogen, fluorine, methyl or trifluoromethyl.

In formulae (A1) and (A2), R¹, R² and R³ are each independently a C₁-C₂₀ hydrocarbyl group which may contain a heteroatom. The hydrocarbyl group may be straight, branched or cyclic. Examples thereof include C₁-C₂₀ alkyl groups such as methyl, ethyl, n-propyl, isopropyl, n-butyl, and tert-butyl; C₃-C₂₀ cyclic saturated hydrocarbyl groups such as cyclopropyl, cyclopentyl, cyclohexyl, cyclopropylmethyl, 4-methylcyclohexyl, cyclohexylmethyl, norbornyl, and adamantyl; C₂-C₂₀ alkenyl groups such as vinyl, allyl, propenyl, butenyl, and hexenyl; C₃-C₂₀ cyclic unsaturated hydrocarbyl groups such as cyclohexenyl; C₆-C₂₀ aryl groups such as phenyl, naphthyl and thienyl; C₇-C₂₀ aralkyl groups such as benzyl, 1-phenylethyl and 2-phenylethyl. Inter alia, aryl groups are preferred. In the hydrocarbyl group, some or all of the hydrogen atoms may be substituted by a moiety containing a heteroatom such as oxygen, sulfur, nitrogen or halogen and a moiety containing a heteroatom such as oxygen, sulfur or nitrogen may intervene between carbon atoms, so that the group may contain a hydroxy, fluorine, chlorine, bromine, iodine, cyano, carbonyl, ether bond, ester bond, sulfonate ester bond, carbonate bond, lactone ring, sultone ring, carboxylic anhydride (—C(═O)—O—C(═O)—), or haloalkyl moiety. R¹ and R² may bond together to form a ring with the sulfur atom to which they are attached.

In formulae (A1) and (A2), X¹ is each independently a single bond or phenylene group.

In formulae (A1) and (A2), X² is each independently *—C(═O)—O—X²¹—, *—C(═O)—NH—X²¹— or *—O—X²¹—. X²¹ is a C₁-C₆ aliphatic hydrocarbyl group, phenylene or a divalent group obtained by combining the foregoing, which may contain at least one moiety selected from carbonyl, ester bond, ether bond and hydroxy.

In formulae (A3) and (A4), X³ is each independently a single bond, a phenylene group which may be substituted with at least one moiety selected from halogen and a hydrocarbylcarbonyloxy moiety which may contain a heteroatom, a naphthylene group which may be substituted with at least one moiety selected from halogen and a hydrocarbylcarbonyloxy moiety which may contain a heteroatom, or *—C(═O)—O—X³¹—. X³¹ is a C₁-C₂₀ aliphatic hydrocarbylene group, an optionally halogenated phenylene group, or an optionally halogenated naphthylene group. The aliphatic hydrocarbylene group may contain at least one moiety selected from hydroxy, ether bond, ester bond and lactone ring. The asterisk (*) designates a point of attachment to the carbon atom in the backbone.

In formulae (A3) and (A4), X⁴ is each independently a single bond, —X⁴¹—C(═O)—O—, or —O—X⁴¹—O—C(═O)—. X⁴¹ is a C₁-C₂₀ aliphatic hydrocarbylene group which may contain a heteroatom, optionally halogenated phenylene group or optionally halogenated naphthylene group.

In formula (A5), X⁵ is a single bond, methylene group, ethylene group, optionally halogenated phenylene group, optionally halogenated naphthylene group, *—C(═O)—O—X⁵¹—, *—C(═O)—N(H)—X⁵¹— or *—O—X⁵¹—. X⁵¹ is a C₁-C₂₀ aliphatic hydrocarbylene group which may contain at least one moiety selected from carbonyl, ester bond, ether bond and hydroxy, optionally halogenated phenylene group or optionally halogenated naphthylene group, and * designates a point of attachment to the carbon atom in the backbone.

In formula (A6), X⁶ is a single bond, methylene group, ethylene group, a phenylene group which may be substituted with at least one moiety selected from halogen and hydrocarbylcarbonyloxy moiety which may contain a heteroatom, a naphthylene group which may be substituted with at least one moiety selected from halogen and hydrocarbylcarbonyloxy moiety which may contain a heteroatom, *—C(═O)—O—X⁶¹—, *—C(═O)—N(H)—X⁶¹— or *—O—X⁶¹. X⁶¹ is a C₁-C₂₀ aliphatic hydrocarbylene group which may contain at least one moiety selected from carbonyl, ester bond, ether bond and hydroxy, optionally halogenated phenylene group or optionally halogenated naphthylene group, and * designates a point of attachment to the carbon atom in the backbone.

In formulae (A3) and (A4), L^{A1} is each independently a single bond, ether bond, ester bond, carbonyl group, sulfonate ester bond, carbonate bond or carbamate bond.

In formulae (A3) and (A4), “a” and “b” are each independently 0, 1, 2 or 3, “a” is preferably 0 or 1, and “b” is preferably 1.

In formula (A3), Rf¹ and Rf² are each independently fluorine or a C₁-C₆ fluorinated alkyl group. Rf³ and Rf⁴ are each independently hydrogen, fluorine or a C₁-C₆ fluorinated alkyl group.

In formula (A4), Rf⁵ and Rf⁶ are each independently hydrogen, fluorine or a C₁-C₆ fluorinated alkyl group, excluding that all Rf⁵ and Rf⁶ are hydrogen at the same time.

Examples of the cation in the monomer having formula (A1) are shown below, but not limited thereto. Herein R^{A} is as defined above.

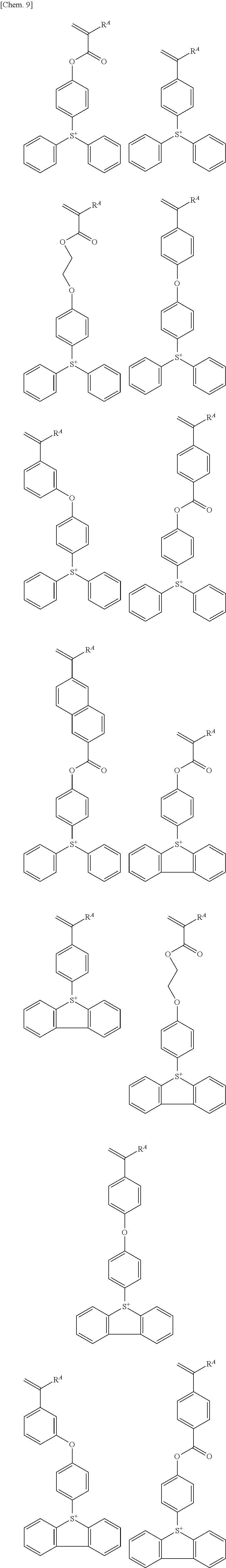

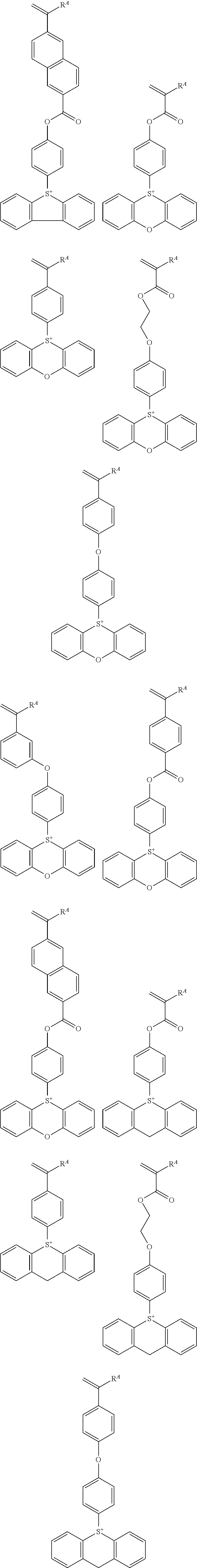

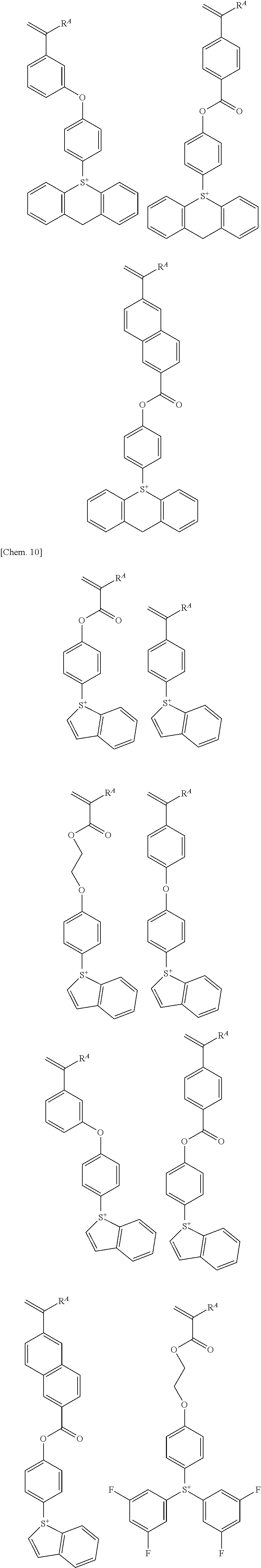

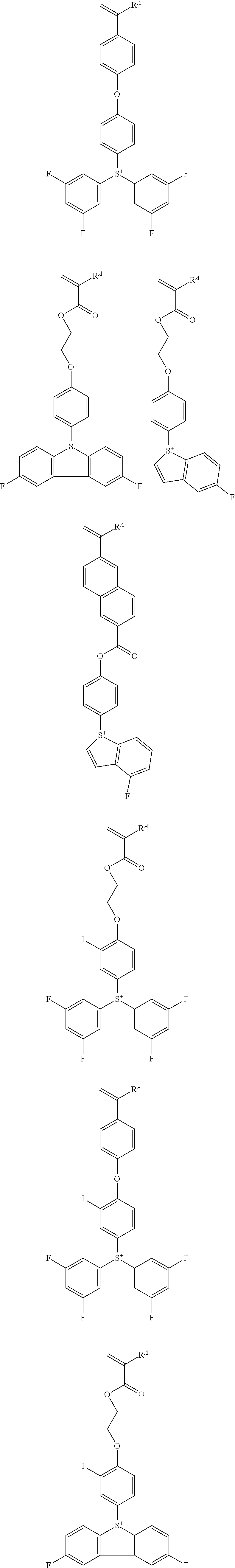

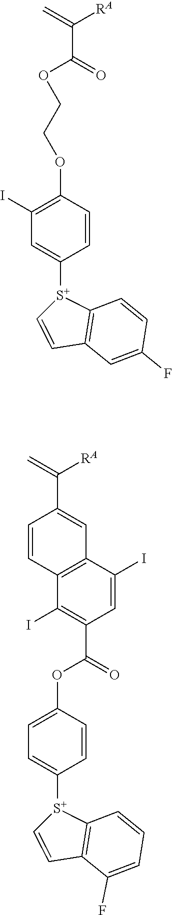

Examples of the cation in the monomer having formula (A2) are shown below, but not limited thereto. Herein R^{A} is as defined above.

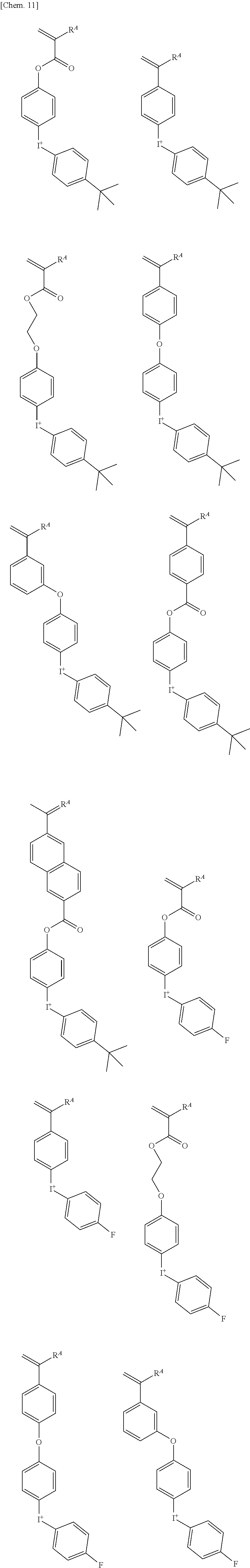

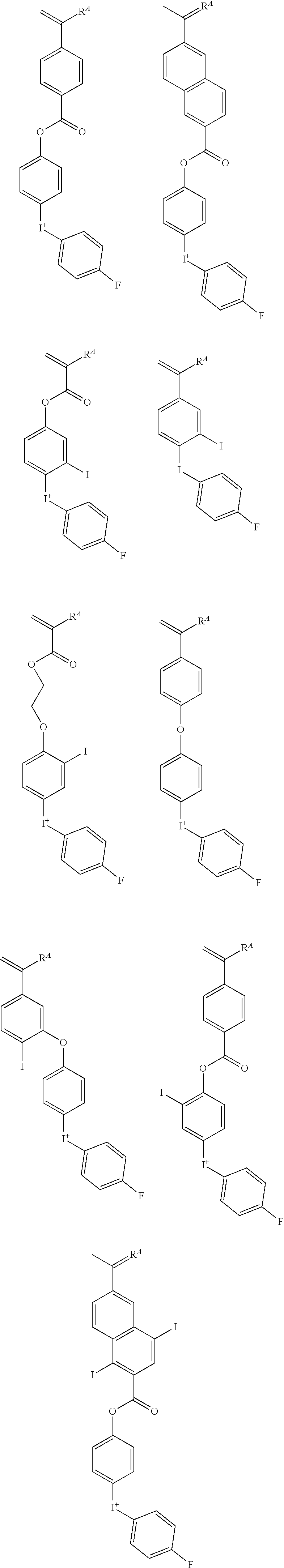

Examples of the anion in the monomer having formula (A3) are shown below, but not limited thereto. Herein R^{A} is as defined above.

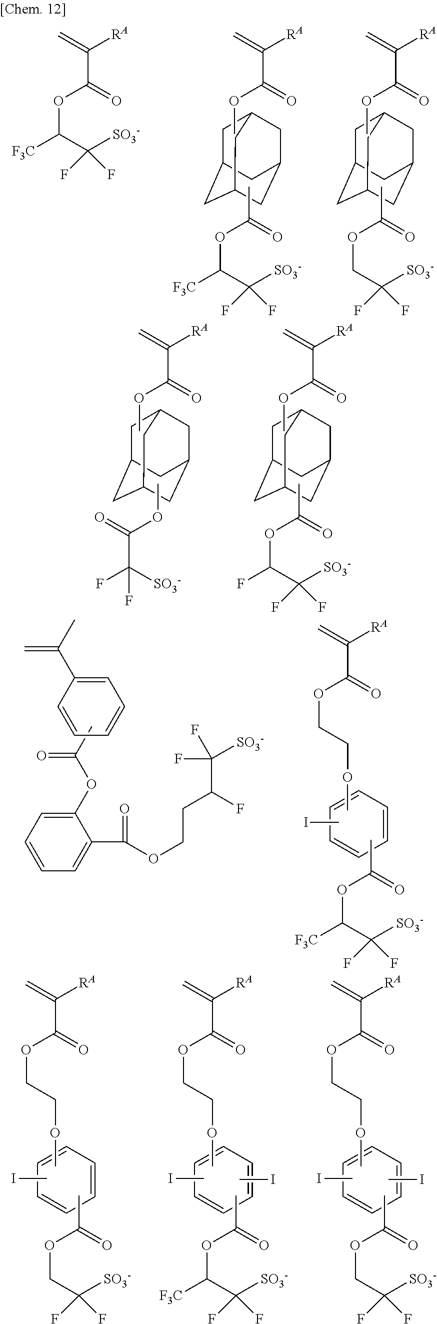

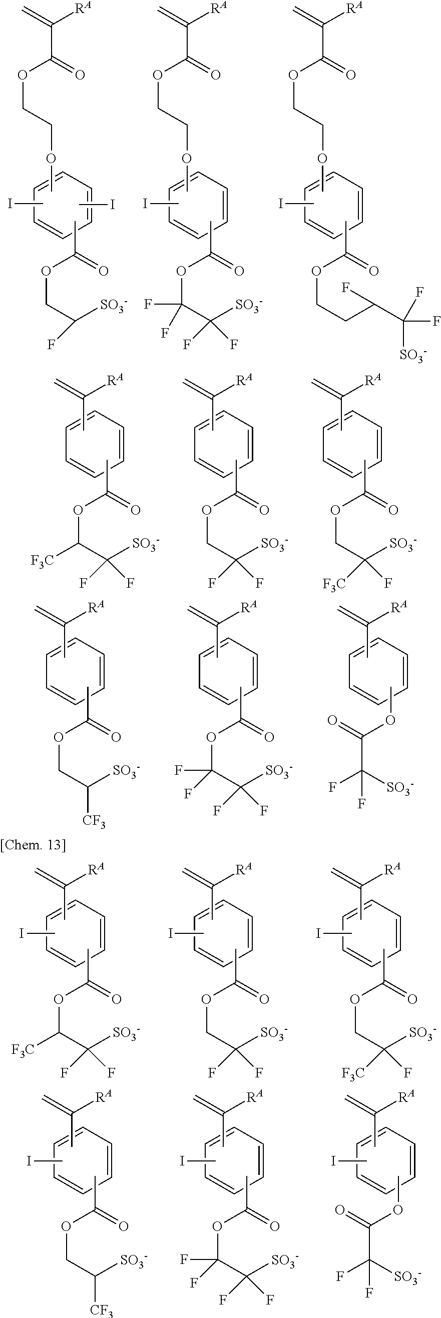

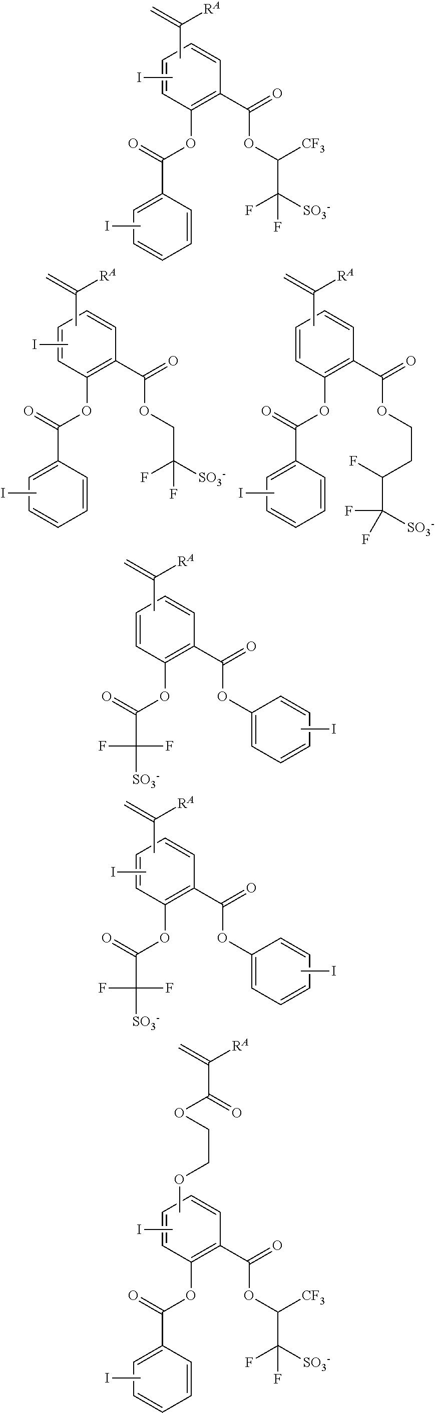

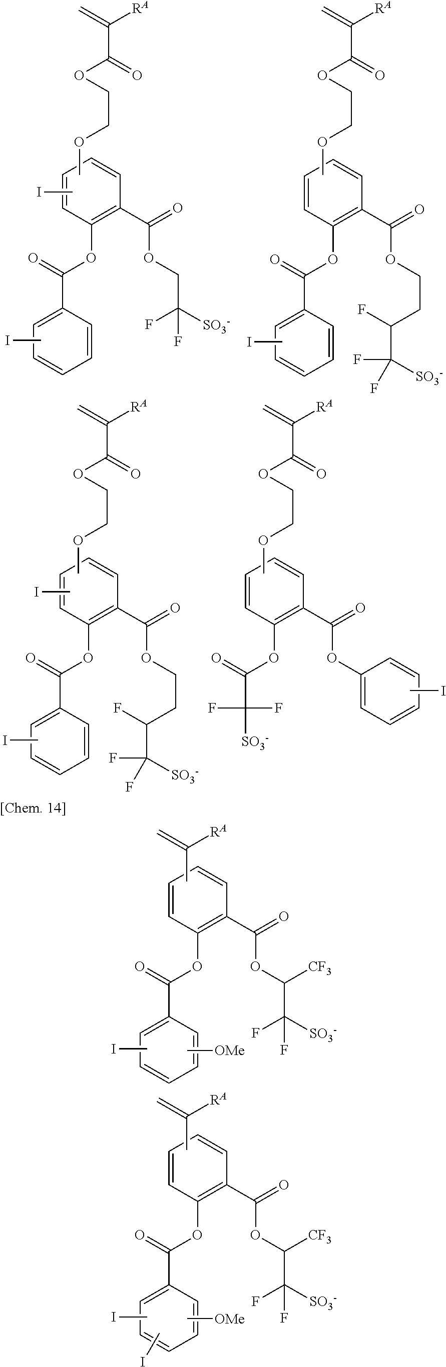

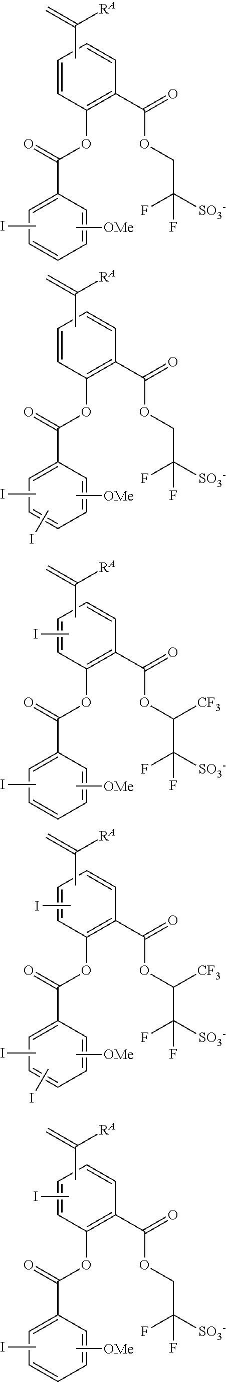

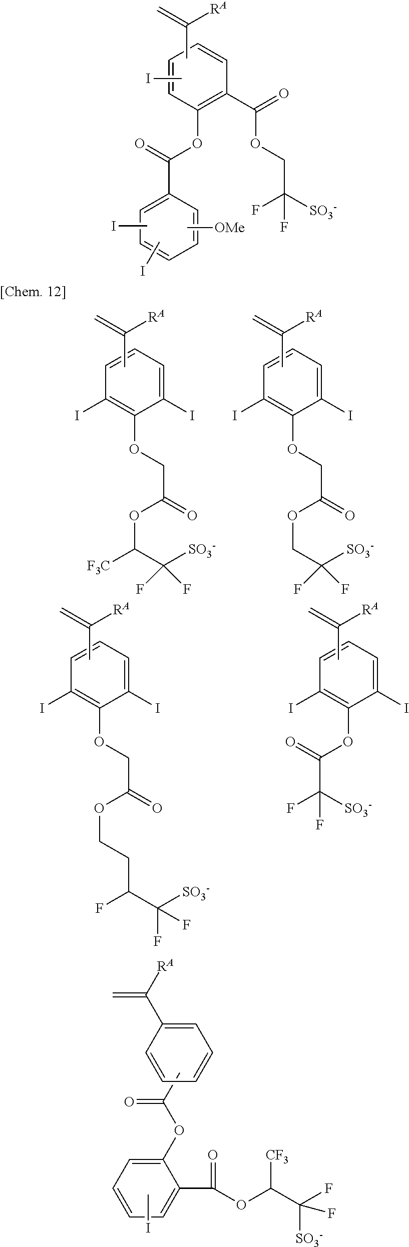

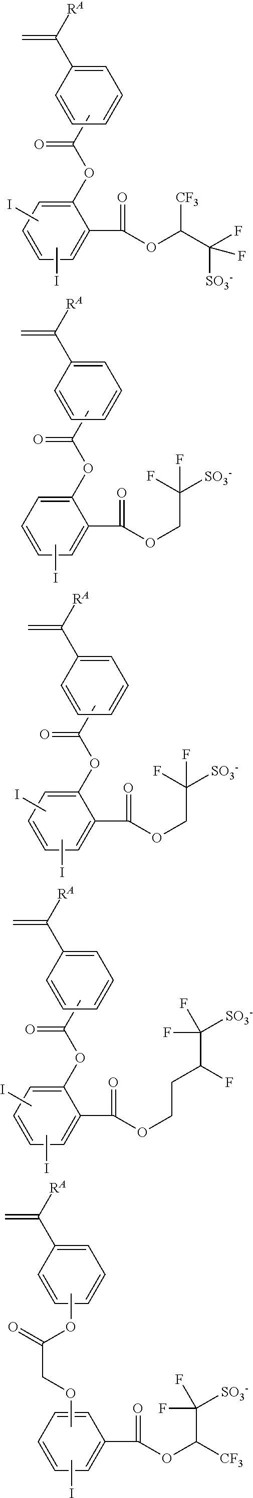

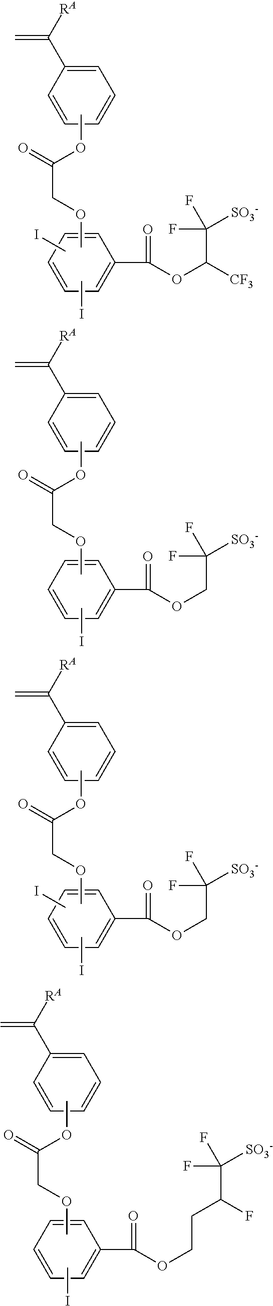

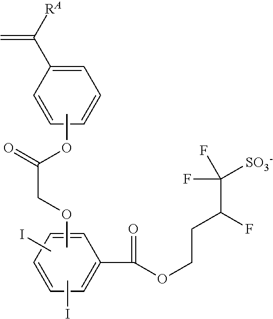

Examples of the anion in the monomer having formula (A4) are shown below, but not limited thereto. Herein R^{A} is as defined above.

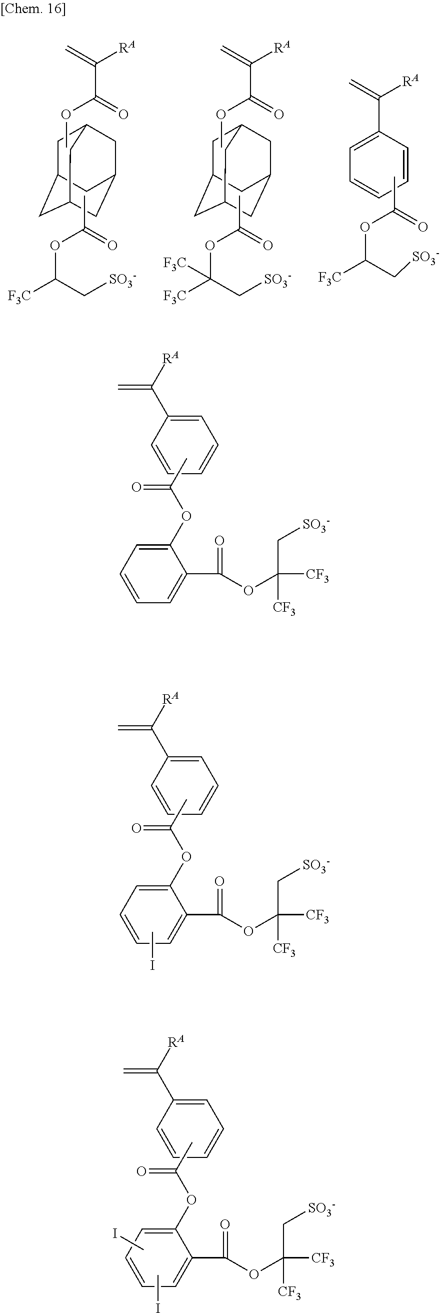

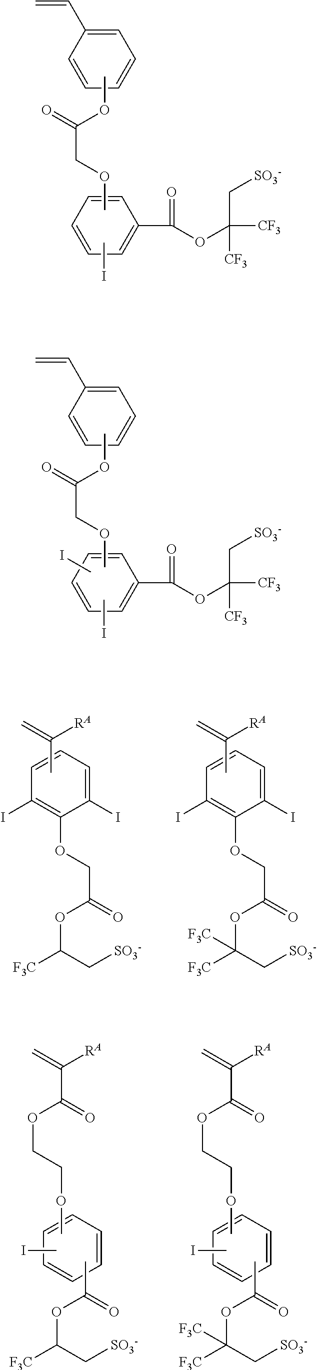

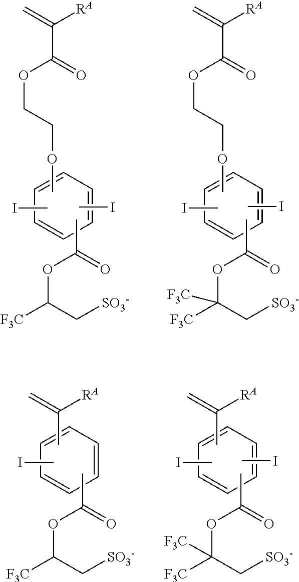

Examples of the anion in the monomer having formula (A5) are shown below, but not limited thereto. Herein R^{A} is as defined above.

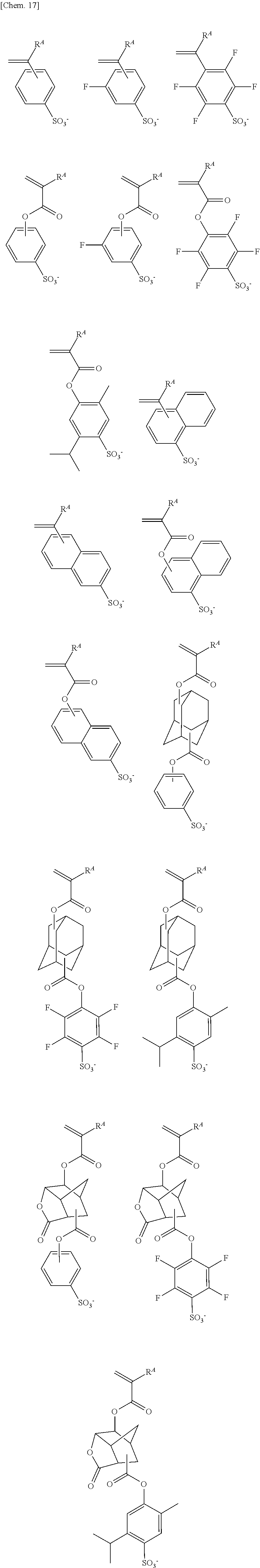

Examples of the anion in the monomer having formula (A6) are shown below, but not limited thereto. Herein R^{A} is as defined above.

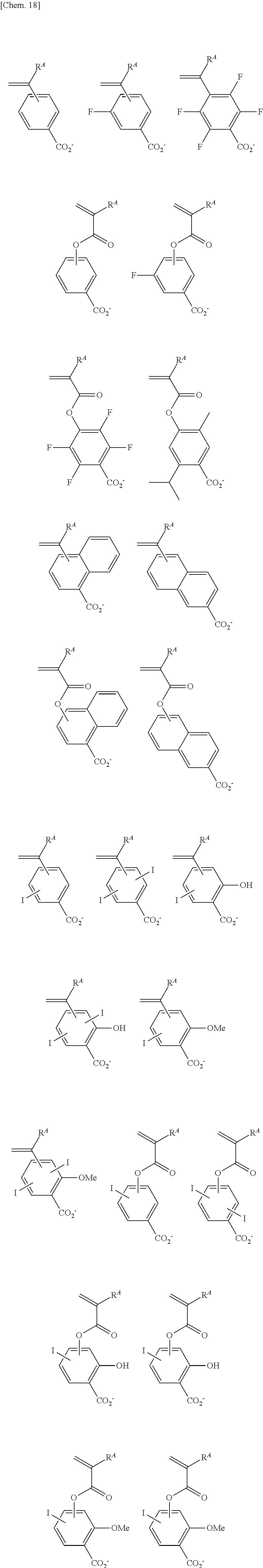

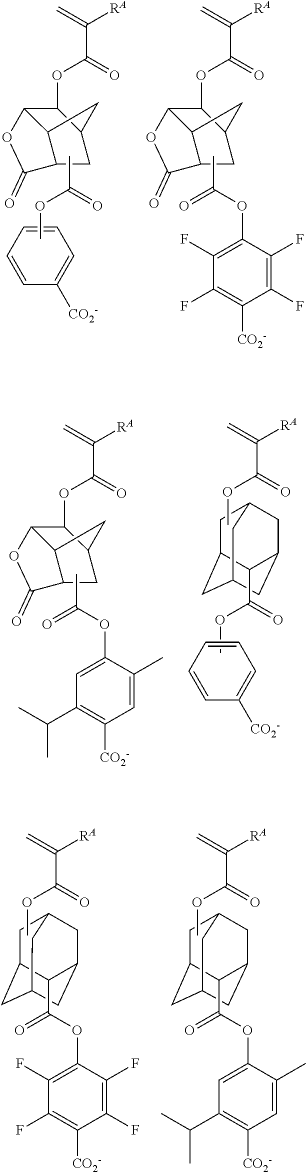

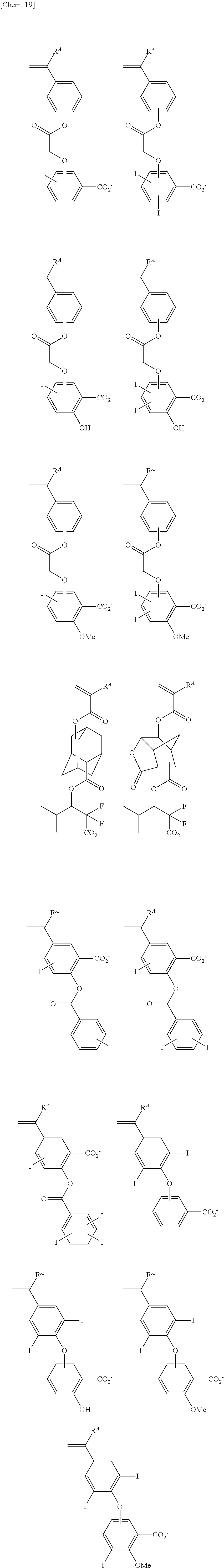

In formulae (A1) and (A2), M⁻ is each independently a non-nucleophilic counter ion. The non-nucleophilic counter ion is preferably selected from those having the formulae (M-1) to (M-6).

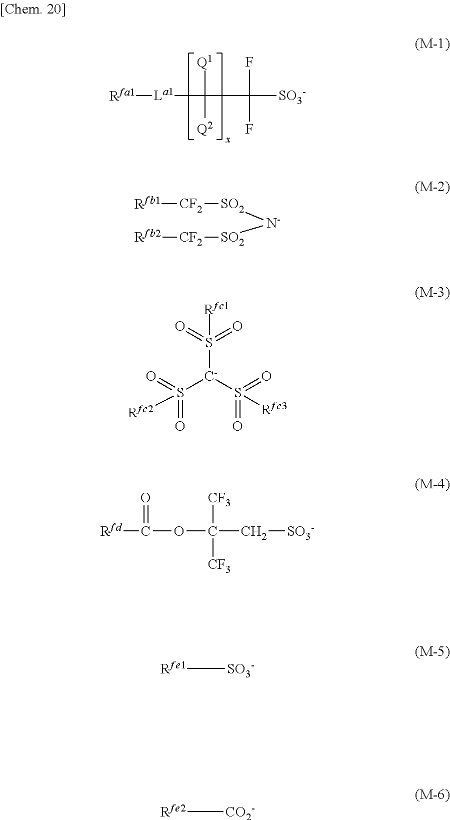

In formula (M-1), Q¹¹ and Q¹² are each independently hydrogen, fluorine or a C₁-C₆ fluorinated saturated hydrocarbyl group. R^{fa1} is a C₁-C₃₅ hydrocarbyl group which may contain a heteroatom, and x is an integer of 0 to 4.

In formula (M-2), R^{fb1} and R^{fb2} are each independently fluorine or a C₁-C₄₀ hydrocarbyl group which may contain a heteroatom. R^{fb1} and R^{fb2} may bond together to form a ring with the linkage: —CF₂—SO₂—N⁻—SO₂—CF₂— to which they are attached.

In formula (M-3), R^{fc1}, R^{fc2} and R^{fc3} are each independently fluorine or a C₁-C₄₀ hydrocarbyl group which may contain a heteroatom. R^{fc1} and R^{fc2} may bond together to form a ring with the linkage: —CF₂—SO₂—C⁻—SO₂—CF₂— to which they are attached.

In formula (M-4), R^{fd} is a C₁-C₄₀ hydrocarbyl group which may contain a heteroatom.

In formula (M-5), R^{fe1} is a C₁-C₃₀ aliphatic hydrocarbylene group, a phenylene group which may be substituted with fluorine or iodine, or a naphthylene group which may be substituted with fluorine or iodine. These groups may contain at least one moiety selected from hydroxy, ether bond, ester bond and lactone ring, and some hydrogen in the carbylene group may be substituted by fluorine or fluoroalkyl.

In formula (M-6), R^{fe2} is a C₁-C₃₀ aliphatic hydrocarbylene group, a phenylene group which may be substituted with fluorine or iodine, or a naphthylene group which may be substituted with fluorine or iodine. These groups may contain at least one moiety selected from hydroxy, ether bond, ester bond and lactone ring, and some hydrogen in the carbylene group may be substituted by fluorine or fluoroalkyl.

Examples of the non-nucleophilic counter ion are shown below, but not limited thereto.

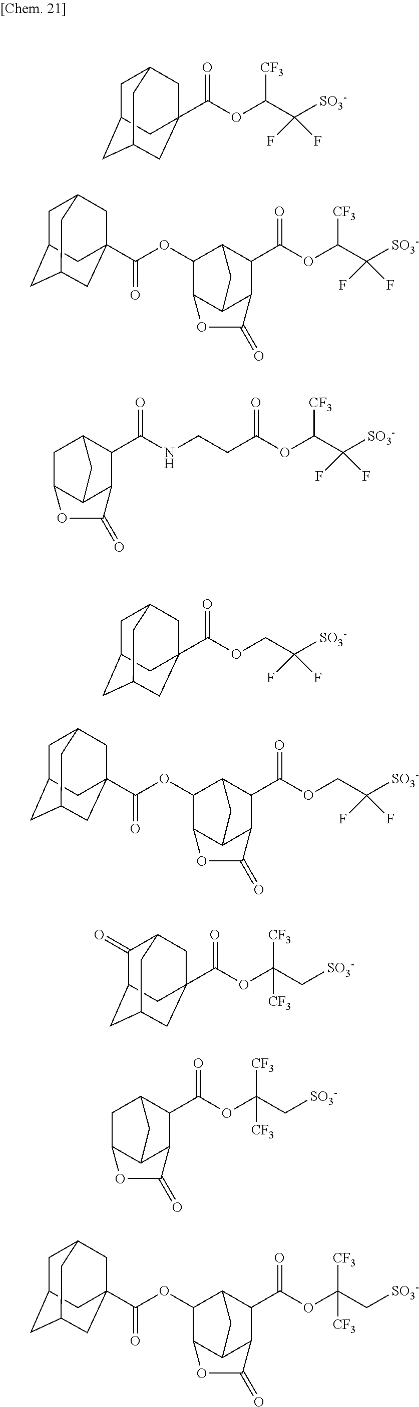

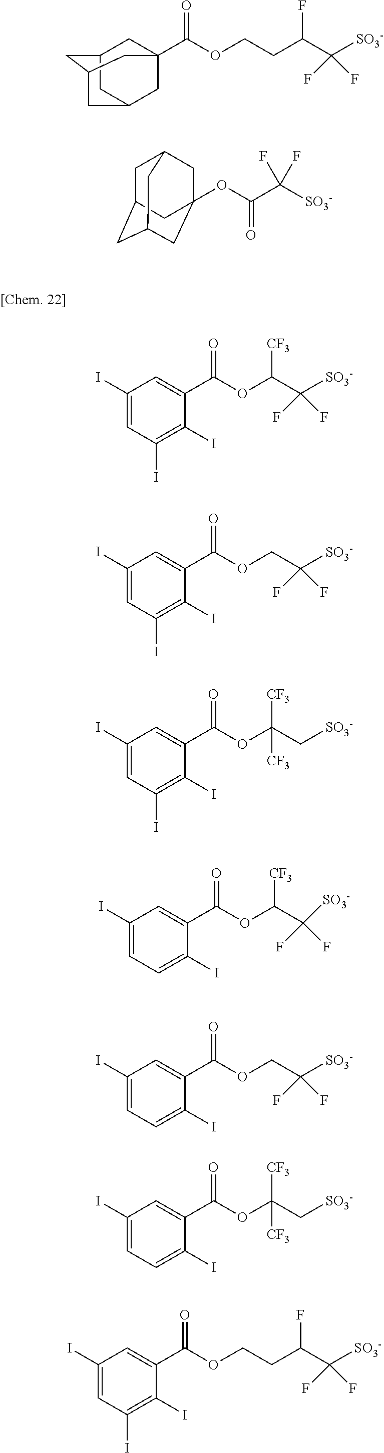

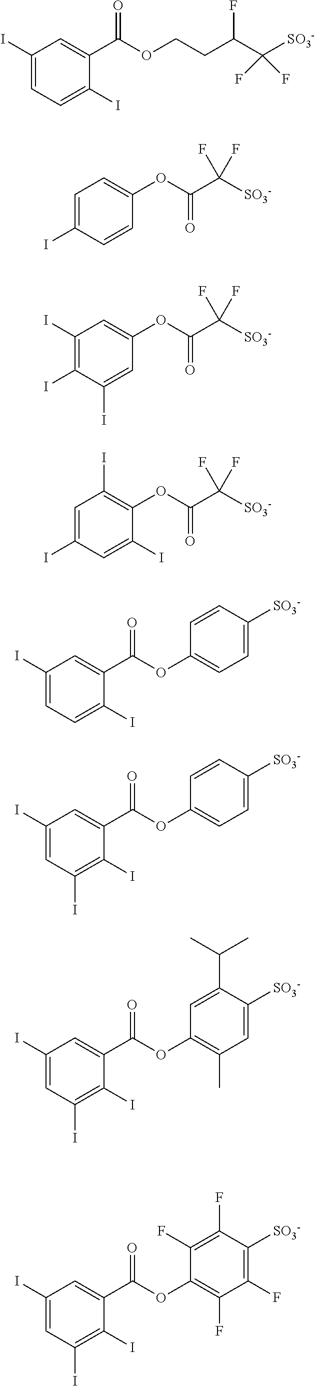

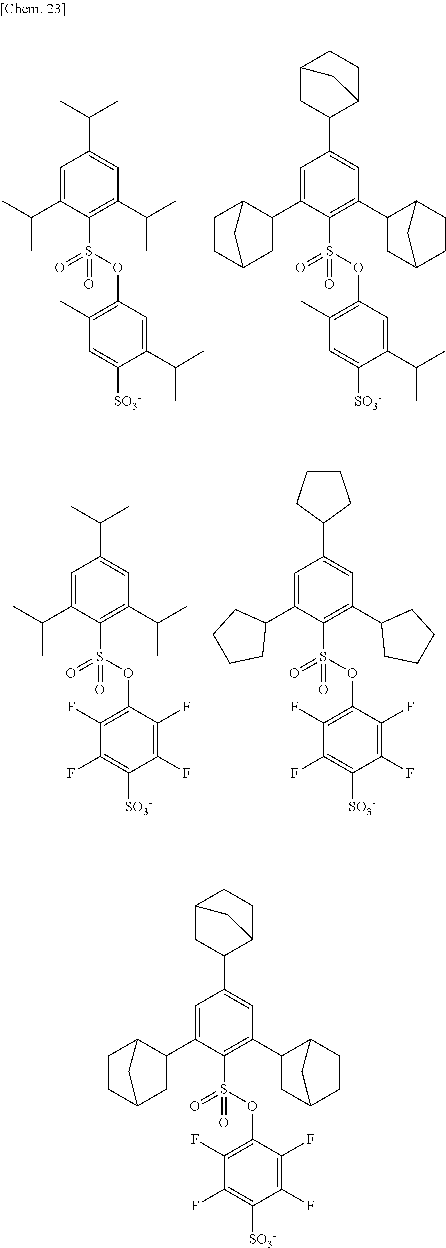

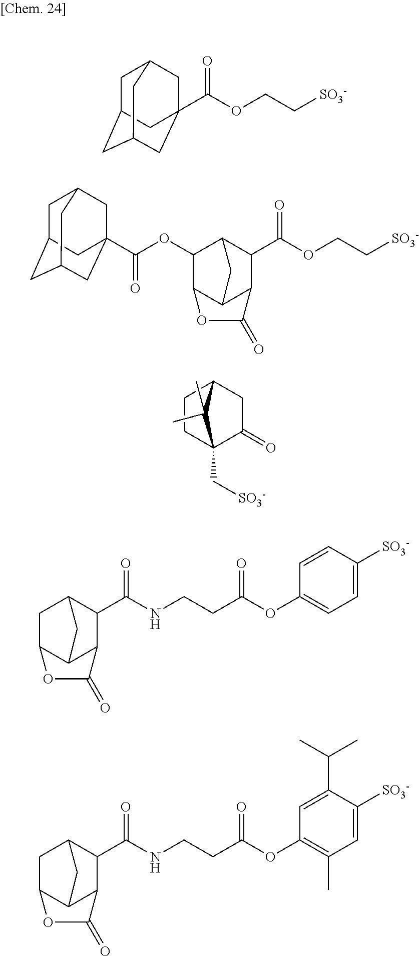

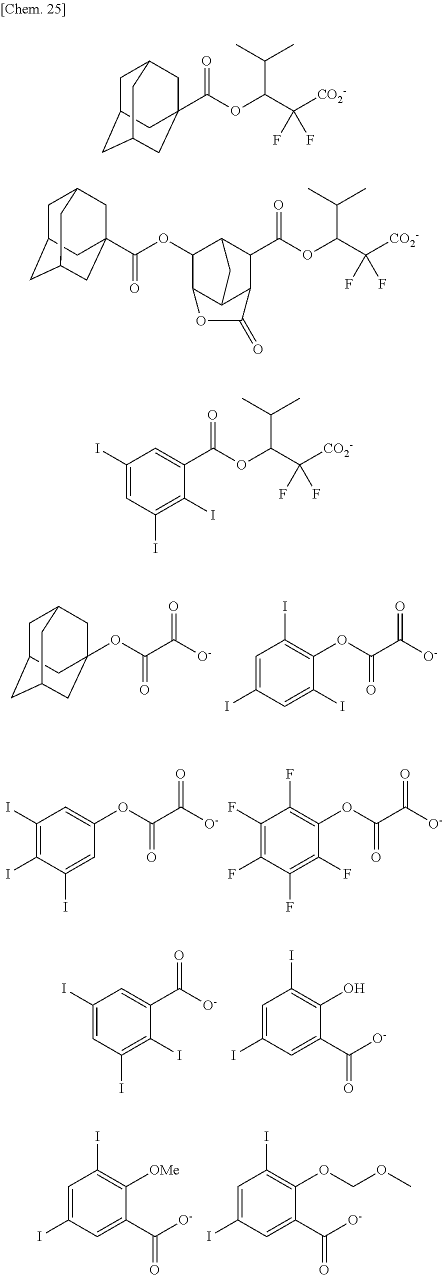

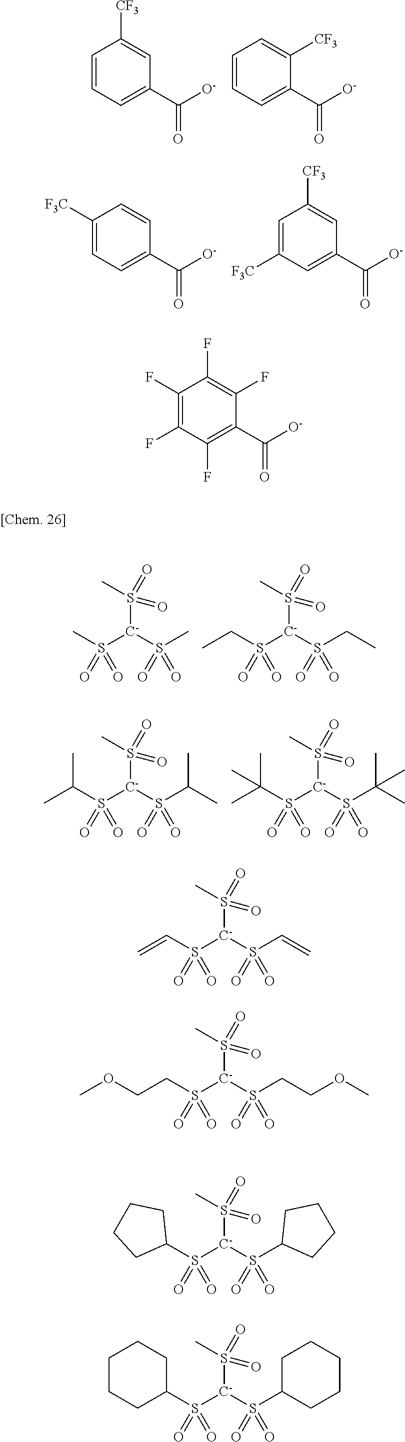

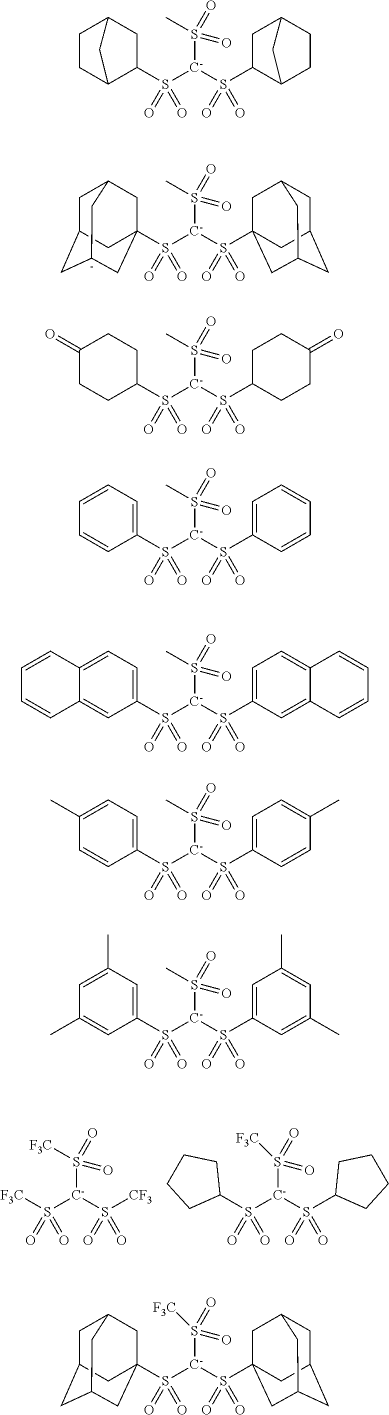

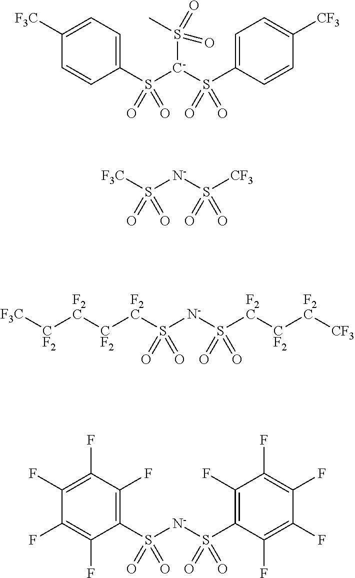 [SMILES: CS(=O)(=O)[C-](S(=O)(=O)c1ccc(C(F)(F)F)cc1)S(=O)(=O)c1ccc(C(F)(F)F)cc1 ; O=S(=O)([N-]S(=O)(=O)C(F)(F)F)C(F)(F)F ; O=S(=O)([N-]S(=O)(=O)C(F)(F)C(F)(F)C(F)(F)C(F)(F)C(F)(F)F)C(F)(F)C(F)(F)C(F)(F)C(F)(F)F ; O=S(=O)([N-]S(=O)(=O)c1c(F)c(F)c(F)c(F)c1F)c1c(F)c(F)c(F)c(F)c1F]

In formulae (A3) to (A6), A⁺ is an onium cation. Suitable onium cations include sulfonium, iodonium and ammonium cations, with the sulfonium and iodonium cations being preferred.

Of the onium cations, preferred are sulfonium cations having the formula (cation-1) and iodonium cations having formula (cation-2).

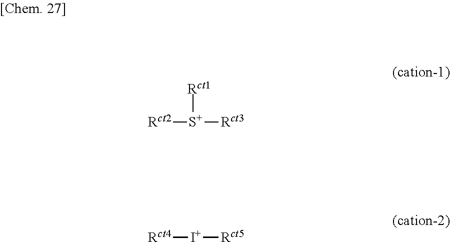

In formulae (cation-1) and (cation-2), R^{ct1} to R^{ct5} are each independently halogen or a C₁-C₃₀ hydrocarbyl group which may contain a heteroatom. Suitable halogen atoms include fluorine, chlorine, bromine, and iodine. The hydrocarbyl group R^{ct1} to R^{ct5} may be saturated or unsaturated and straight, branched or cyclic. Examples thereof are as exemplified above for the hydrocarbyl group represented by R¹ to R³ in formulae (A1) and (A2). In the hydrocarbyl group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, fluorine, chlorine, bromine, iodine, cyano moiety, nitro moiety, carbonyl moiety, ether bond, ester bond, sulfonic ester bond, carbonate bond, lactone ring, sultone ring, carboxylic anhydride (—C(═O)—O—C(═O)—) or haloalkyl moiety.

Also, R^{ct1} and R^{ct2} may bond together to form a ring with the sulfur atom to which they are attached. Exemplary structures of the ring are shown below.

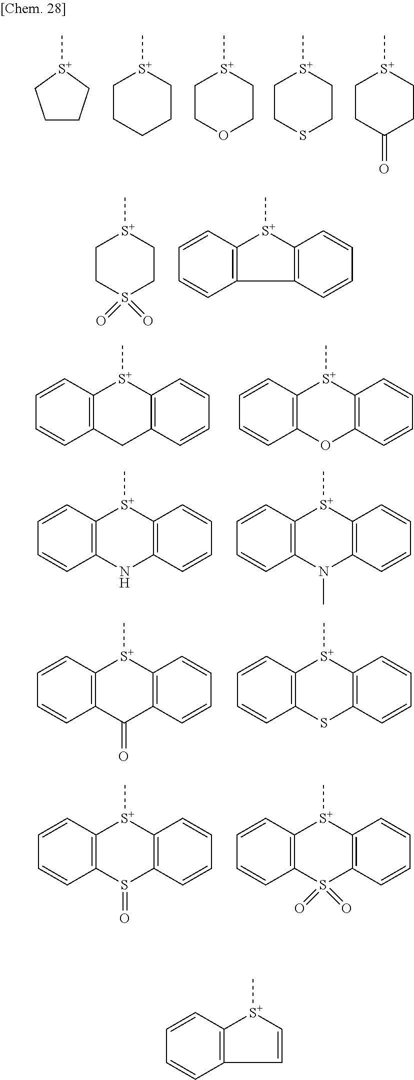

Herein the broken line designates a point of attachment to R^{ct3}.

Examples of the onium cation are shown below, but not limited thereto.

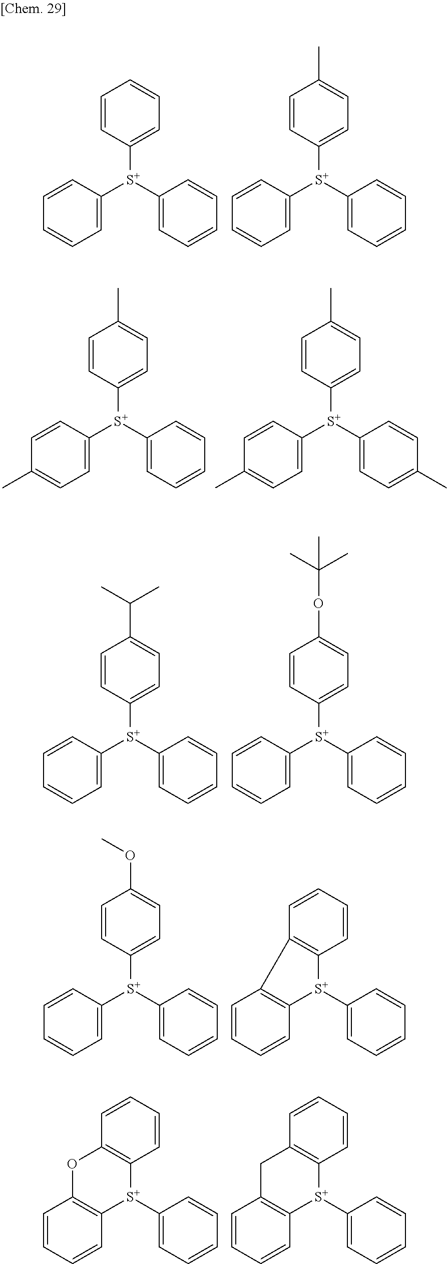

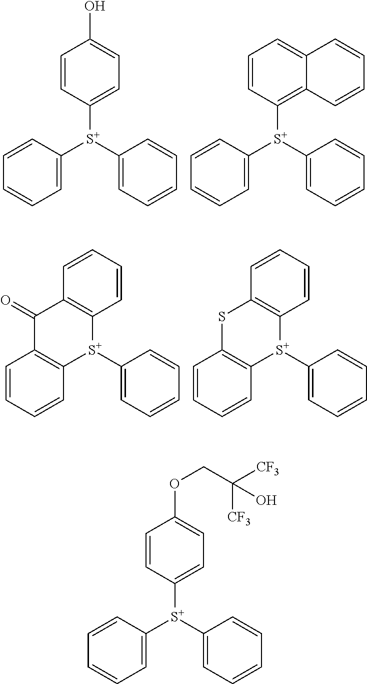 [SMILES: Oc1ccc([S+](c2ccccc2)c2ccccc2)cc1 ; c1ccc([S+](c2ccccc2)c2cccc3ccccc23)cc1 ; O=c1c2ccccc2[s+](-c2ccccc2)c2ccccc12 ; c1ccc([S+]2c3ccccc3Sc3ccccc32)cc1 ; OC(COc1ccc([S+](c2ccccc2)c2ccccc2)cc1)(C(F)(F)F)C(F)(F)F]

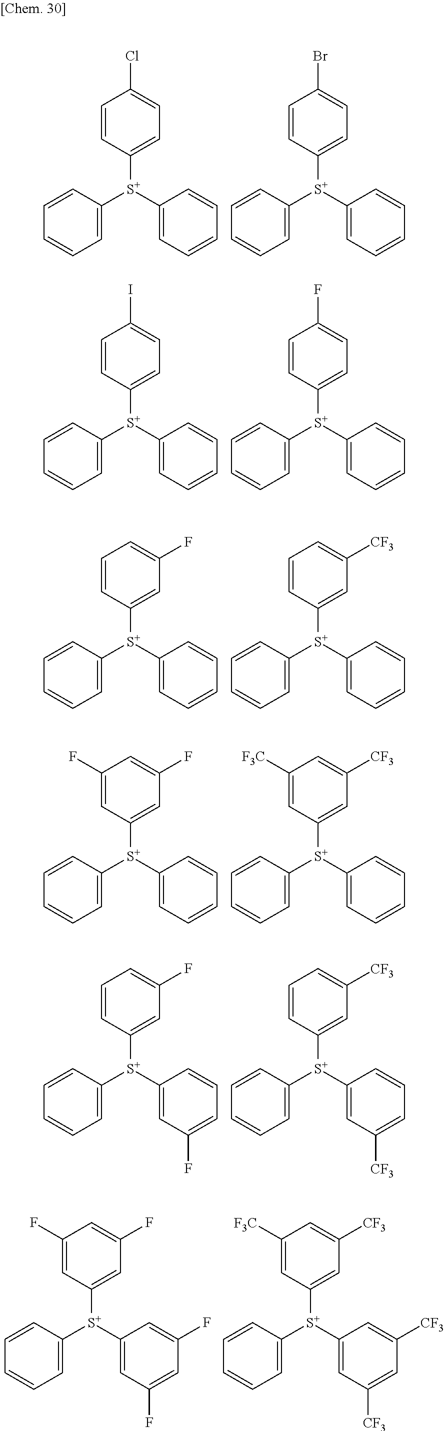

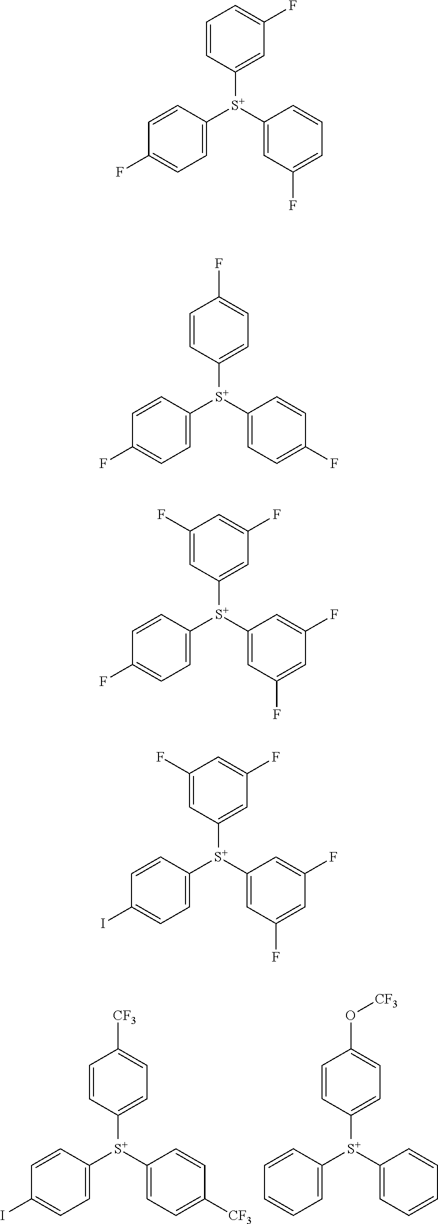 [SMILES: Fc1ccc([S+](c2cccc(F)c2)c2cccc(F)c2)cc1 ; Fc1ccc([S+](c2ccc(F)cc2)c2ccc(F)cc2)cc1 ; Fc1ccc([S+](c2cc(F)cc(F)c2)c2cc(F)cc(F)c2)cc1 ; Fc1cc(F)cc([S+](c2ccc(I)cc2)c2cc(F)cc(F)c2)c1 ; FC(F)(F)c1ccc([S+](c2ccc(I)cc2)c2ccc(C(F)(F)F)cc2)cc1 ; FC(F)(F)Oc1ccc([S+](c2ccccc2)c2ccccc2)cc1]

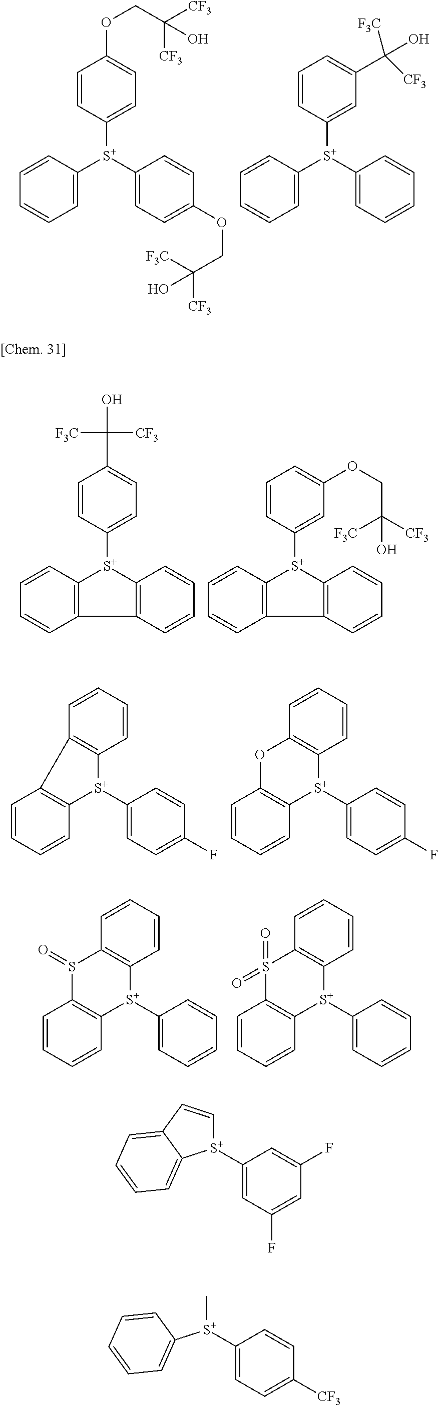

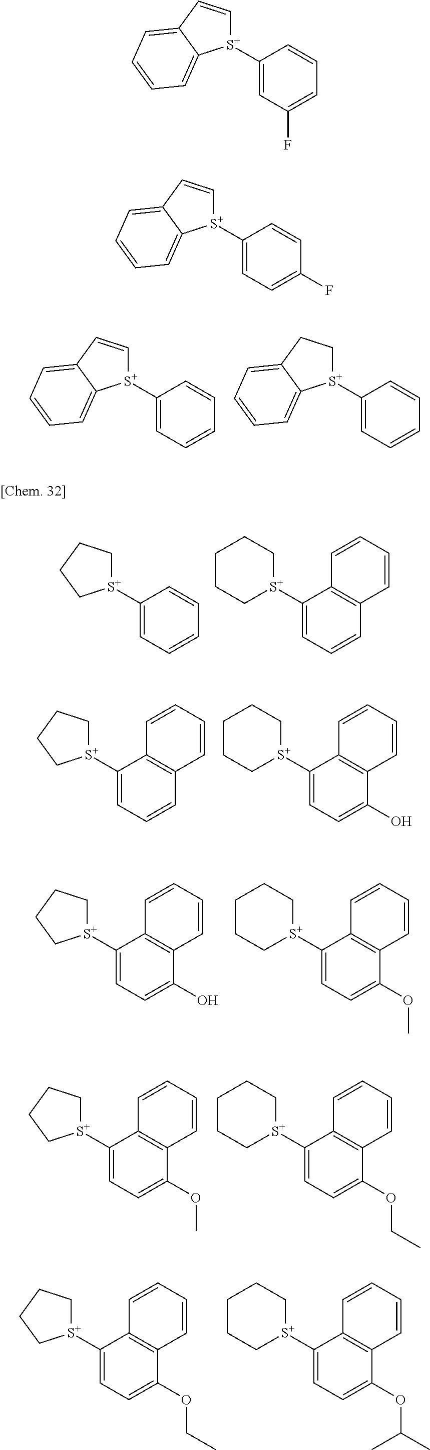

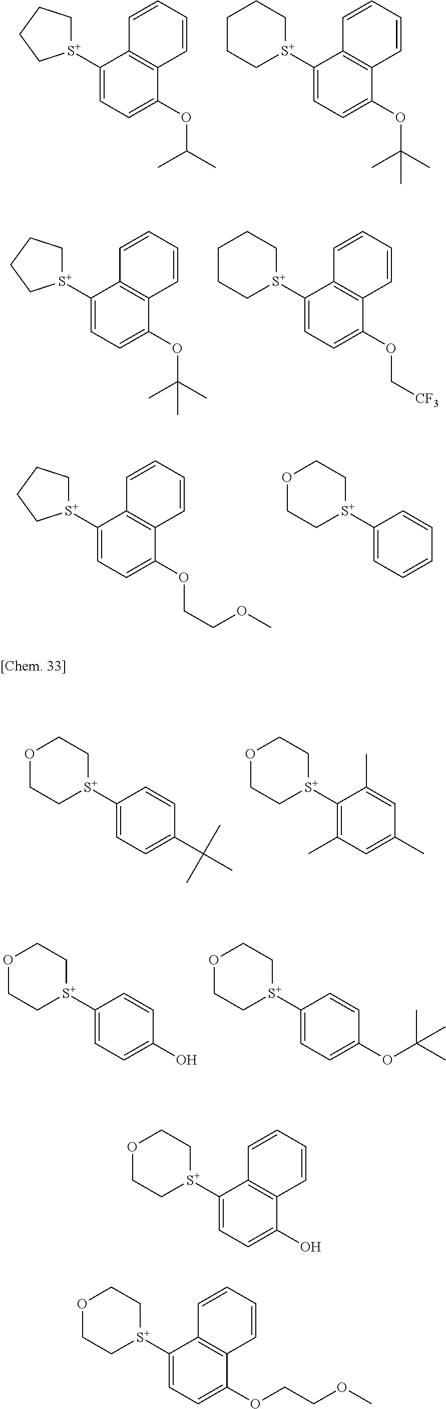

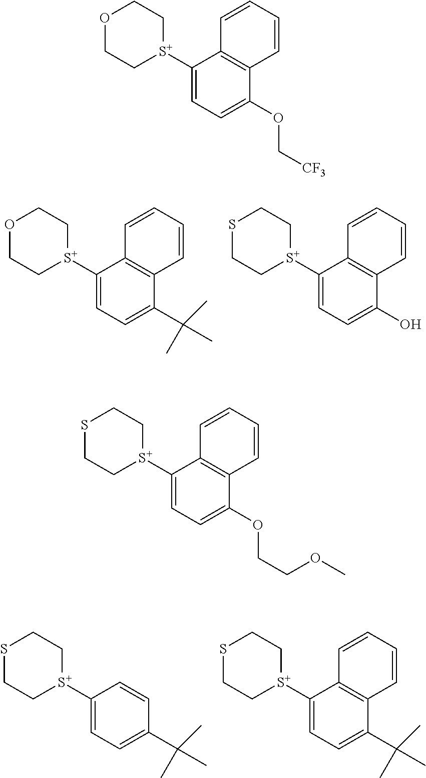 [SMILES: FC(F)(F)COc1ccc([S+]2CCOCC2)c2ccccc12 ; CC(C)(C)c1ccc([S+]2CCOCC2)c2ccccc12 ; Oc1ccc([S+]2CCSCC2)c2ccccc12 ; COCCOc1ccc([S+]2CCSCC2)c2ccccc12 ; CC(C)(C)c1ccc([S+]2CCSCC2)cc1 ; CC(C)(C)c1ccc([S+]2CCSCC2)c2ccccc12]

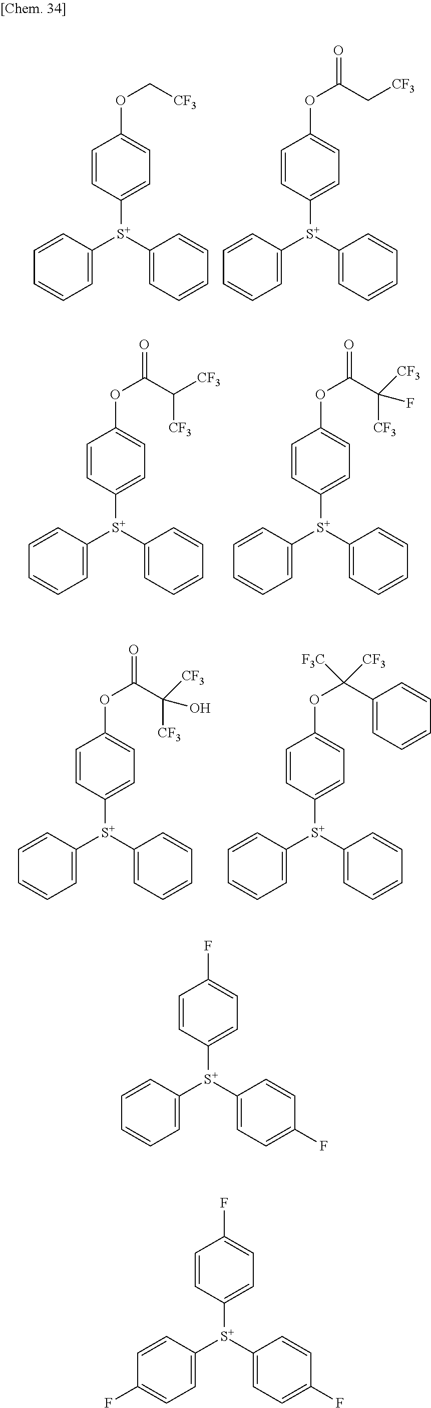

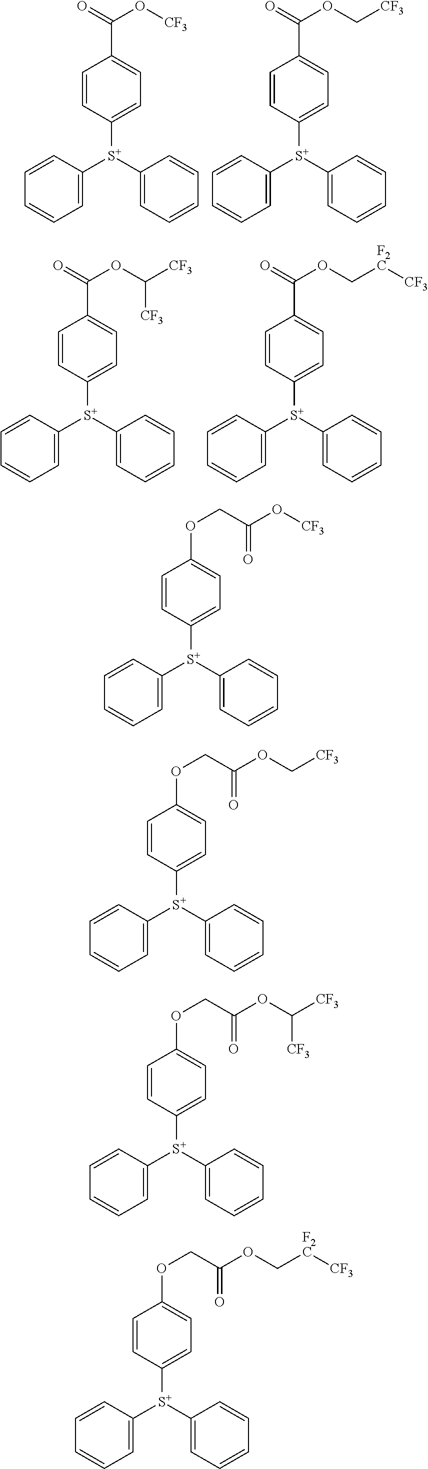

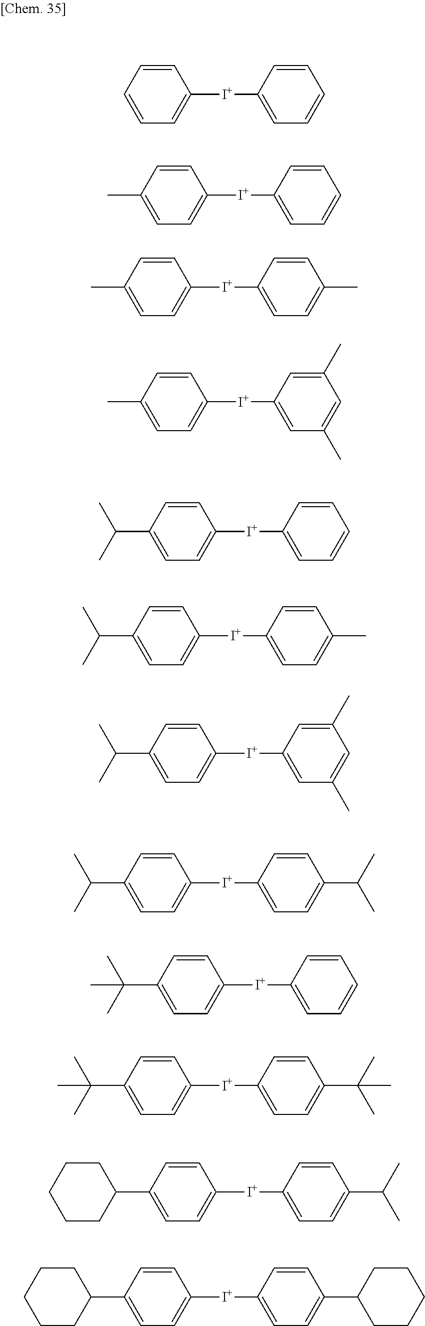

The monomer (B) has the formula (B1).

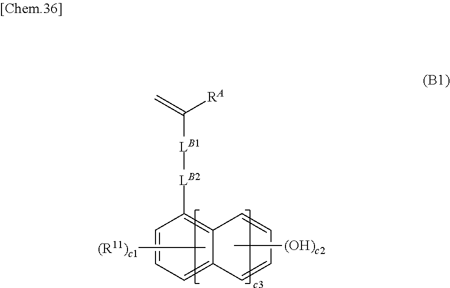

In formula (B1), R^{A} is each independently hydrogen, fluorine, methyl or trifluoromethyl. R¹¹ is halogen or a C₁-C₆ saturated hydrocarbyl group which may contain at least one moiety selected from ether bond and carbonyl moiety. L^{B1} is a single bond, carbonyloxy group or amide group. L^{B2} is a single bond, or a C₁-C₇ alkanediyl group which contain at least one moiety selected from ether bond and carbonyl moiety. The subscript c1 is an integer meeting 0≤c1≤5+2(c3)−c2, c2 is 1, 2, 3, 4 or 5, and c3 is 0, 1 or 2. When c1 is 2 or more, a plurality of R¹¹ may be identical or different.

In formula (B1), examples of the C₁-C₆ hydrocarbyl group which may contain ether bond and/or carbonyl moiety, represented by R¹¹, include methyl, ethyl, propyl, isopropyl, n-butyl, sec-butyl, tert-butyl, pentyl, hexyl, heptyl, octyl, cyclopentyl and cyclohexyl as well as the groups shown below, but not limited thereto.

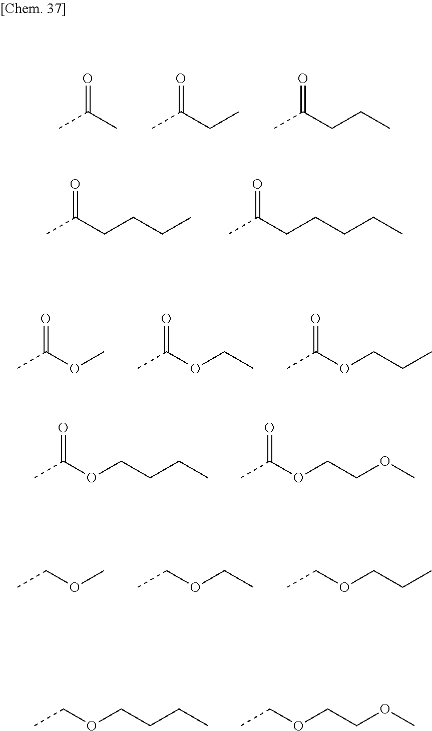

Herein the broken line designates a point of attachment.

In formula (B1), examples of the C₁-C₇ alkanediyl group which contain ether bond and/or carbonyl moiety, represented by L^{B2}, include methylene, ethylene, propane-1,3-diyl, butane-1,4-diyl, pentane-1,5-diyl, hexane-1,6-diyl, and heptane-1,7-diyl as well as the groups shown below, but not limited thereto.

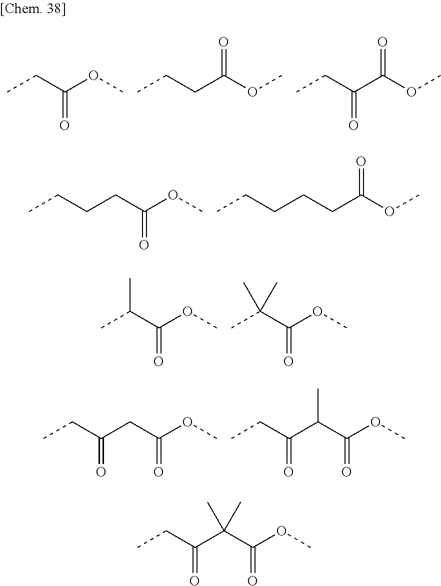

Herein the broken line designates a point of attachment.

Examples of the monomer having formula (B1) are shown below, but not limited thereto. Herein R^{A} is as defined above.

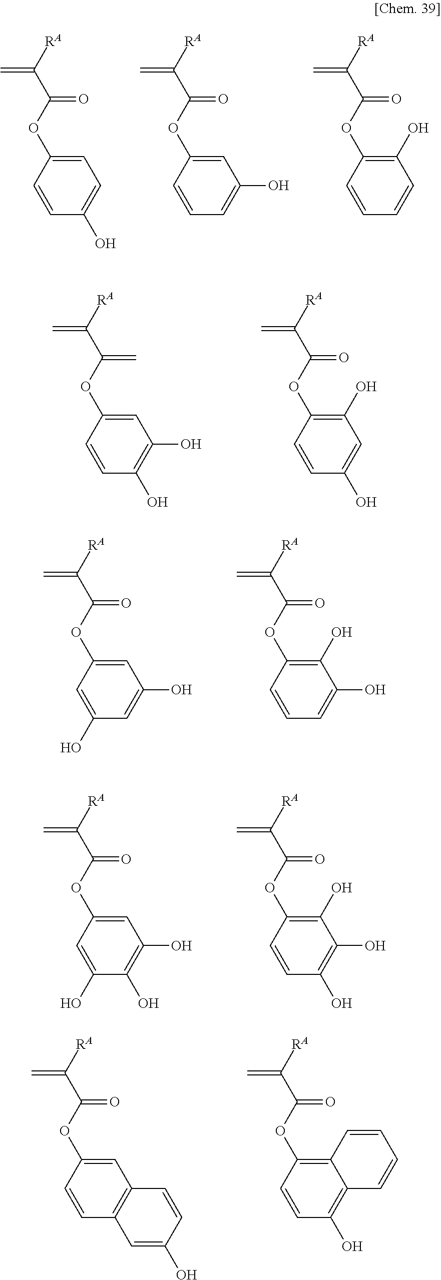

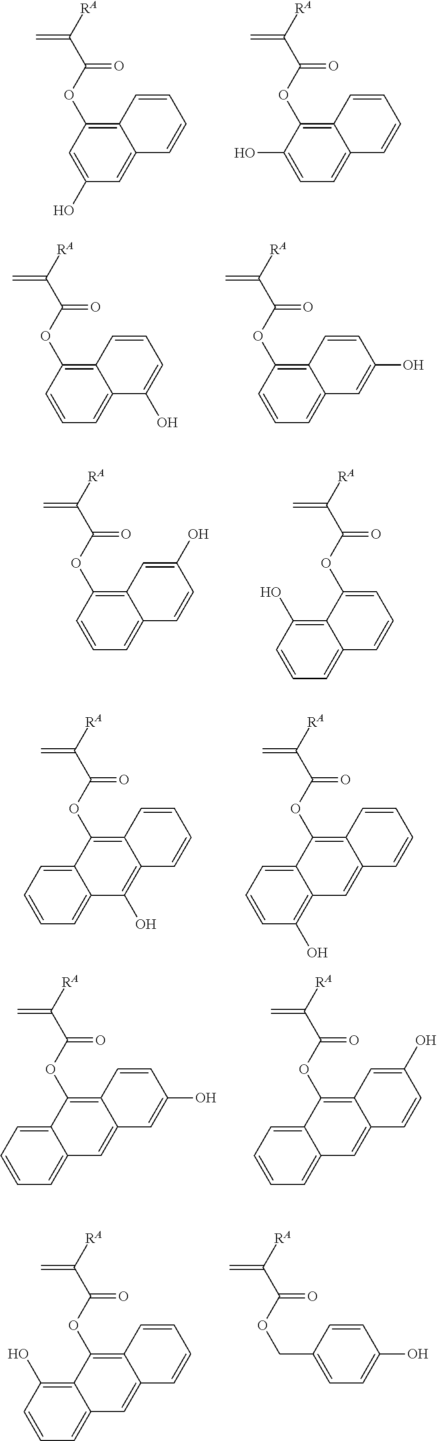

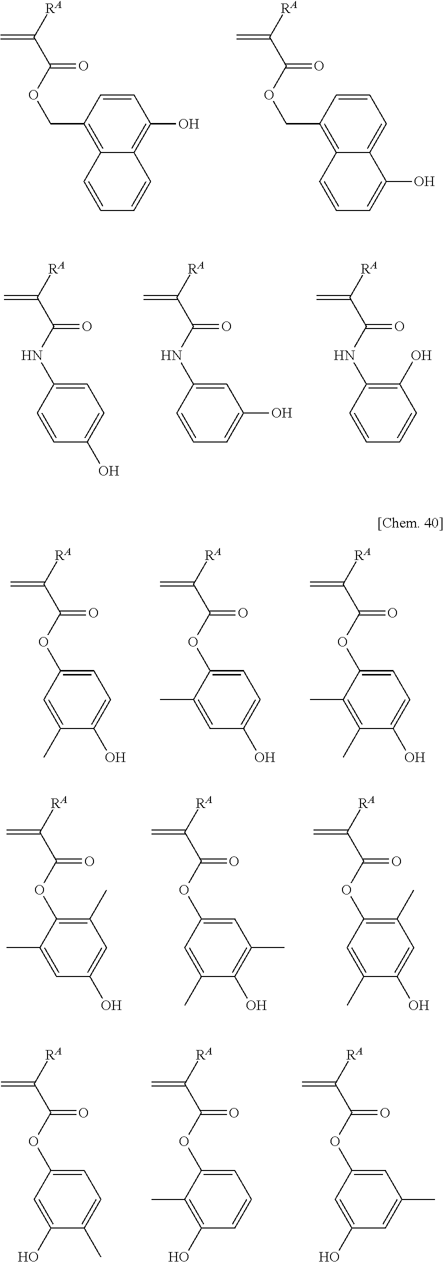

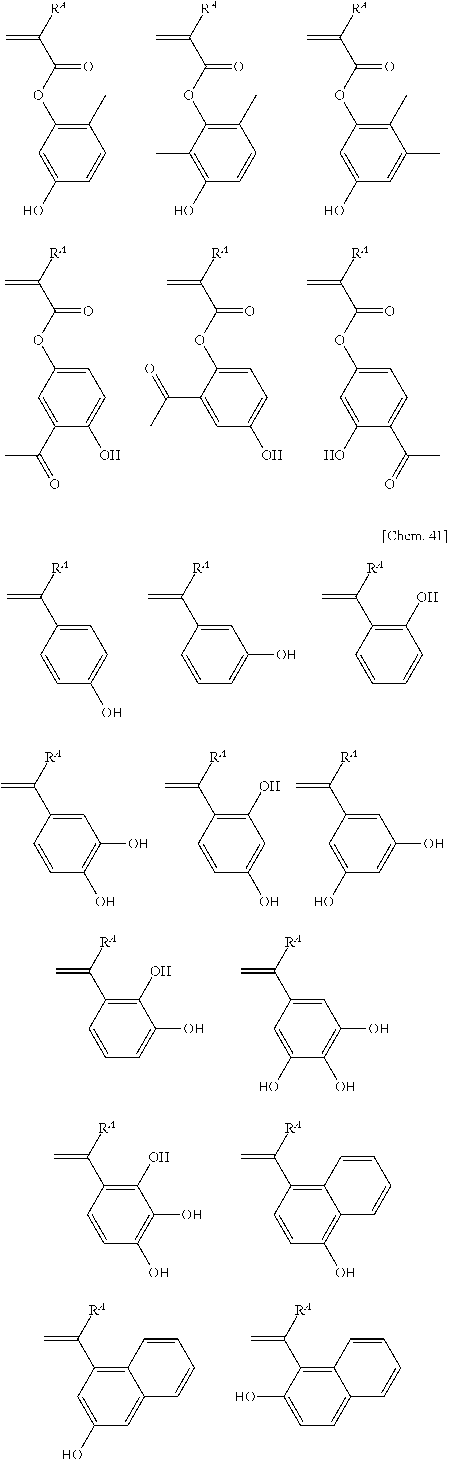

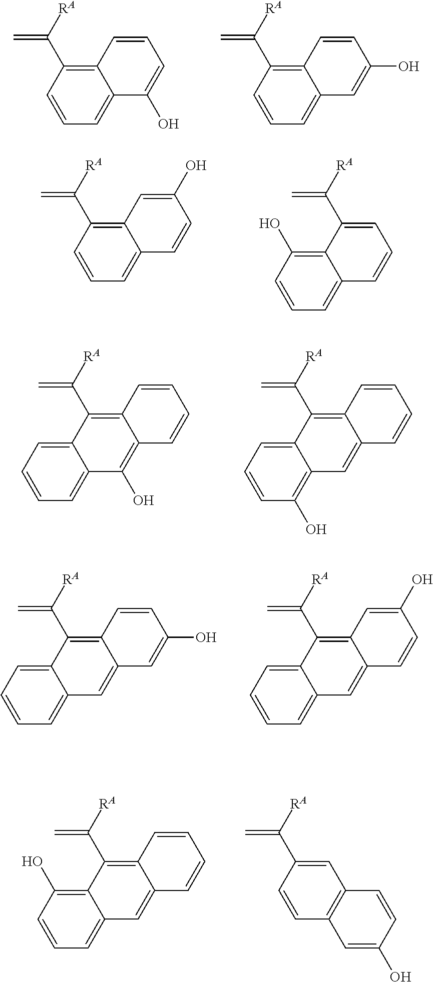

The monomer (C) is preferably a monomer having an acid labile group, more preferably a monomer having the formula (C1), (C2) or (C3).

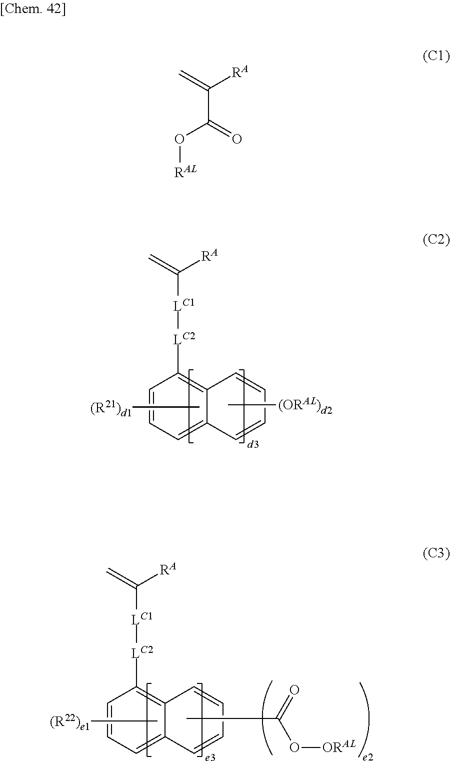

In formulae (C1), (C2) and (C3), R^{A} is each independently hydrogen, fluorine, methyl or trifluoromethyl. R^{AL} is each independently an acid labile group. R²¹ and R²² are each independently halogen or a C₁-C₆ saturated hydrocarbyl group halogen atom which may contain at least one moiety selected from ether bond and carbonyl, or halogen. L^{C1} is each independently a single bond, carbonyloxy group or amide group. L^{C2} is each independently a single bond or a C₁-C₇ alkanediyl group which may contain ether bond or carbonyl moiety. The subscript d1 is an integer meeting 0≤d1≤5+2(d3)−d2; d2 is 1, 2, 3, 4 or 5; d3 is 0, 1 or 2; e1 is an integer meeting 0≤e1≤5+2(e3)−e2; e2 is 1, 2, 3, 4 or 5; and e3 is 0, 1 or 2. When d1 is 2 or more, a plurality of R²¹ may be identical or different. When e1 is 2 or more, a plurality of R²² may be identical or different.

Examples of the C₁-C₆ saturated hydrocarbyl group which may contain ether bond and/or carbonyl, represented by R²¹ and R²², include methyl, ethyl, propyl, isopropyl, n-butyl, sec-butyl, tert-butyl, pentyl, hexyl, heptyl, octyl, cyclopentyl, cyclohexyl and the following, but are not limited thereto.

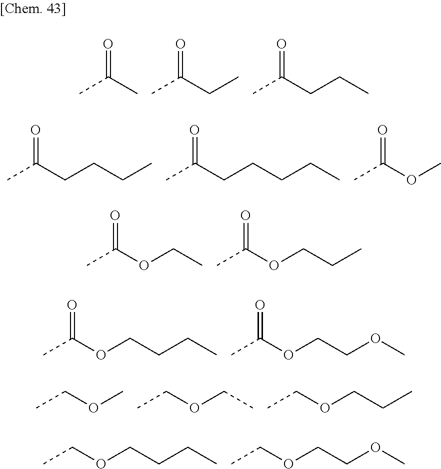

Herein the broken line designates a point of attachment.

Examples of the C₁-C₇ alkanediyl group which may contain ether bond or carbonyl moiety, represented by L^{C2}, include methylene, ethylene, propane-1,3-diyl, butane-1,4-diyl, pentane-1,5-diyl, hexane-1,6-diyl, heptane-1,7-diyl and the following, but are not limited thereto.

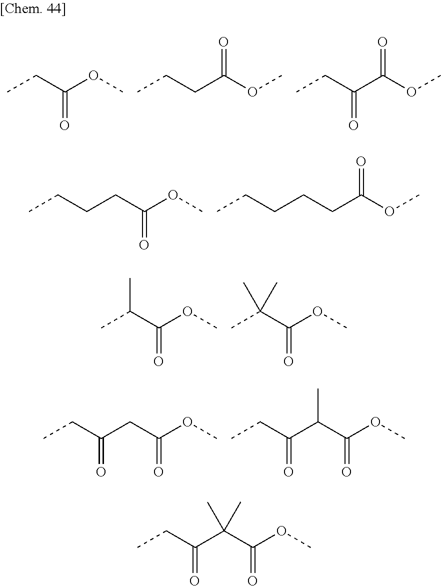

Herein the broken line designates a point of attachment.

A polymer comprising repeat units derived from the monomer having formula (C1), (C2) or (C3) is decomposed under the action of acid to generate a carboxy or phenolic hydroxy group and turns alkaline soluble. The acid labile group R^{AL} may be selected from a variety of such groups, specifically groups having the following formulae (L1) to (L9), tertiary hydrocarbyl groups of 4 to 20 carbon atoms, preferably 4 to 15 carbon atoms, trihydrocarbylsilyl groups in which each hydrocarbyl moiety has 1 to 6 carbon atoms, and C₄-C₂₀ hydrocarbyl groups containing carbonyl moiety, ether bond or ester bond.

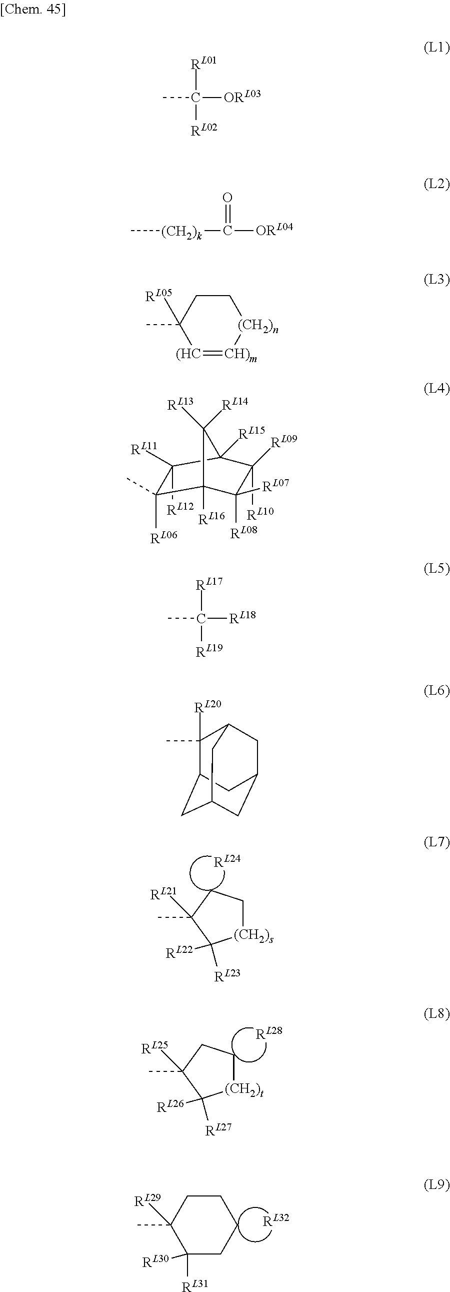

Herein the broken line designates a point of attachment.

In formula (L1), R^{L01} and R^{L02} are each independently hydrogen or a C₁-C₁₈, preferably C₁-C₁₀ saturated hydrocarbyl group. The saturated alkyl hydrocarbyl group may be straight, branched or cyclic, and examples thereof include C₁-C₁₈ alkyl groups such as methyl, ethyl, n-propyl, isopropyl, n-butyl, isobutyl, sec-butyl, tert-butyl, 2-ethylhexyl, and n-octyl; and C₃-C₁₈ cyclic saturated hydrocarbyl groups such as cyclopentyl, cyclohexyl, norbornyl, tricyclodecanyl, tetracyclododecanyl, and adamantyl.

In formula (L1), R^{L03} is a C₁-C₁₈, preferably C₁-C₁₀ hydrocarbyl group which may contain a heteroatom. Suitable heteroatoms include oxygen, nitrogen, and sulfur. The hydrocarbyl group may be saturated or unsaturated and straight, branched or cyclic, with saturated hydrocarbyl groups being preferred. In the saturated hydrocarbyl group, some hydrogen may be substituted by hydroxy, C₁-C₈ saturated hydrocarbyloxy, oxo, amino, saturated hydrocarbylamino or the like, and some —CH₂— may be replaced by a moiety containing a heteroatom such as oxygen. Examples of the saturated hydrocarbyl group are as exemplified for the saturated hydrocarbyl groups R^{L01} and R^{L02}. Examples of the substituted saturated hydrocarbyl group are illustrated below.

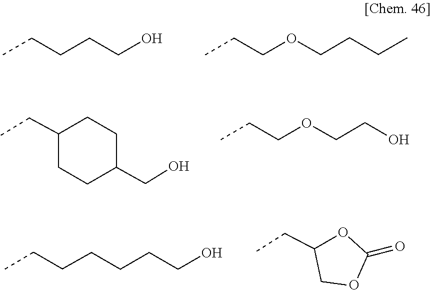

Any two of R^{L01}, R^{L02} and R^{L03} may bond together to form a ring with the carbon atom or carbon and oxygen atoms to which they are attached. In the case of ring formation, the group formed by two of R^{L01}, R^{L02} and R^{L03} is a C₁-C₁₈, preferably C₁-C₁₀ alkanediyl group.

In formula (L2), R^{L04} is a C₄-C₂₀, preferably C₄-C₁₅ tertiary hydrocarbyl group, a trihydrocarbylsilyl group in which each hydrocarbyl moiety has 1 to 6 carbon atoms, a C₄-C₂₀ saturated hydrocarbyl group containing carbonyl, ether bond or ester bond, or a group of formula (L1), and k is an integer of 0 to 6.

The tertiary hydrocarbyl group R^{L04} may be branched or cyclic. Examples thereof include tert-butyl, tert-pentyl, 1,1-diethylpropyl, 2-cyclopentylpropan-2-yl, 2-cyclohexylpropan-2-yl, 2-(bicyclo[2.2.1]heptan-2-yl)propan-2-yl, 2-(adamantan-1-yl)propan-2-yl, 1-ethylcyclopentyl, 1-butylcyclopentyl, 1-ethylcyclohexyl, 1-butylcyclohexyl, 1-ethyl-2-cyclopentenyl, 1-ethyl-2-cyclohexenyl, 2-methyl-2-adamantyl, and 2-ethyl-2-adamantyl. Examples of the trihydrocarbylsilyl group include trimethylsilyl, triethylsilyl, and dimethyl-tert-butylsilyl. Examples of the saturated hydrocarbyl group containing carbonyl, ether bond or ester bond include 3-oxocyclohexyl, 4-methyl-2-oxooxan-4-yl, and 5-methyl-2-oxooxolan-5-yl.

In formula (L3), R^{L05} is a C₁-C₈ saturated hydrocarbyl group which may contain a heteroatom or a C₆-C₂₀ aryl group which may contain a heteroatom. The saturated hydrocarbyl group may be straight, branched or cyclic and examples thereof include alkyl groups such as methyl, ethyl, n-propyl, isopropyl, n-butyl, isobutyl, sec-butyl, tert-butyl, n-pentyl, tert-pentyl, n-hexyl, and cyclic saturated hydrocarbyl groups such as cyclopentyl and cyclohexyl. In the saturated hydrocarbyl group, some hydrogen may be substituted by hydroxy, C₁-C₈ saturated hydrocarbyloxy, carboxy, C₁-C₈ saturated hydrocarbyloxycarbonyl, oxo, amino, C₁-C₈ saturated hydrocarbylamino, cyano, mercapto, C₁-C₈ saturated hydrocarbylthio, sulfo or the like. Exemplary aryl groups include phenyl, methylphenyl, naphthyl, anthryl, phenanthryl, and pyrenyl. In the aryl group, some hydrogen may be substituted by hydroxy, C₁-C₈ saturated hydrocarbyloxy, carboxy, C₁-C₈ saturated hydrocarbylcarbonyl, oxo, amino, C₁-C₈ saturated hydrocarbylamino, cyano, mercapto, C₁-C₈ saturated hydrocarbylthio, sulfo or the like.

In formula (L3), m is 0 or 1, n is 0, 1, 2 or 3, and 2m+n is equal to 2 or 3.

In formula (L4), R^{L06} is a C₁-C₁₀ saturated hydrocarbyl group which may contain a heteroatom or a C₆-C₂₀ aryl group which may contain a heteroatom. Examples of the saturated hydrocarbyl and aryl groups are as exemplified for the saturated hydrocarbyl and aryl groups R^{L05}.

In formula (L4), R^{L07} to R^{L16} are each independently hydrogen or a C₁-C₁₅ hydrocarbyl group. The hydrocarbyl group may be saturated or unsaturated and straight, branched or cyclic, with saturated hydrocarbyl groups being preferred. Examples thereof include alkyl groups such as methyl, ethyl, n-propyl, isopropyl, n-butyl, isobutyl, sec-butyl, tert-butyl, n-pentyl, tert-pentyl, n-hexyl, n-octyl, n-nonyl, n-decyl, and cyclic saturated hydrocarbyl groups such as cyclopentyl, cyclohexyl, cyclopentylmethyl, cyclopentylethyl, cyclopentylbutyl, cyclohexylmethyl, cyclohexylethyl and cyclohexylbutyl. In the hydrocarbyl group, some hydrogen may be substituted by hydroxy, C₁-C₈ saturated hydrocarbyloxy, carboxy, C₁-C₈ saturated hydrocarbyloxycarbonyl, oxo, amino, C₁-C₈ saturated hydrocarbylamino, cyano, mercapto, C₁-C₈ saturated hydrocarbylthio, sulfo or the like. Any two of R^{L07} to R^{L16} (e.g., R^{L07} and R^{L08}, R^{L07} and R^{L09}, R^{L08} and R^{L10}, R^{L09} and R^{L10}, R^{L11} and R^{L12}, or R^{L13} and R^{L14}) may bond together to form a ring with the carbon atom to which they are attached. The group to form a ring is a C₁-C₁₅ hydrocarbylene group. Examples of the hydrocarbylene group are those exemplified above for the hydrocarbyl group, with one hydrogen atom being eliminated. Also a pair of R^{L07} to R^{L16} (e.g., R^{L07} and R^{L09}, R^{L09} and R^{L15}, or R^{L13} and R^{L15}) which are attached to vicinal carbon atoms may bond together directly to form a double bond.

In formula (L5), R^{L17} to R^{L19} are each independently hydroxy, halogen, a C₁-C₁₅ alkyl group which may contain a heteroatom, or C₆-C₁₅ aryl group which may contain a heteroatom. The saturated hydrocarbyl group may be straight, branched or cyclic. Examples thereof include alkyl groups such as methyl, ethyl, n-propyl, isopropyl, n-butyl, isobutyl, sec-butyl, tert-butyl, 2-ethylhexyl, n-octyl; and cyclic saturated hydrocarbyl groups such as cyclopentyl, cyclohexyl, 1-adamantyl and 2-adamantyl. Suitable aryl groups include phenyl and naphthyl. The aryl group may contain hydroxy, halogen or the like.

In formula (L6), R^{L20} is a C₁-C₁₀ cyclic saturated hydrocarbyl group which may contain a heteroatom or C₆-C₂₀ aryl group which may contain a heteroatom. Examples of the cyclic saturated hydrocarbyl and aryl groups are as exemplified for the saturated hydrocarbyl and aryl groups R^{L05}.

In formula (L7), R^{L21} is a C₁-C₁₀ saturated hydrocarbyl group which may contain a heteroatom or a C₆-C₂₀ aryl group which may contain a heteroatom. Examples of the saturated hydrocarbyl and aryl groups are as exemplified for the saturated hydrocarbyl and aryl groups R^{L05}. R^{L22} and R^{L23} are each independently hydrogen or a C₁-C₁₀ hydrocarbyl group. The hydrocarbyl group may be saturated or unsaturated and straight, branched or cyclic. Examples thereof are as exemplified for the hydrocarbyl group R^{L07} to R^{L16}. R^{L22} and R^{L23} may bond together to form a substituted or unsubstituted cyclopentane ring or a substituted or unsubstituted cyclohexane ring with the carbon atom to which they are attached. R^{L24} is a divalent group which forms a substituted or unsubstituted cyclopentane, cyclohexane or norbornane ring with the carbon atom to which it is attached. The subscript s is 1 or 2.

In formula (L8), R^{L25} is a C₁-C₁₀ saturated hydrocarbyl group which may contain a heteroatom or a C₆-C₂₀ aryl group which may contain a heteroatom. Examples of the saturated hydrocarbyl and aryl groups are as exemplified for the saturated hydrocarbyl and aryl groups R^{L05}. R^{L26} and R^{L27} are each independently hydrogen or a C₁-C₁₀ hydrocarbyl group. The hydrocarbyl group may be saturated or unsaturated and straight, branched or cyclic. Examples thereof are as exemplified for the hydrocarbyl group R^{L07} to R^{L16}. R^{L26} and R^{L27} may bond together to form a substituted or unsubstituted cyclopentane ring or a substituted or unsubstituted cyclohexane ring with the carbon atom to which they are attached. R^{L28} is a divalent group which forms a substituted or unsubstituted cyclopentane, cyclohexane or norbornane ring with the carbon atom to which it is attached. The subscript t is 1 or 2.

In formula (L9), R^{L29} is a C₁-C₁₀ saturated hydrocarbyl group which may contain a heteroatom or a C₆-C₂₀ aryl group which may contain a heteroatom. Examples of the saturated hydrocarbyl and aryl groups are as exemplified for the saturated hydrocarbyl and aryl groups R^{L05}. R^{L30} and R^{L31} are each independently hydrogen or a C₁-C₁₀ hydrocarbyl group. The hydrocarbyl group may be saturated or unsaturated and straight, branched or cyclic. Examples thereof are as exemplified for the hydrocarbyl group R^{L07} to R^{L16}. R^{L30} and R^{L31} may bond together to form a substituted or unsubstituted cyclopentane ring or a substituted or unsubstituted cyclohexane ring with the carbon atom to which they are attached. R^{L32} is a divalent group which forms a substituted or unsubstituted cyclopentane, cyclohexane or norbornane ring with the carbon atom to which it is attached.

Of the acid labile groups of formula (L1), the straight or branched groups are exemplified below, but not limited thereto.

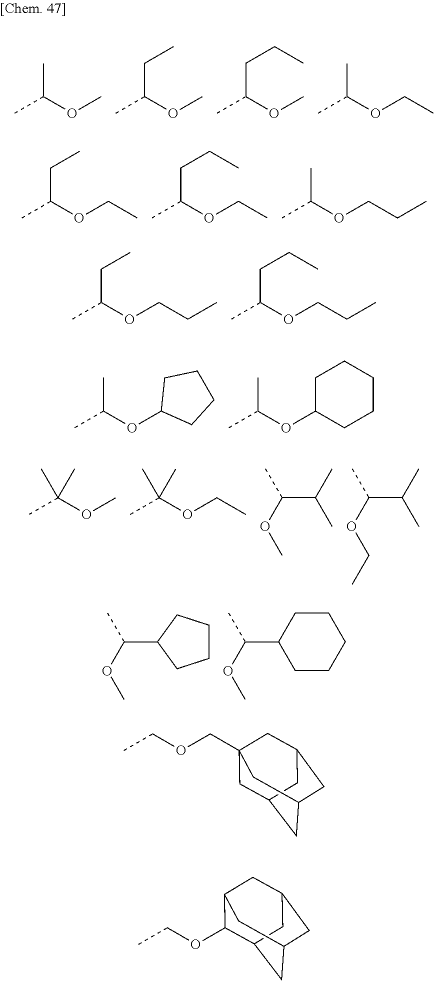

Of the acid labile groups of formula (L1), the cyclic groups are, for example, tetrahydrofuran-2-yl, 2-methyltetrahydrofuran-2-yl, tetrahydropyran-2-yl, and 2-methyltetrahydropyran-2-yl.

Examples of the acid labile group of formula (L2) include tert-butoxycarbonyl, tert-butoxycarbonylmethyl, tert-pentyloxycarbonyl, tert-pentyloxycarbonylmethyl, 1,1-diethylpropyloxycarbonyl, 1,1-diethylpropyloxycarbonylmethyl, 1-ethylcyclopentyloxycarbonyl, 1-ethylcyclopentyloxycarbonylmethyl, 1-ethyl-2-cyclopentenyloxycarbonyl, 1-ethyl-2-cyclopentenyloxycarbonylmethyl, 1-ethoxyethoxycarbonylmethyl, 2-tetrahydropyranyloxycarbonylmethyl, and 2-tetrahydrofuranyloxycarbonylmethyl.

Examples of the acid labile group of formula (L3) include 1-methylcyclopentyl, 1-ethylcyclopentyl, 1-n-propylcyclopentyl, 1-isopropylcyclopentyl, 1-n-butylcyclopentyl, 1-sec-butylcyclopentyl, 1-tert-butylcyclopentyl, 1-cyclohexylcyclopentyl, 1-(4-methoxy-n-butyl)cyclopentyl, 1-methylcyclohexyl, 1-ethylcyclohexyl, 3-methyl-1-cyclopenten-3-yl, 3-ethyl-1-cyclopenten-3-yl, 3-methyl-1-cyclohexen-3-yl, and 3-ethyl-1-cyclohexen-3-yl.

Of the acid labile groups of formula (L4), those groups of the following formulae (L4-1) to (L4-4) are preferred.

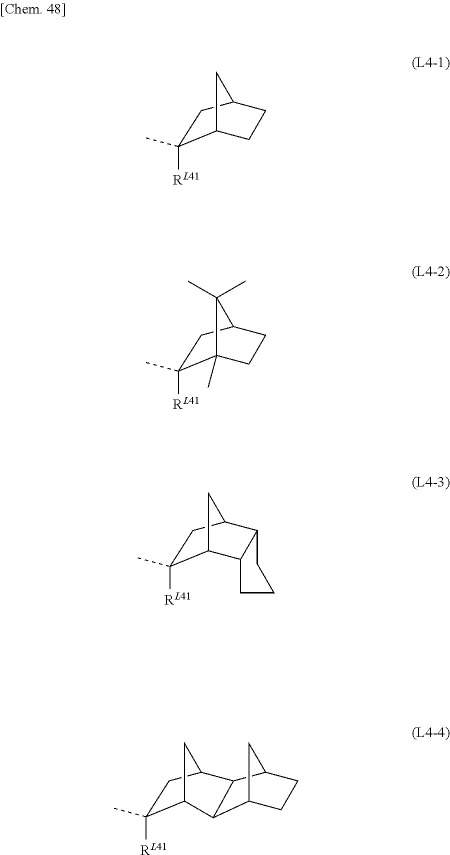

In formulas (L4-1) to (L4-4), the broken line denotes a point and direction of attachment. R^{L41} is each independently a C₁-C₁₀ hydrocarbyl group, which may be saturated or unsaturated and straight, branched or cyclic, with saturated hydrocarbyl groups being preferred. Examples of the hydrocarbyl group include alkyl groups such as methyl, ethyl, propyl, isopropyl, n-butyl, isobutyl, sec-butyl, tert-butyl, n-pentyl, tert-pentyl, n-hexyl; and cyclic saturated hydrocarbyl groups such as cyclopentyl and cyclohexyl.

For formulas (L4-1) to (L4-4), there can exist enantiomers and diastereomers. Each of formulae (L4-1) to (L4-4) collectively represents all such stereoisomers. When the acid labile group is of formula (L4), a plurality of stereoisomers may be included.

For example, the formula (L4-3) represents one or a mixture of two selected from groups having the following formulas (L4-3-1) and (L4-3-2).

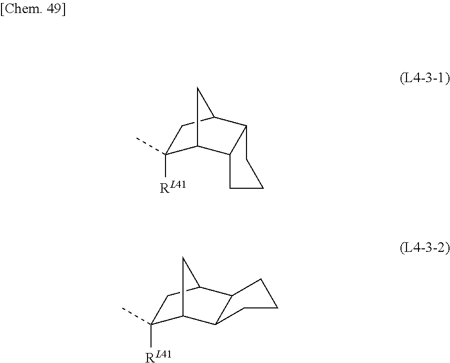

Herein, R^{L41} is as defined above and the broken line designates a point or direction of attachment.

Similarly, the formula (L4-4) represents one or a mixture of two or more selected from groups having the following formulas (L4-4-1) to (L4-4-4).

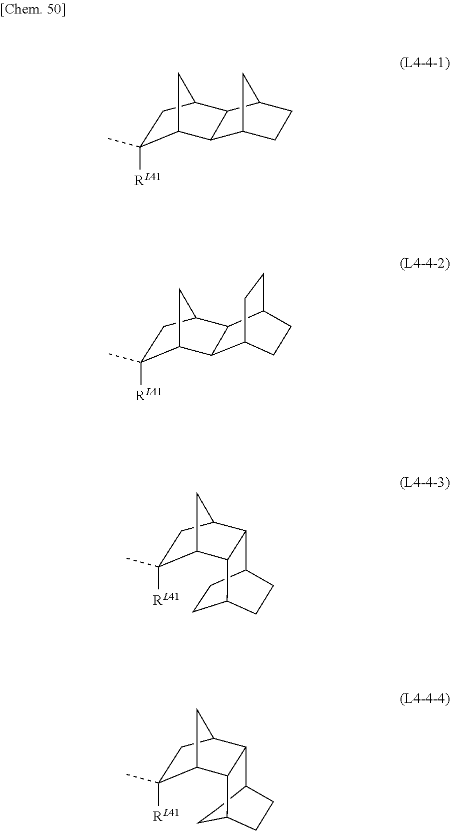

Herein R^{L41} is as defined above and the broken line designates a point or direction of attachment.

Each of formulas (L4-1) to (L4-4), (L4-3-1) and (L4-3-2), and (L4-4-1) to (L4-4-4) collectively represents an enantiomer thereof and a mixture of enantiomers.

It is noted that in the above formulas (L4-1) to (L4-4), (L4-3-1) and (L4-3-2), and (L4-4-1) to (L4-4-4), the direction of attachment is on the exo side relative to the bicyclo[2.2.1]heptane ring, which ensures high reactivity for acid catalyzed elimination reaction (see JP-A 2000-336121). In preparing these monomers having a tertiary exo-saturated hydrocarbyl group of bicyclo[2.2.1]heptane structure as a substituent group, there may be contained monomers substituted with an endo-saturated hydrocarbyl group as represented by the following formulas (L4-1-endo) to (L4-4-endo). For good reactivity, an exo proportion of at least 50 mol % is preferred, with an exo proportion of at least 80 mol % being more preferred.

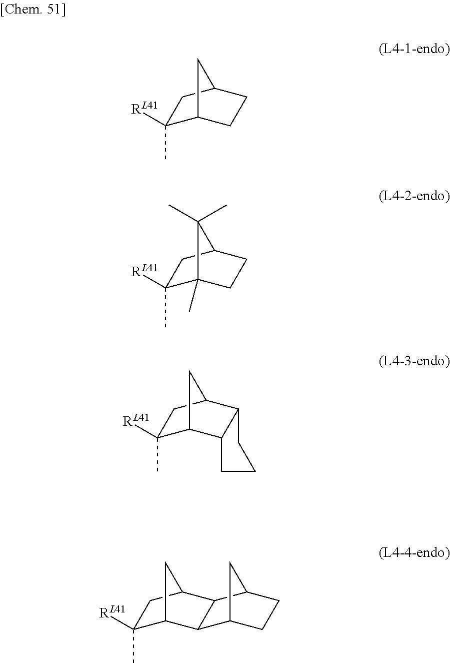

Herein R^{L41} is as defined above and the broken line designates a point or direction of attachment.

Examples of the acid labile group of formula (L4) are given below, but not limited thereto.

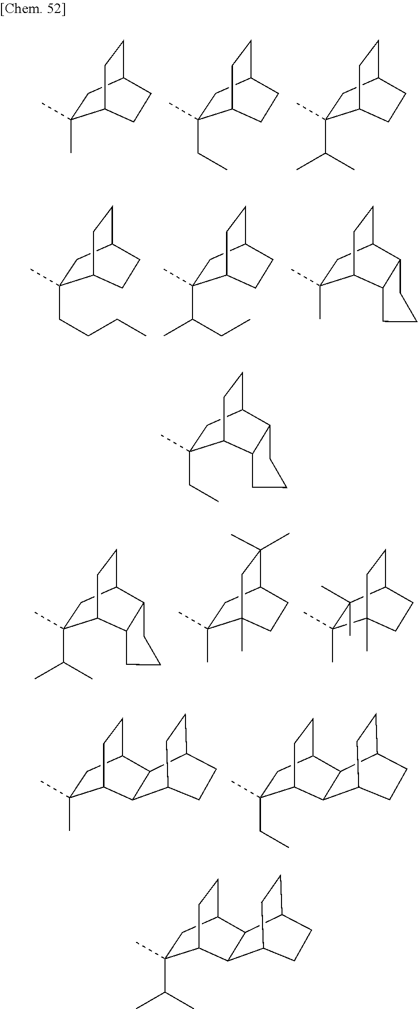

Herein the broken line designates a point of attachment.

Examples of the acid labile group of formula (L5) include tert-butyl, tert-pentyl and the groups shown below, but are not limited thereto.

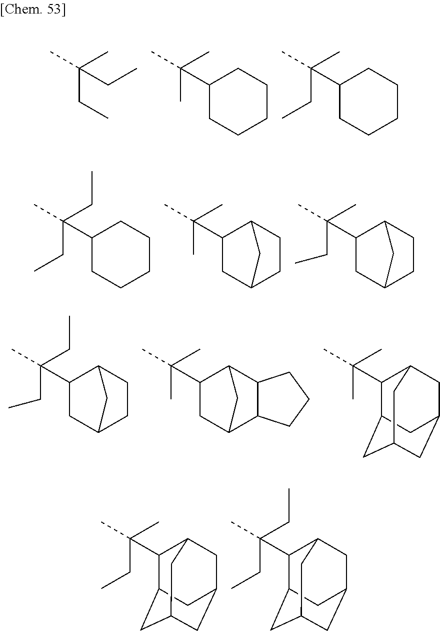

Herein the broken line designates a point of attachment.

Examples of the acid labile group of formula (L6) are given below, but not limited thereto.

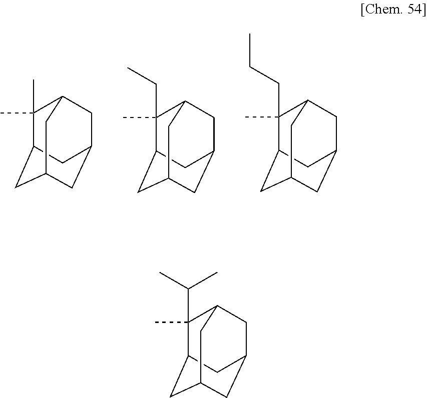

Herein the broken line designates a point of attachment.

Examples of the acid labile group of formula (L7) are given below, but not limited thereto.

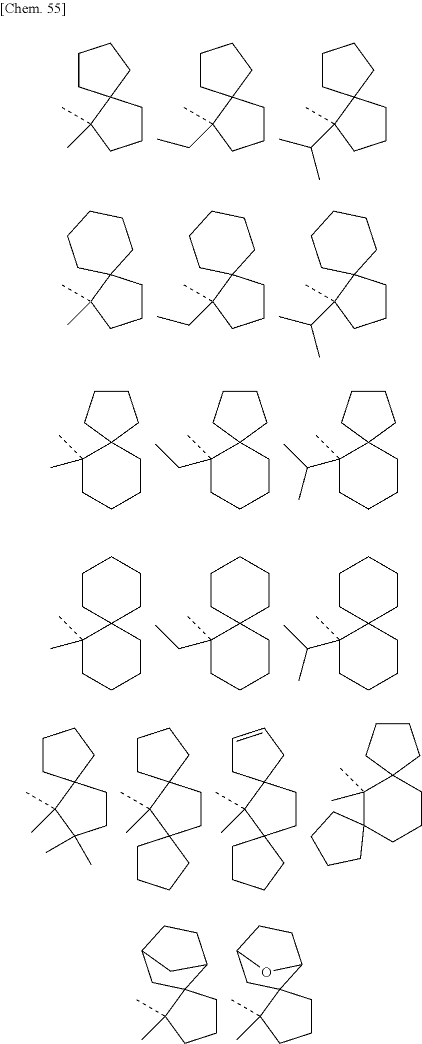

Herein the broken line designates a point of attachment.

Examples of the acid labile group of formula (L8) are given below, but not limited thereto.

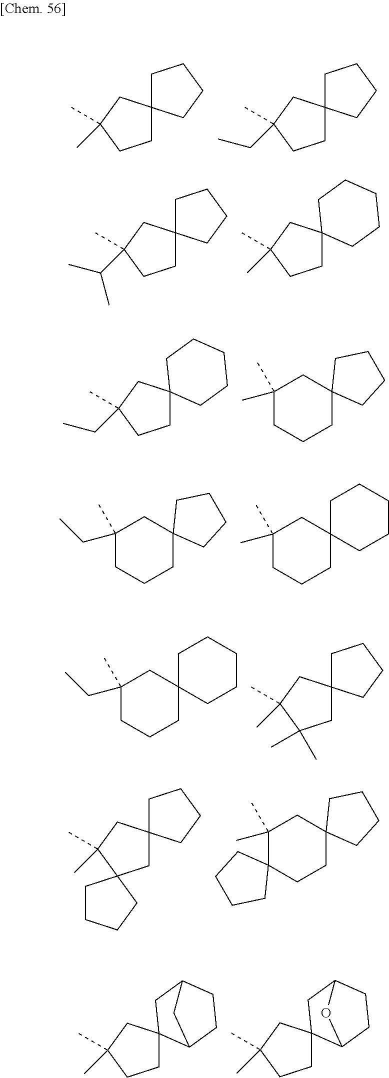

Herein the broken line designates a point of attachment.

Examples of the acid labile group of formula (L9) are given below, but not limited thereto.

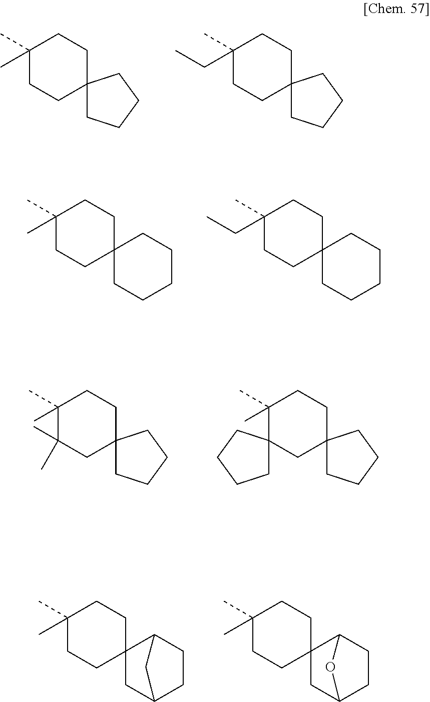

Herein the broken line designates a point of attachment.

Illustrative examples of the monomer having formula (C1) are given below, but not limited thereto. R^{A} is as defined above.

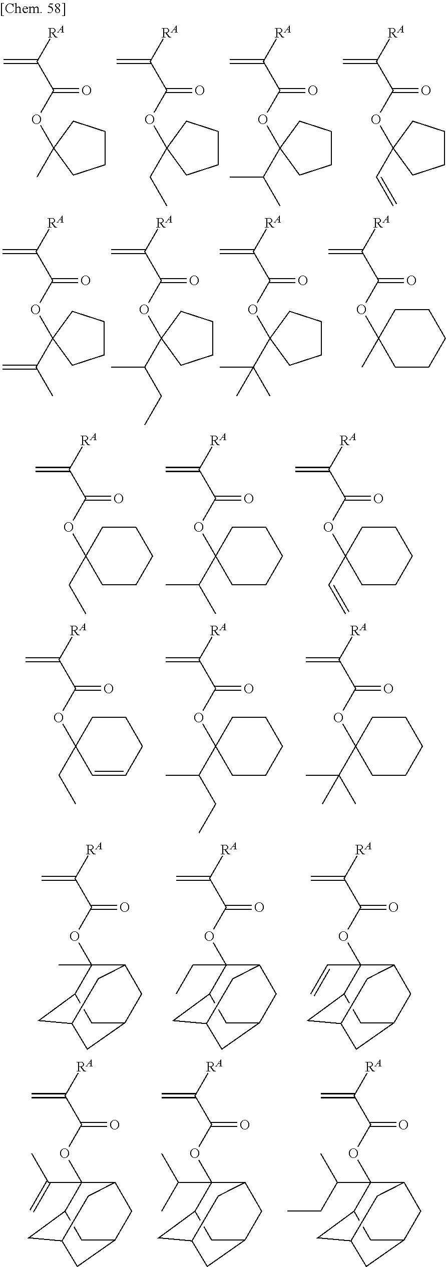

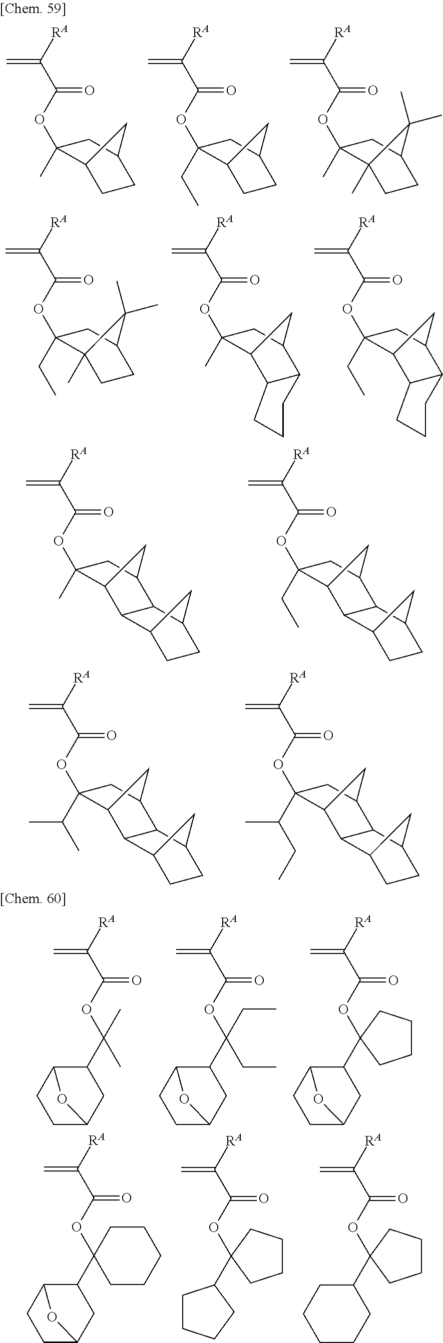

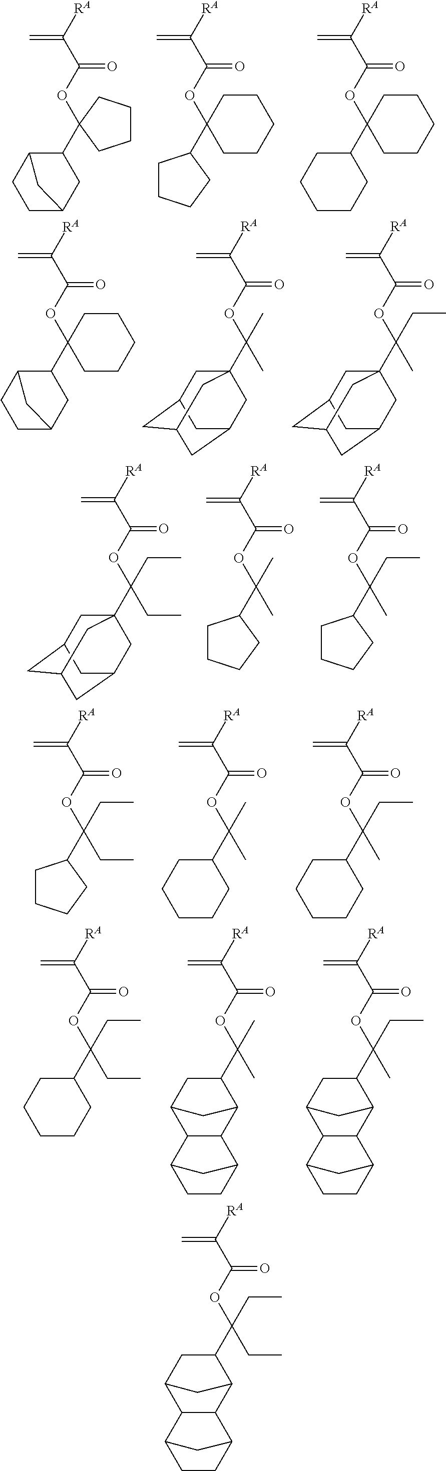

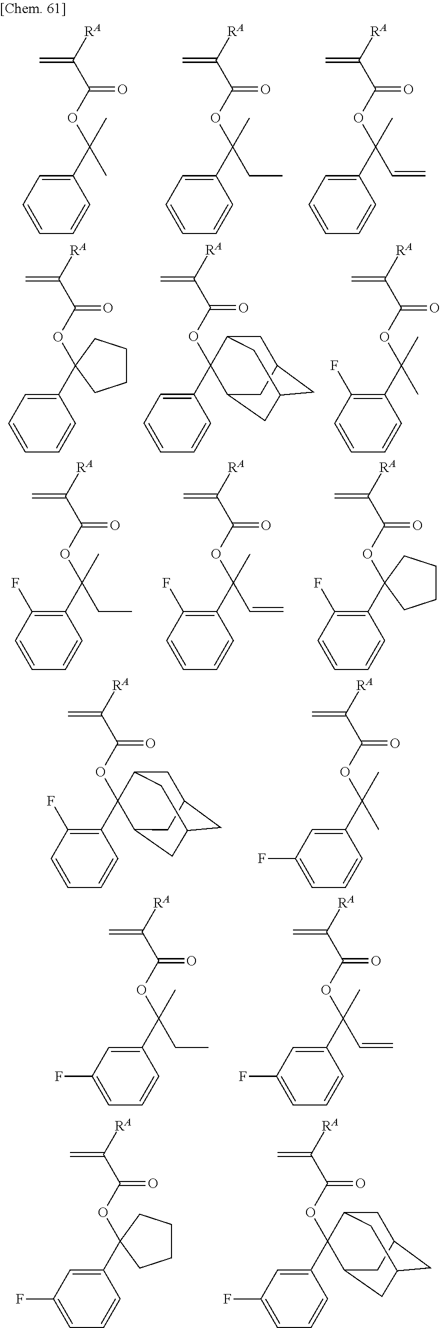

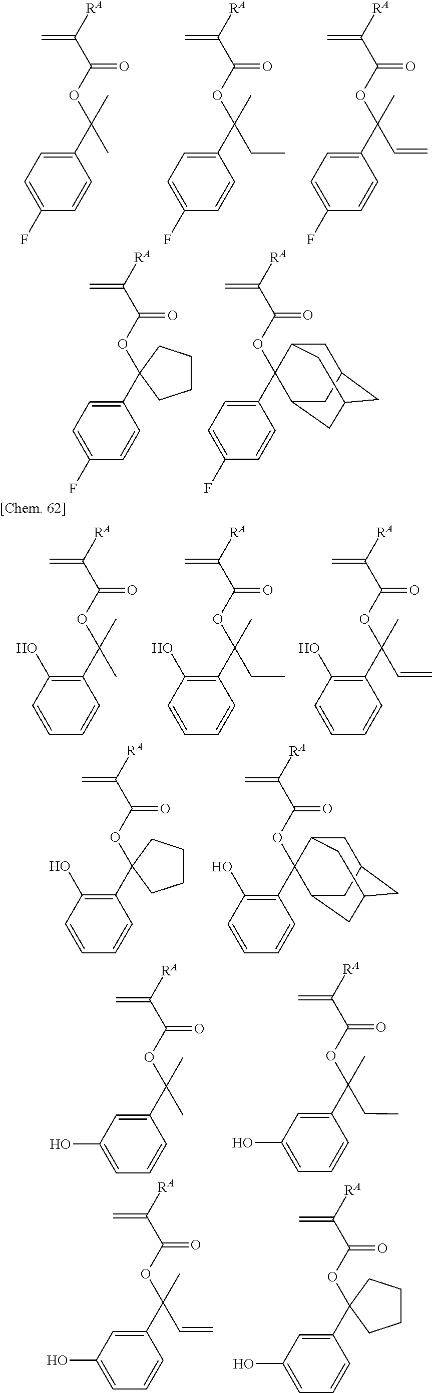

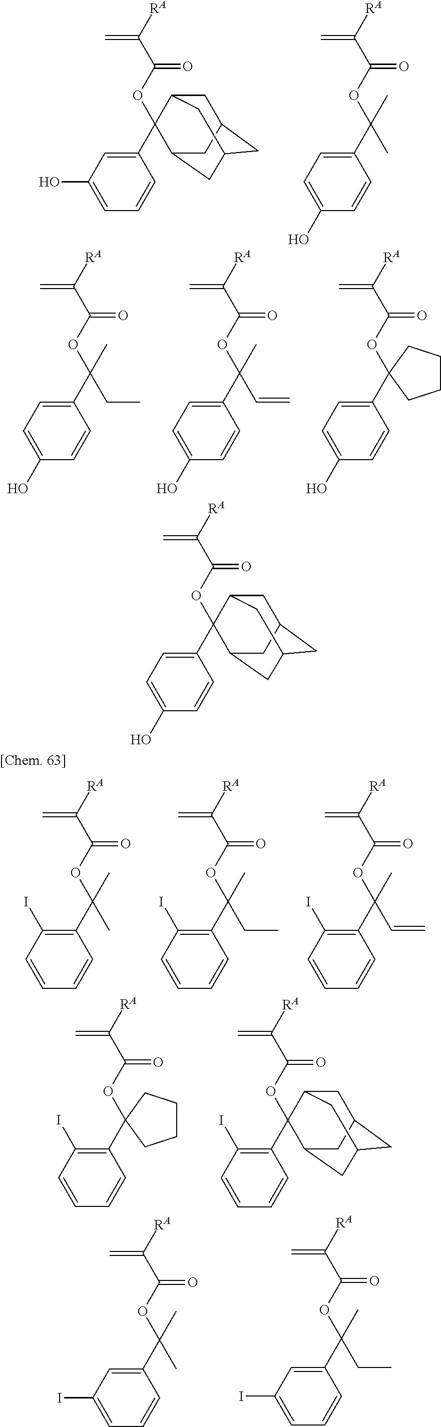

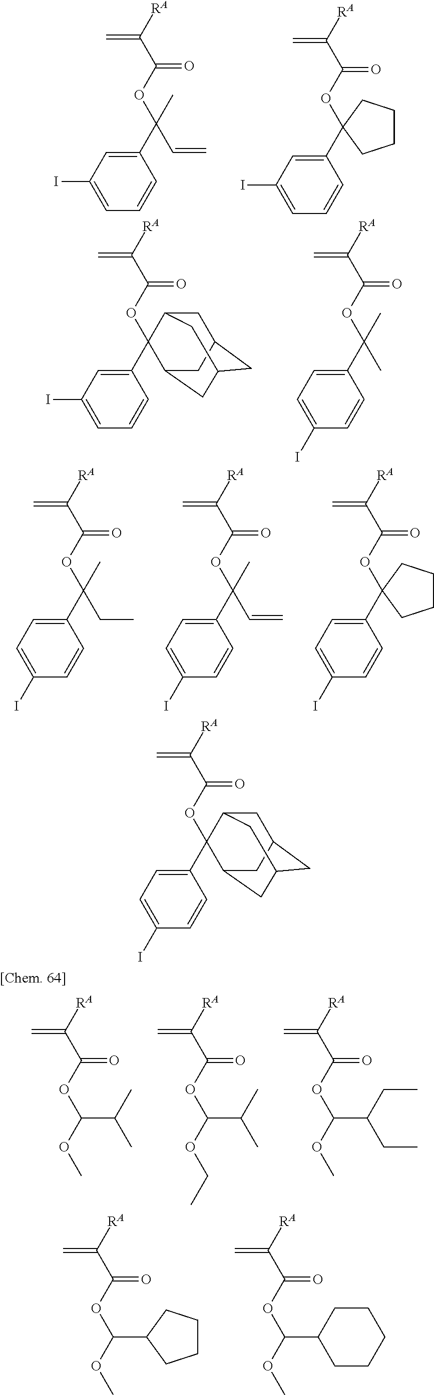

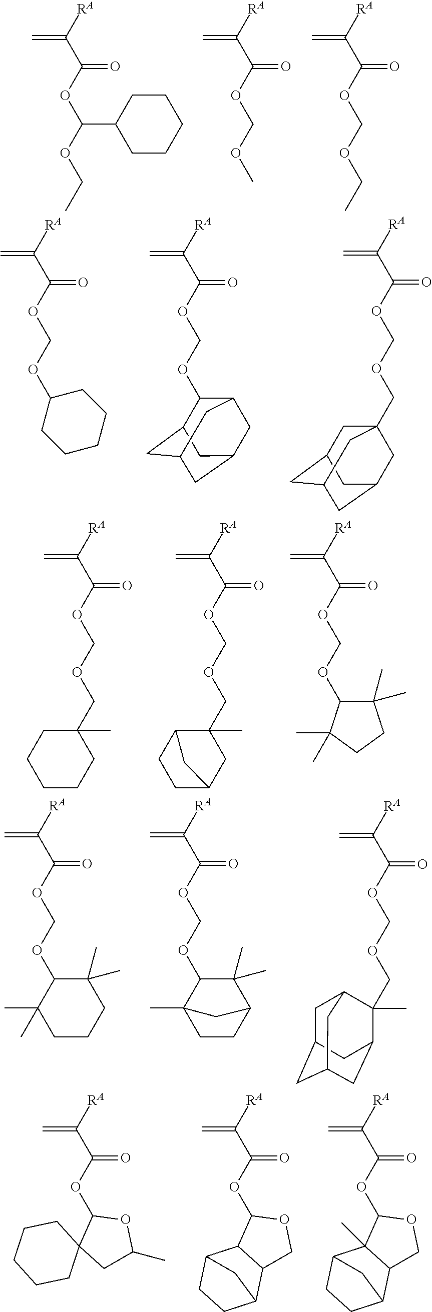

Examples of the monomer having formula (C2) are given below, but not limited thereto. R^{A} is as defined above.

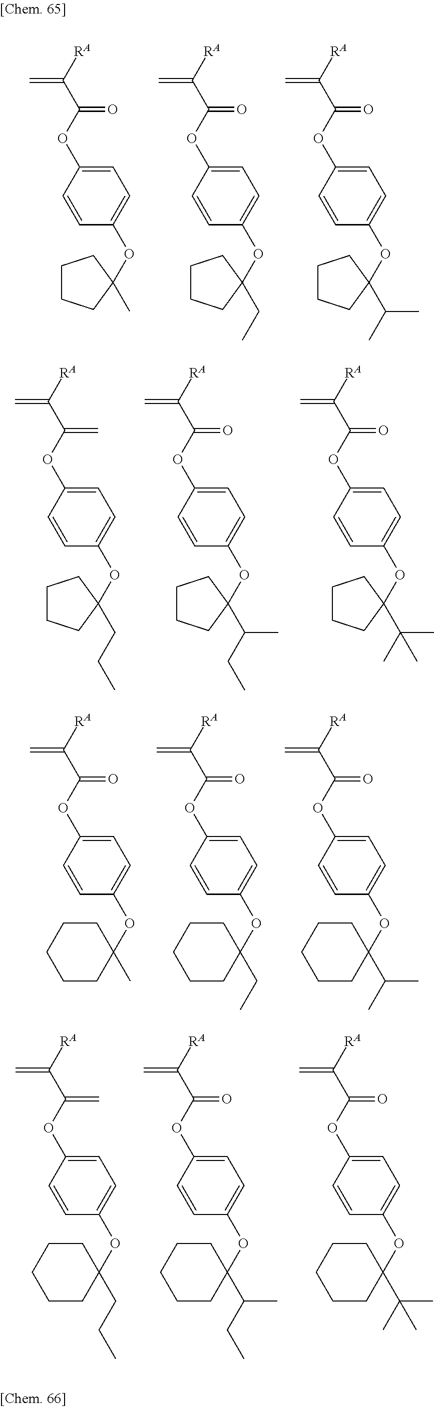

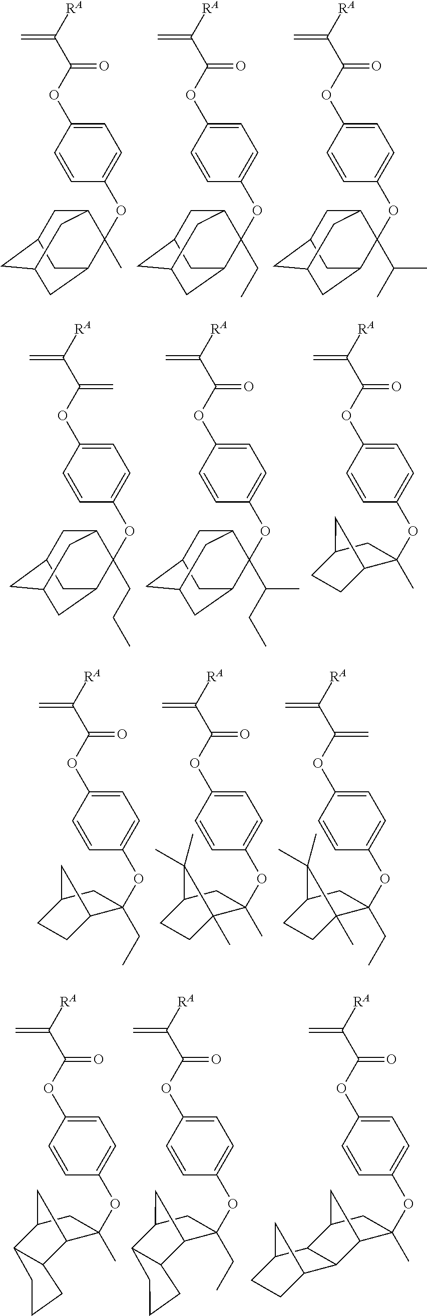

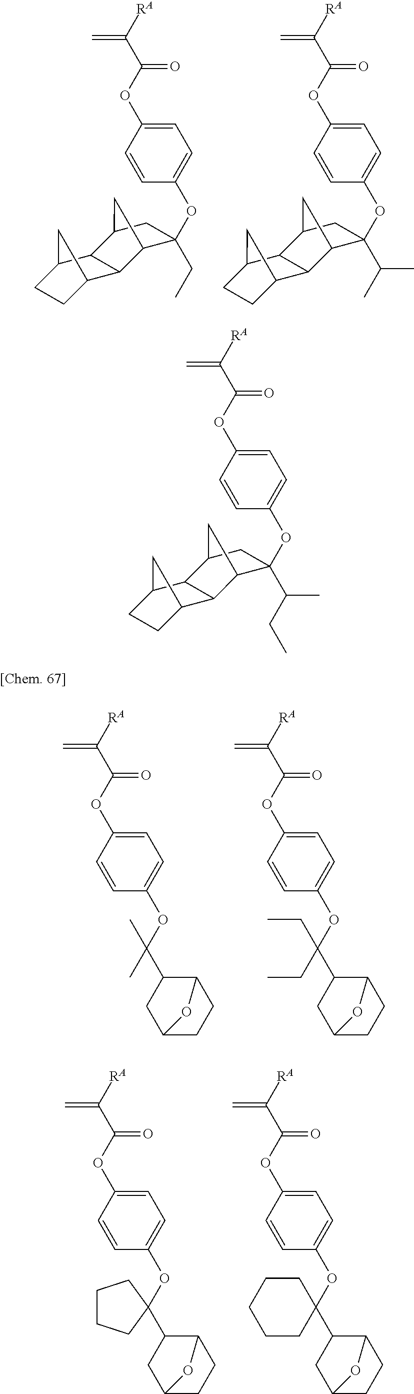

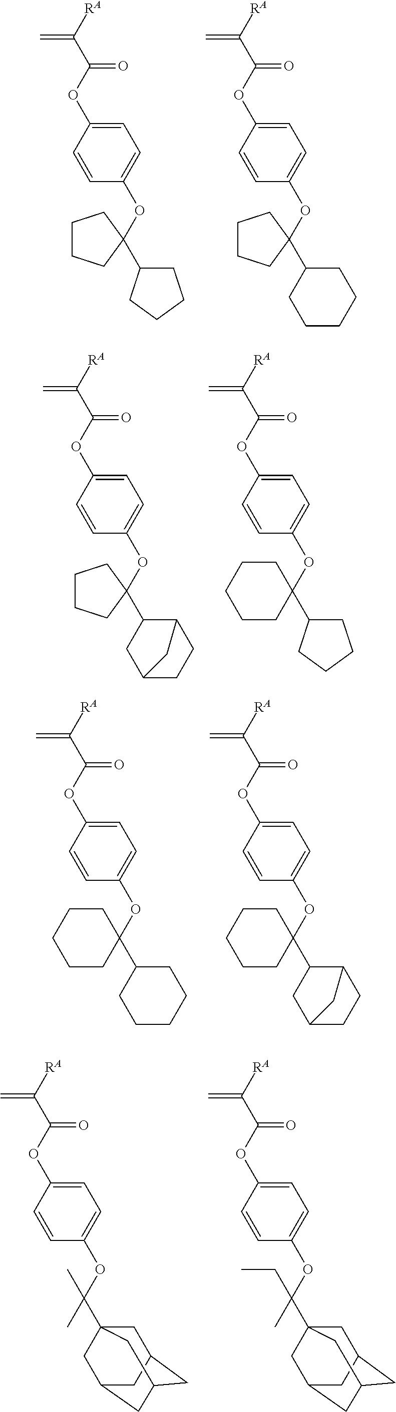

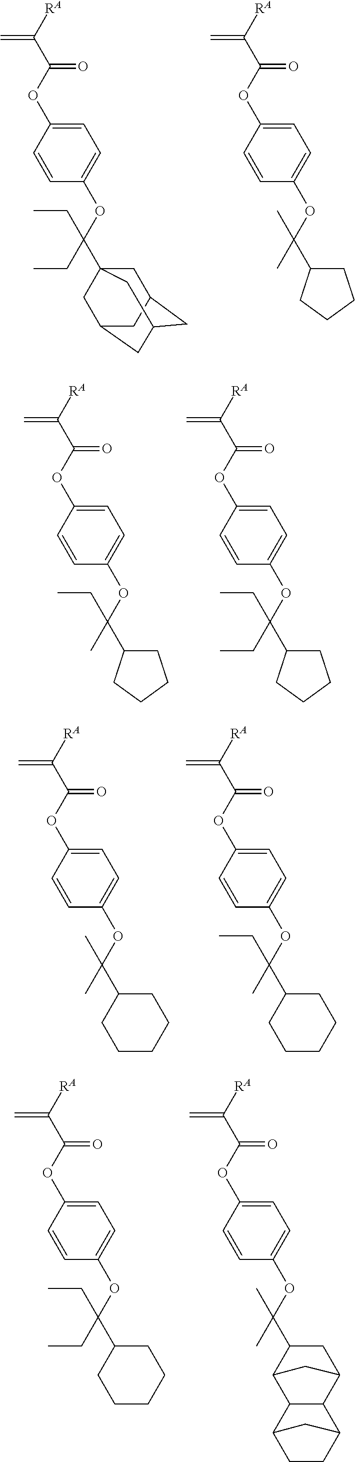

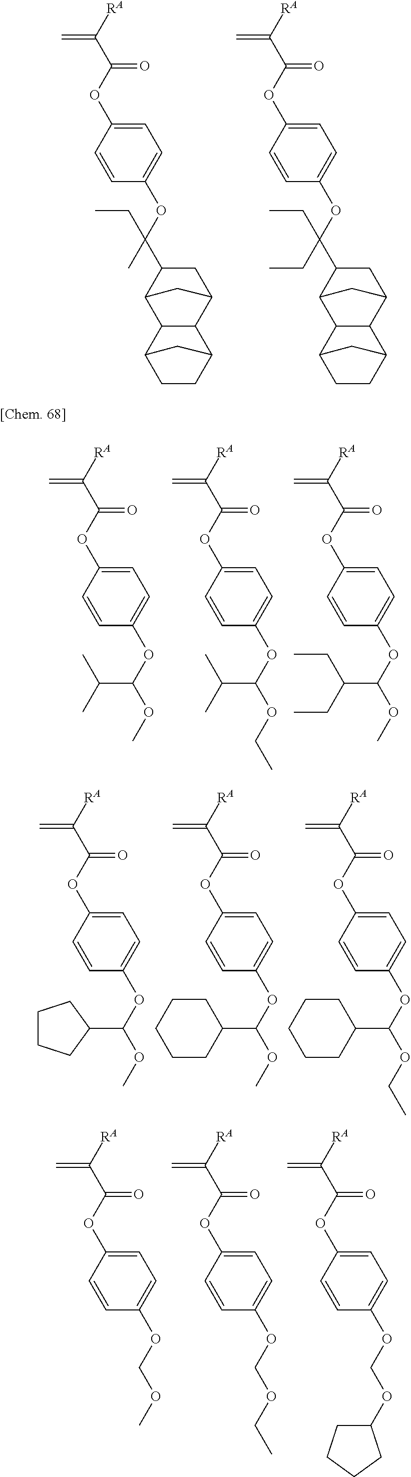

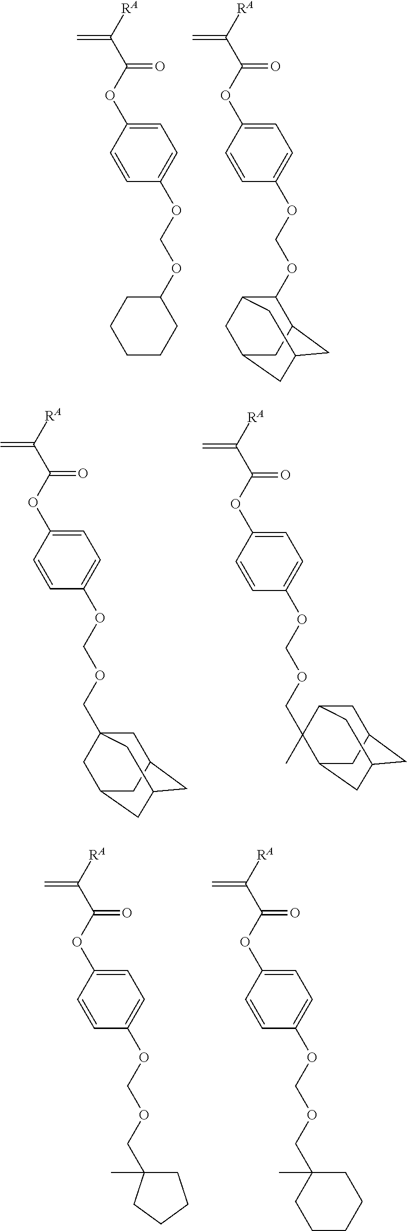

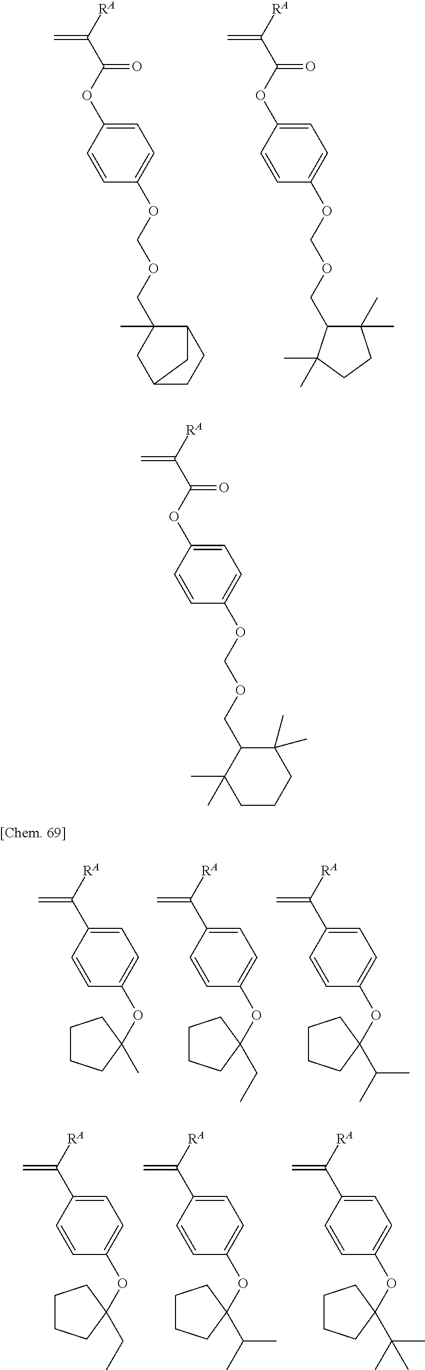

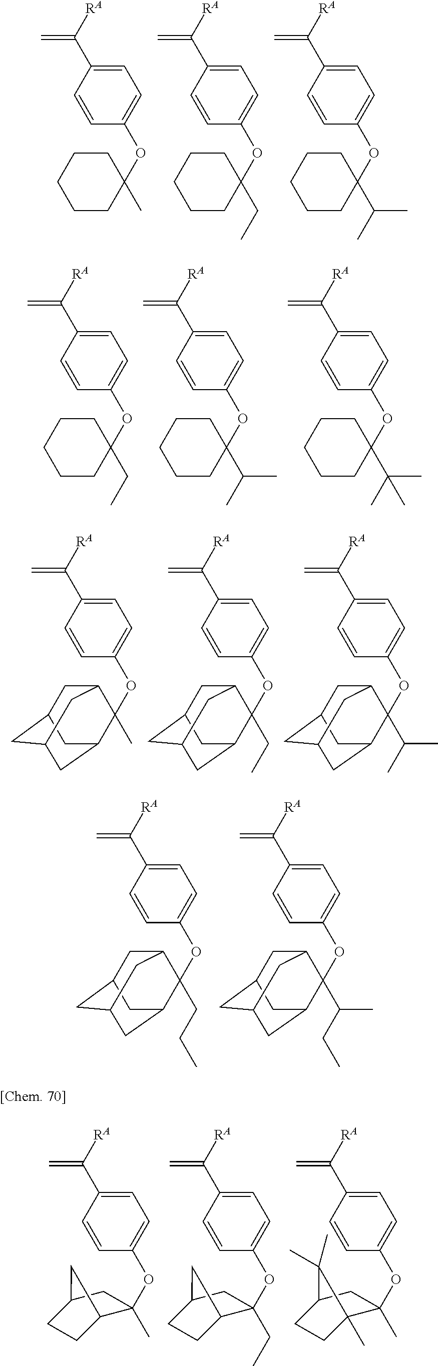

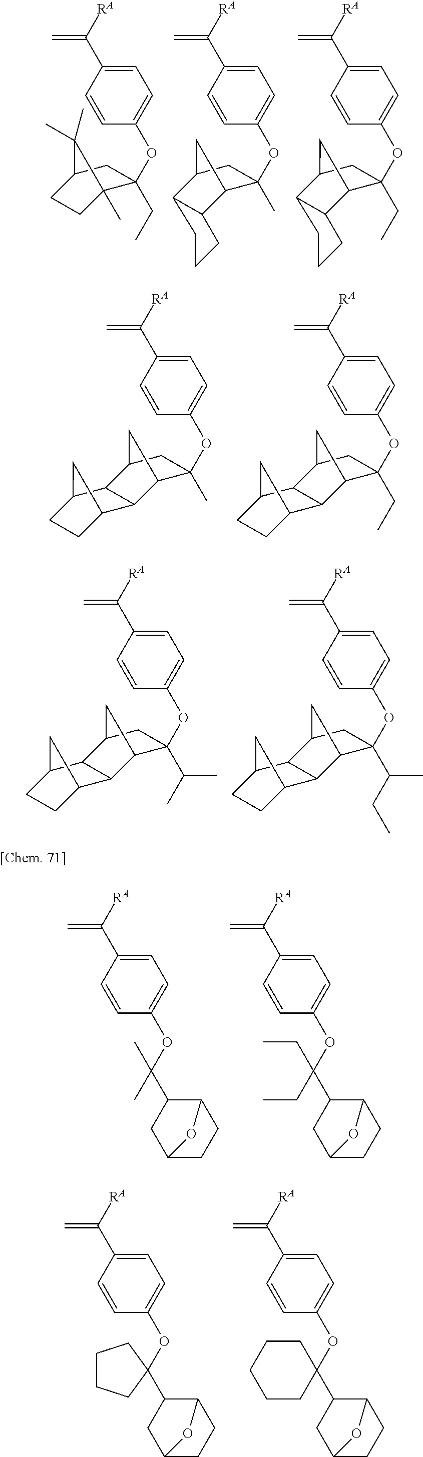

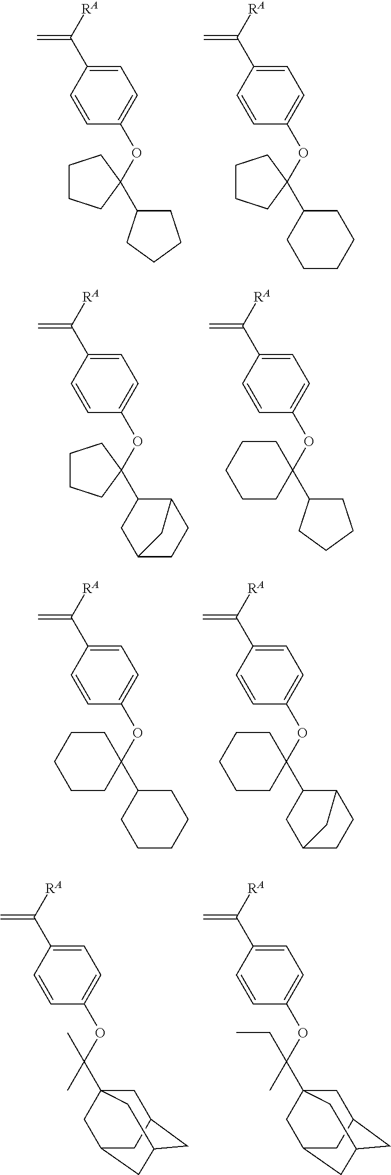

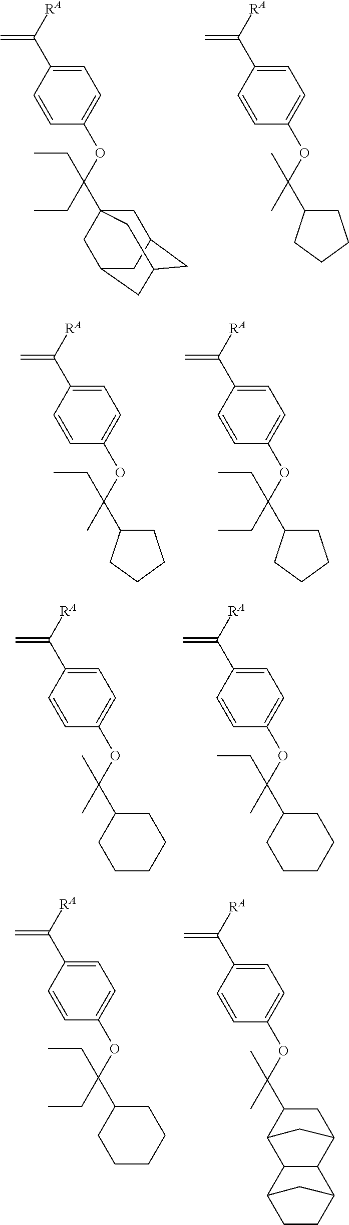

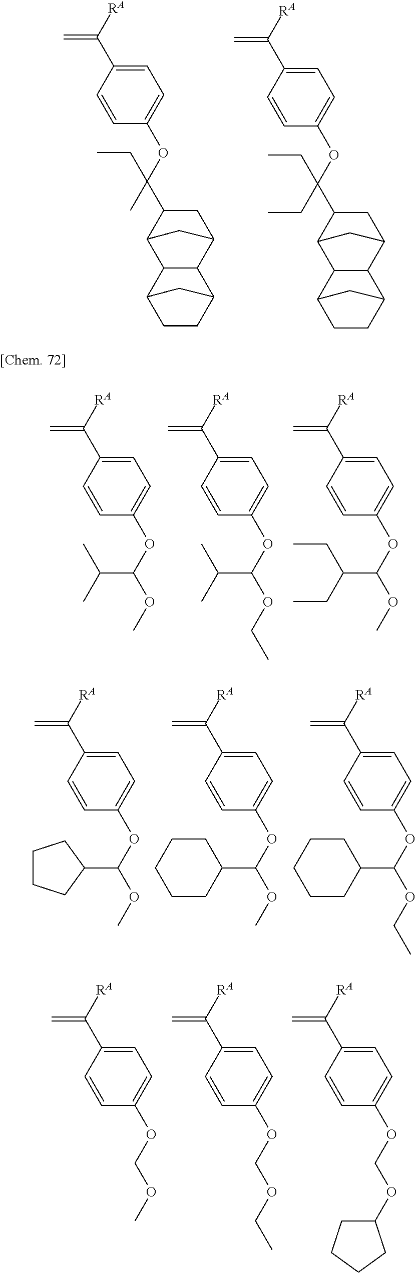

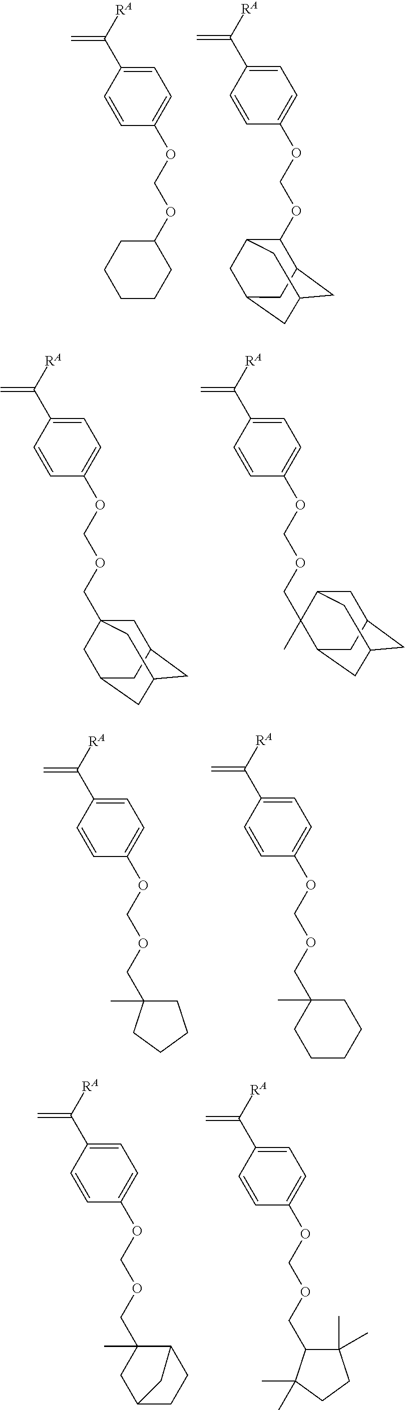

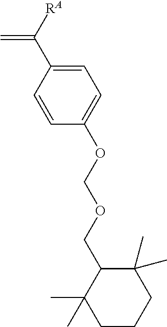

Examples of the monomer having formula (C3) are given below, but not limited thereto. R^{A} is as defined above.

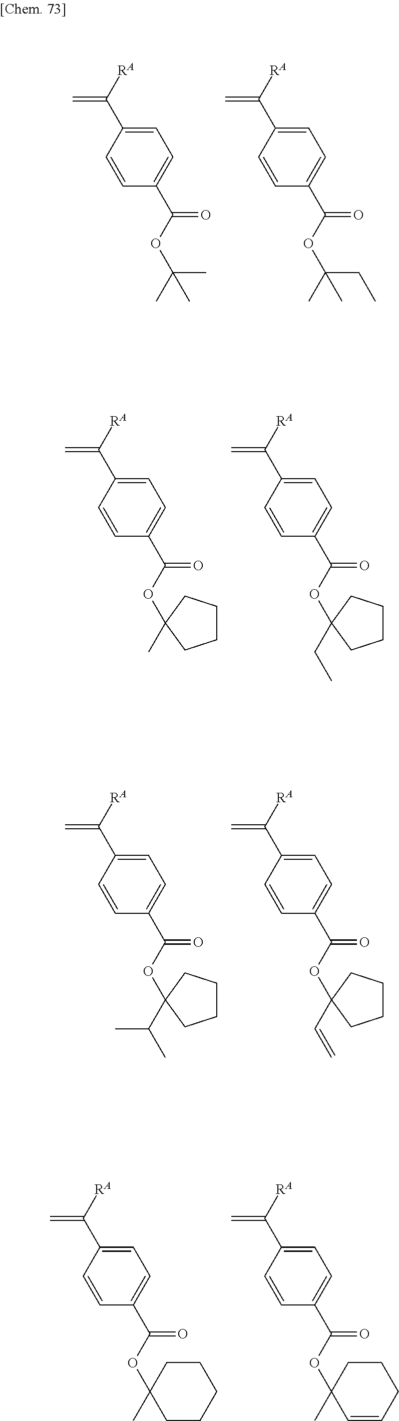

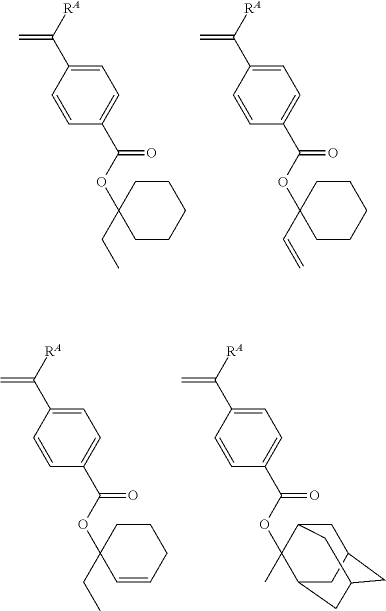

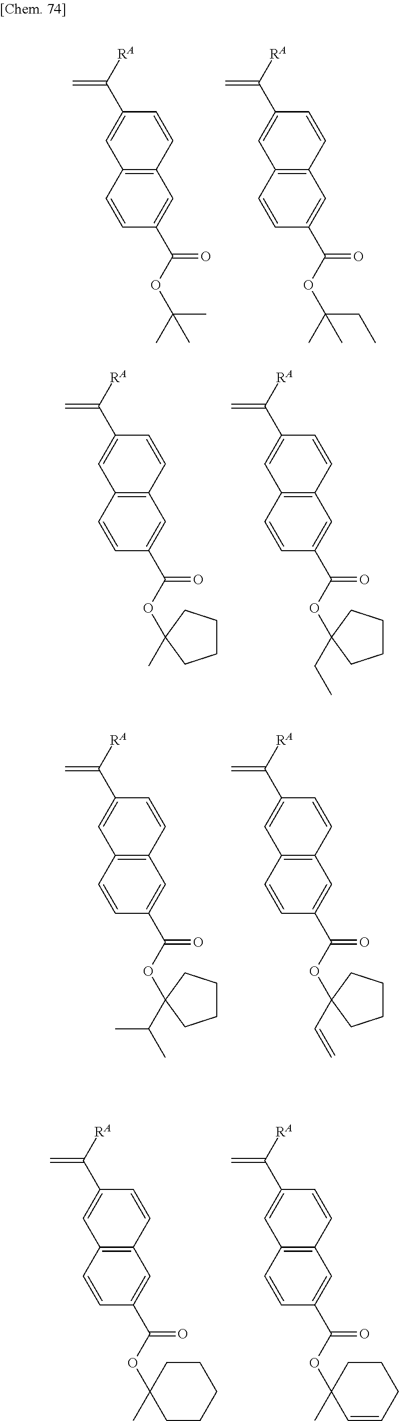

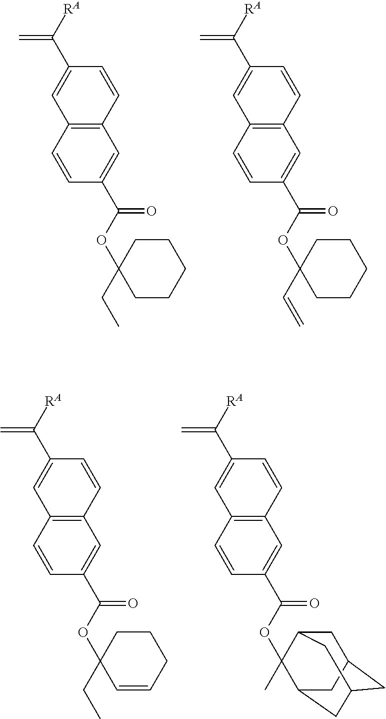

Of the acid labile groups R^{AL}, suitable C₄-C₂₀ tertiary alkyl groups, trialkylsilyl groups in which each alkyl moiety has 1 to 6 carbon atoms, and C₄-C₂₀ oxoalkyl groups are as exemplified for R^{L04}.

In addition to monomers (A) to (C), the starting material may contain at least one of a monomer having the formula (D), referred to as monomer (D), hereinafter, a monomer having the formula (E), referred to as monomer (E), hereinafter, and a monomer having the formula (F), referred to as monomer (F), hereinafter, if necessary.

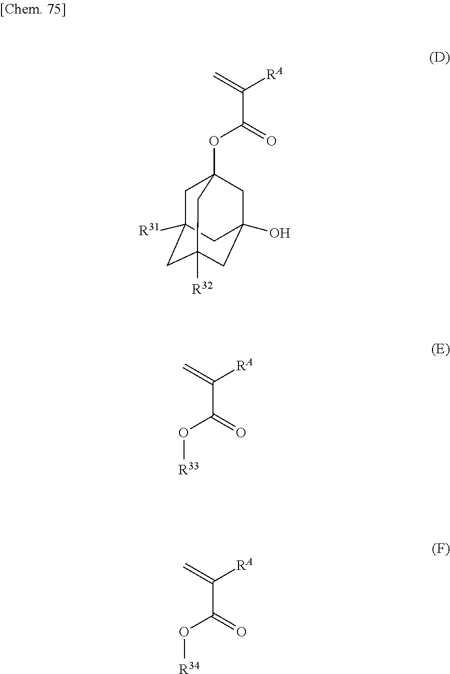

In formulae (D) to (F), R^{A} is hydrogen, fluorine, methyl or trifluoromethyl. R³¹ and R³² are each independently hydrogen or hydroxy. R³³ is a substituent group having a lactone or sultone structure. R³⁴ is hydrogen, a C₁-C₁₅ monovalent fluorinated hydrocarbon group or a C₁-C₁₅ monovalent fluoroalcohol-containing group.

Examples of the monomer (D) are given below, but not limited thereto. R^{A} is as defined above.

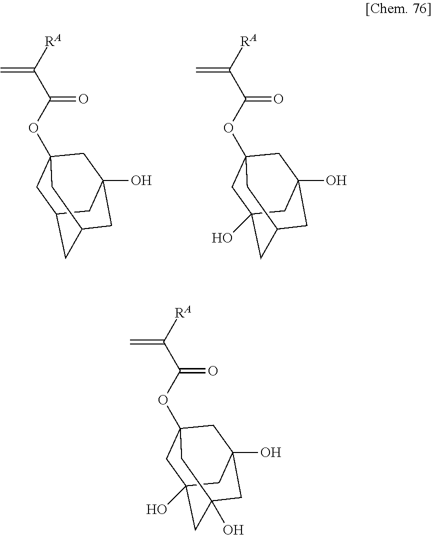

Examples of the monomer (E) are given below, but not limited thereto. R^{A} is as defined above.

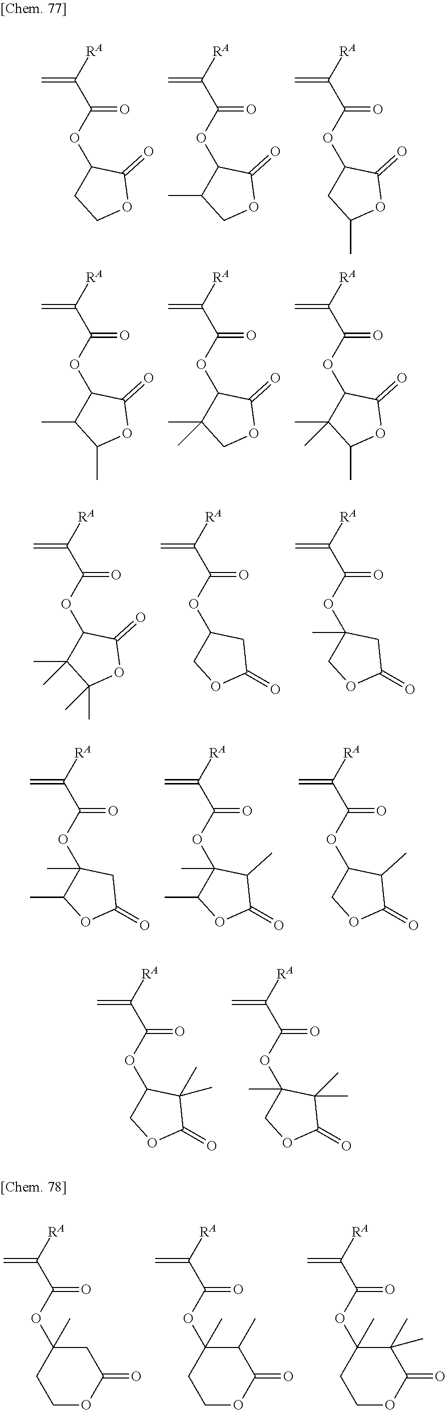

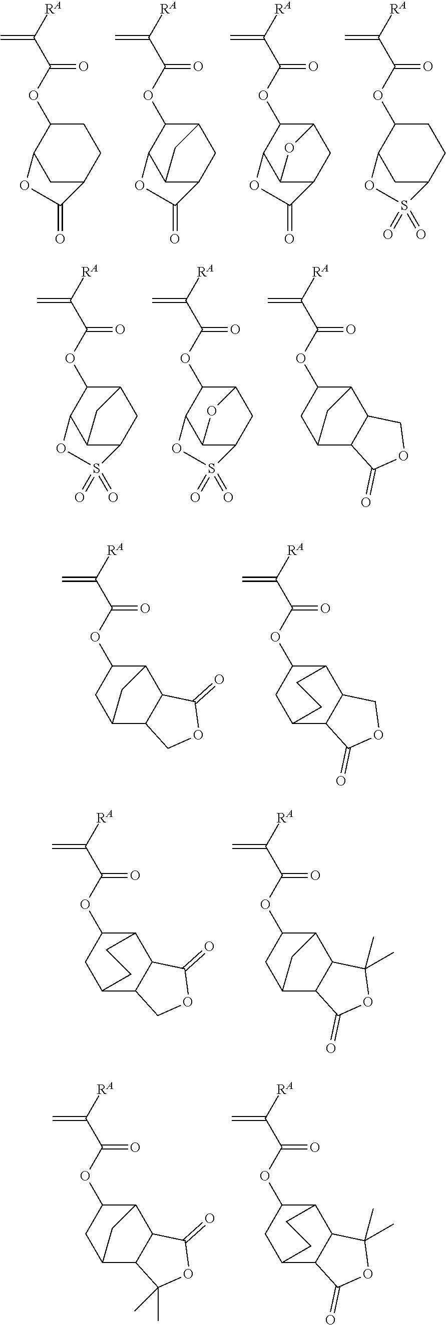

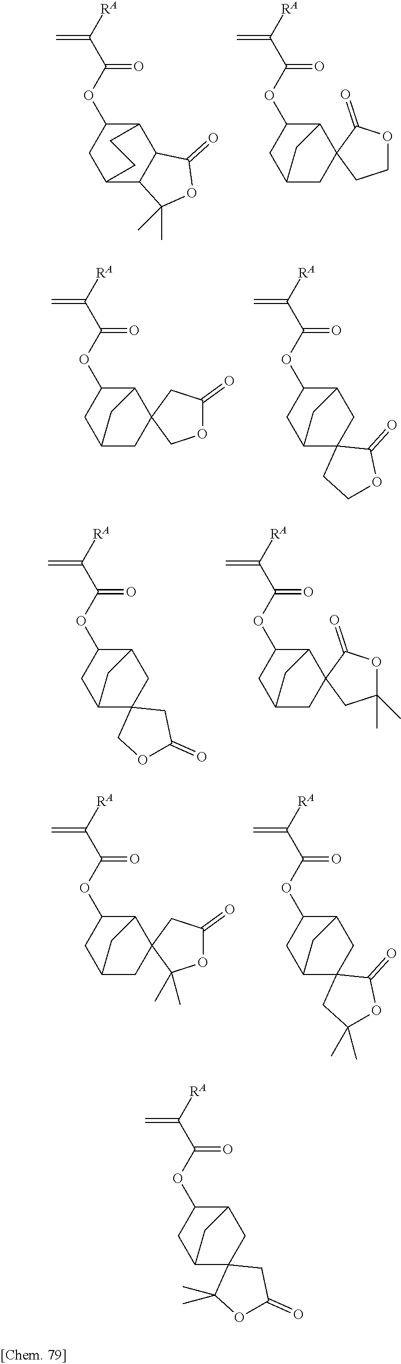

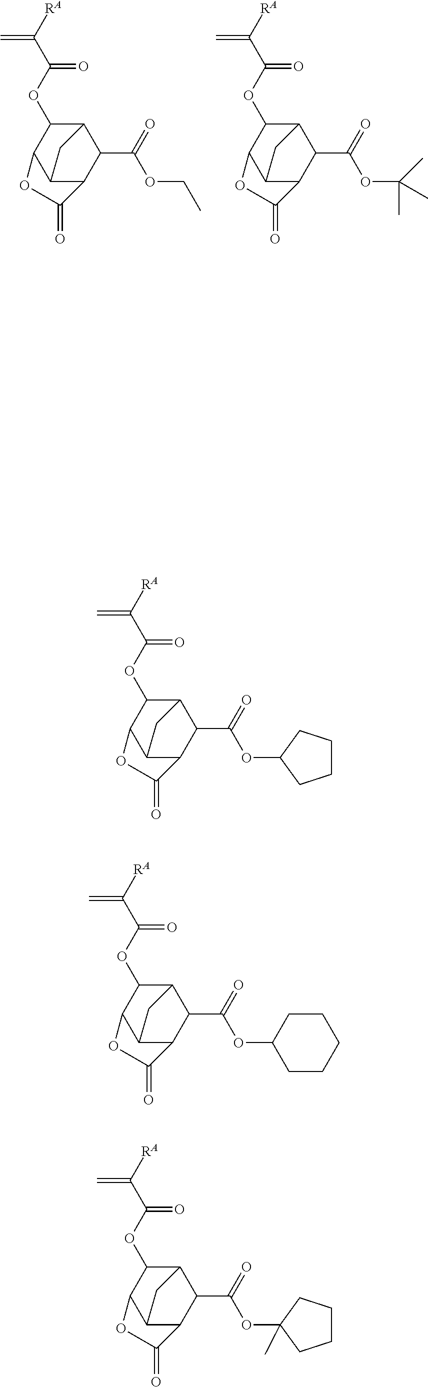

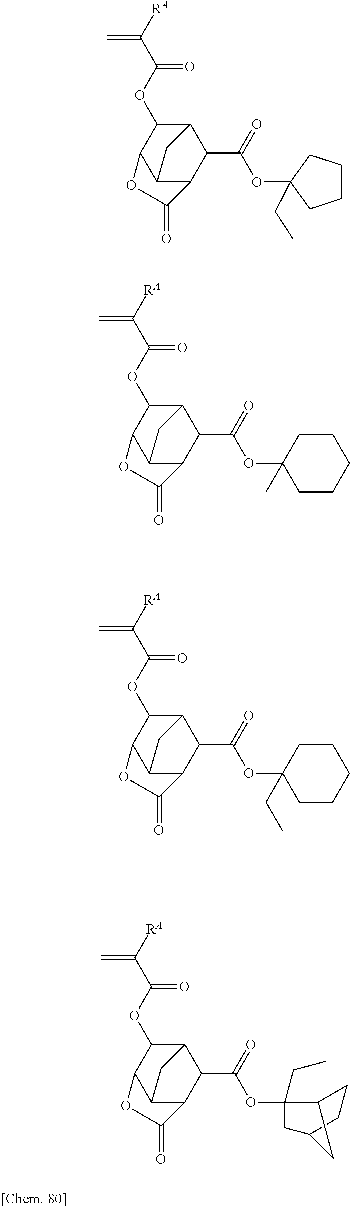

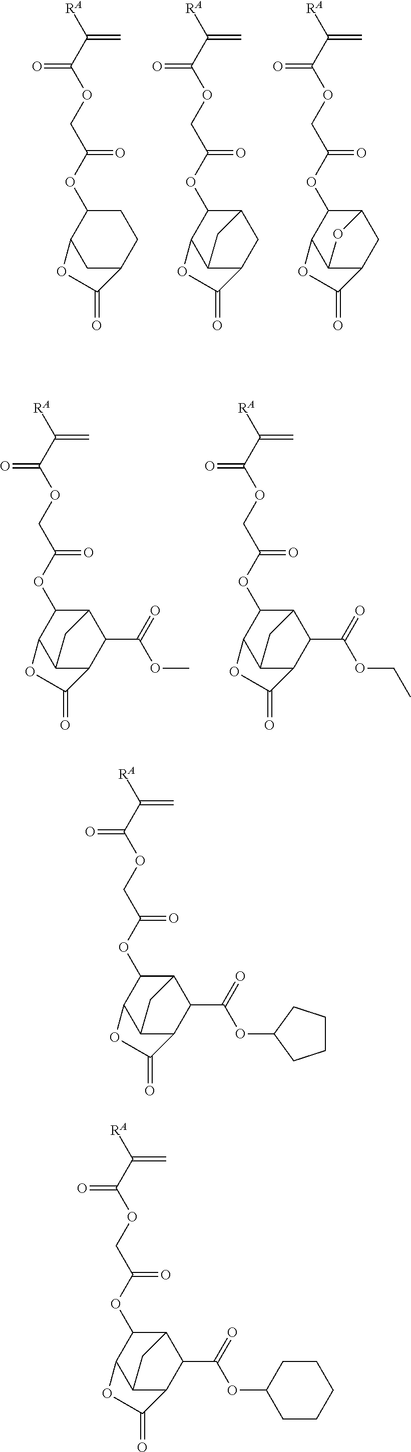

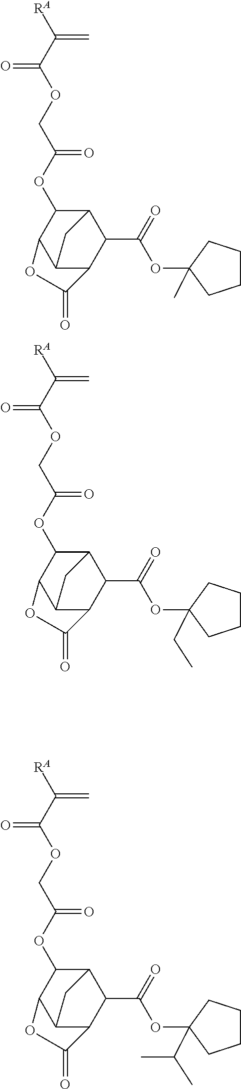

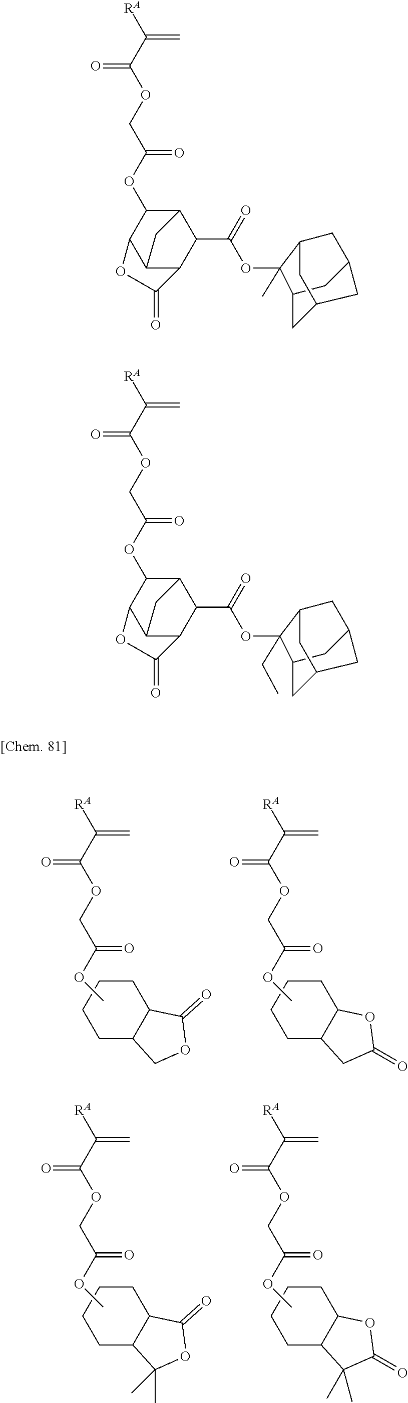

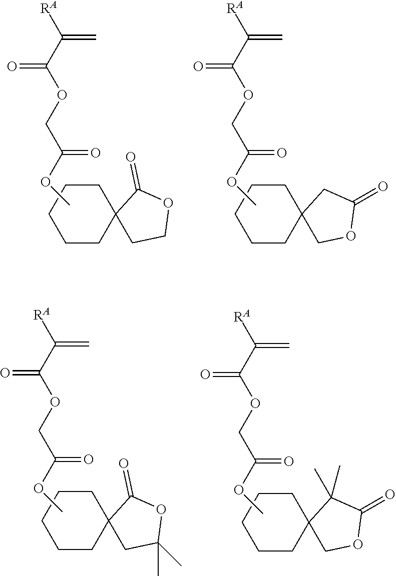

Examples of the monomer (F) are given below, but not limited thereto. R^{A} is as defined above.

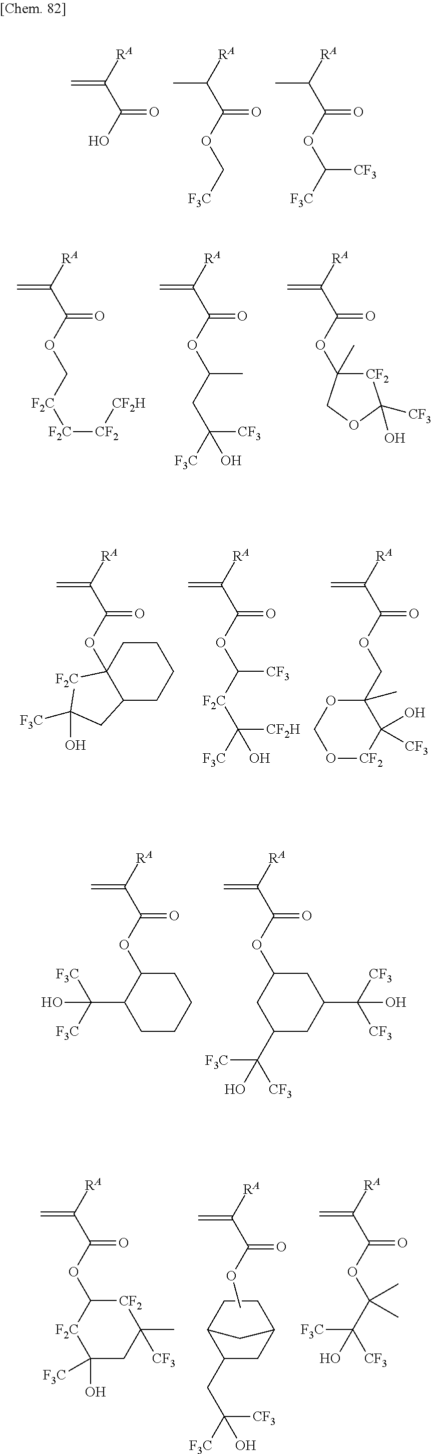

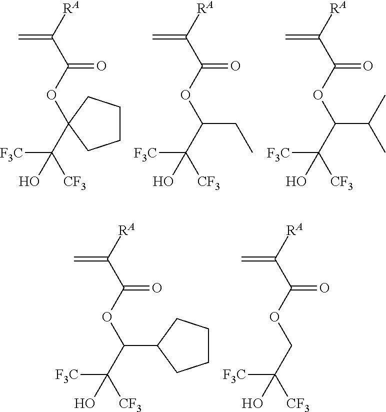

If necessary, the starting material may contain a monomer having a carbon-carbon double bond other than the above-mentioned monomers, for example, substituted acrylates such as methyl methacrylate, methyl crotonate, dimethyl maleate, and dimethyl itaconate; unsaturated carboxylic acids such as maleic acid, fumaric acid and itaconic acid; cyclic olefins such as norbornene, norbornene derivatives, and tetracyclo[4.4.0.1^{2,5}.17^{7,10}]dodecene derivatives; unsaturated acid anhydrides such as itaconic anhydride; α-methyl-γ-butyrolactones; and other monomers such as α-methylstyrene.

In step (1), the proportions of the monomers used fall in the following range (mol %), but are not limited thereto.
(I) 1 to 50 mol %, preferably 1 to 30 mol %, more preferably 1 to 20 mol % of monomer (A), based on the overall monomers,
(II) 1 to 98 mol %, preferably 1 to 80 mol %, more preferably 10 to 70 mol % of monomer (B), based on the overall monomers,
(III) 1 to 98 mol %, preferably 1 to 80 mol %, more preferably 10 to 70 mol % of monomer (C), based on the overall monomers, and
(IV) 0 to 97 mol %, preferably 0 to 70 mol %, more preferably 0 to 50 mol % of one or more monomers other than monomers (A) to (C), based on the overall monomers.

### <RAFT Agent>

The RAFT agent is to introduce a structure having the formula (X-1) or (X-2) at the end of the polymer.

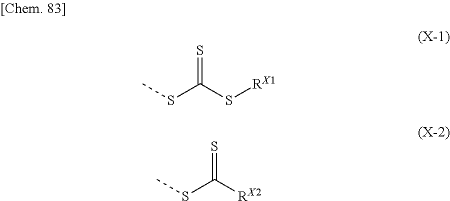

In formulae (X-1) and (X-2), R^{X1} and R^{X2} are each independently a C₂-C₂₀ saturated hydrocarbyl group which may contain a heteroatom, C₇-C₂₀ aralkyl group, or C₆-C₂₀ aryl group. The broken line designates a point of attachment to the carbon atom in the backbone.

The C₂-C₂₀ saturated hydrocarbyl group represented by R^{X1} and R^{X2} may be straight, branched or cyclic. Examples thereof include alkyl groups such as ethyl, n-propyl, isopropyl, n-butyl, tert-butyl, n-pentyl, n-hexyl, n-octyl, n-nonyl, n-decyl, undecyl, dodecyl, n-tetradecyl, n-hexadecyl, n-octadecyl, and n-eicosanyl; and cyclic saturated hydrocarbyl groups such as cyclopentyl, cyclohexyl, cyclooctyl, cyclodecyl, cyclododecyl, 1-adamantyl, 2-adamantyl, 1-methylcyclopentyl, 1-isopropylcyclopentyl, 1-methylcyclohexyl, 1-isopropylcyclohexyl, 1-methyladamantyl and 1-ethyladamantyl.

Examples of the C₇-C₂₀ aralkyl group represented by R^{X1} and R^{X2} include benzyl, phenethyl, 4-methoxybenzyl and 9-anthracenylmethyl. Examples of the C₆-C₂₀ aryl group represented by R^{X1} and R^{X2} include phenyl, naphthyl, 4-methoxyphenyl, 2-anthracenyl and 9-anthracenyl.

Since (meth)acrylate type monomers and aromatic vinyl type monomers such as styrene are used, compounds having the formulae (CTA-1) and (CTA-2) are preferred as the RAFT agent.

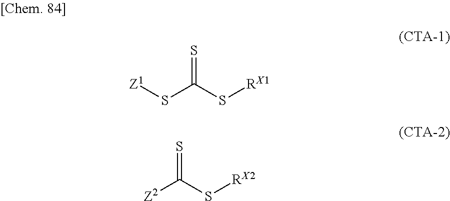

In formulae (CTA-1) and (CTA-2), R^{X1} and R^{X2} are each independently a C₂-C₂₀ saturated hydrocarbyl group which may contain a heteroatom, C₇-C₂₀ aralkyl group, or C₆-C₂₀ aryl group. Z¹ and Z² are each independently a C₃-C₂₀ saturated hydrocarbylthio group, C₇-C₂₀ aralkylthio group, C₅-C₂₀ heterocyclyl group, —N(Z^{A})(Z^{B}), —COOZ^{A}, —OCOZ^{A}, —CON(Z^{A})(Z^{B}), —P(═O)(OZ^{A})₂ or —O—P(═O)(Z^{A})(Z^{B}). Z^{A} and Z^{B} are each independently a C₁-C₂₀ saturated hydrocarbyl group, C₆-C₂₀ aryl group or C₇-C₂₀ aralkyl group. In the groups Z¹ and Z², some or all of the carbon-bonded hydrogen atoms may be substituted by cyano, carboxy or the like.

The RAFT agents (CTA-1) and (CTA-2) are trithiocarbonate and dithioester compounds, respectively. Examples of the trithiocarbonate compound include 2-cyano-2-propyl dodecyl trithiocarbonate, 4-cyano-4-[(dodecylsulfanylthiocarbonyl)sulfanyl]pentanoic acid, cyanomethyldodecyl trithiocarbonate, and 2-(dodecylthiocarbonothioylthio)-2-methylpropionic acid. Examples of the dithioester compound include 1-ethoxycarbonyl-1-phenylmethyl benzodithioate, 2-phenyl-2-propylbenzodithioate, 4-cyano-4-(phenylthiocarbonylthio)pentanoic acid, and 2-cyano-2-propylbenzodithioate.

Of the foregoing RAFT agents, it is preferred from the aspect of availability to select 2-cyano-2-propyl dodecyl trithiocarbonate as the trithiocarbonate compound and 1-ethoxycarbonyl-1-phenylmethyl benzodithioate as the dithioester compound.

The amount of the RAFT agent used in step (1) is preferably at least 0.05 part by weight, more preferably at least 0.1 part by weight per 100 parts by weight of the monomers in total. As the upper limit, the amount is preferably up to 20 parts by weight, more preferably up to 10 parts by weight per 100 parts by weight of the monomers in total. The RAFT agent may be used alone or in admixture of two or more.

### <Polymerization Initiator>

Examples of the polymerization initiator include 2,2′-azobisisobutyronitrile (AIBN), 2,2′-azobis(2,4-dimethylvaleronitrile), dimethyl 2,2-azobis(2-methylpropionate), 1,1′-azobis(1-acetoxy-1-phenylethane), benzoyl peroxide, and lauroyl peroxide. The amount of the polymerization initiator used is preferably 0.01 to 25 mol % based on the total of monomers to be polymerized.

### <Polymerization Solvent>

In step (1), the living radical polymerization is performed by solution polymerization for the purpose of uniformly feeding monomers to the reaction system. The solvent (S) used for polymerization reaction is preferably selected from compounds having the formula (S-1) and compounds having the formula (S-2).

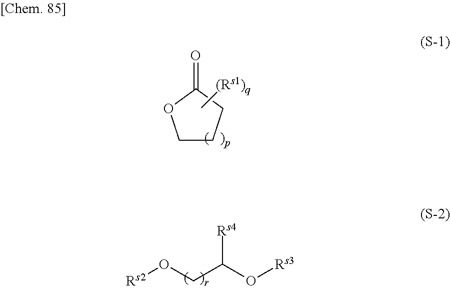

In formulae (S-1) and (S-2), R^{s1} is hydrogen, hydroxy, or an optionally substituted C₁-C₈ saturated hydrocarbyl group. R^{s2} to R^{s4} are each independently hydrogen, an optionally substituted C₁-C₈ saturated hydrocarbyl group or optionally substituted C₂-C₉ saturated hydrocarbylcarbonyl group. The subscript p is 1, 2 or 3, q is 0, 1 or 2, and r is 1, 2 or 3.

The optionally substituted C₁-C₈ saturated hydrocarbyl group represented by R^{s1} to R^{s4} and saturated hydrocarbyl moiety in the C₂-C₉ saturated hydrocarbylcarbonyl group represented by R^{s2} to R^{s4} may be straight, branched or cyclic and examples thereof include alkyl groups such as methyl, ethyl, propyl, isopropyl, n-butyl, sec-butyl, tert-butyl, pentyl, hexyl, heptyl, octyl; cyclic saturated hydrocarbyl groups such as cyclopentyl and cyclohexyl; and substituted forms of the foregoing groups in which some hydrogen is substituted by hydroxy or the like.

Examples of the solvent having formula (S-1) are shown below, but not limited thereto.

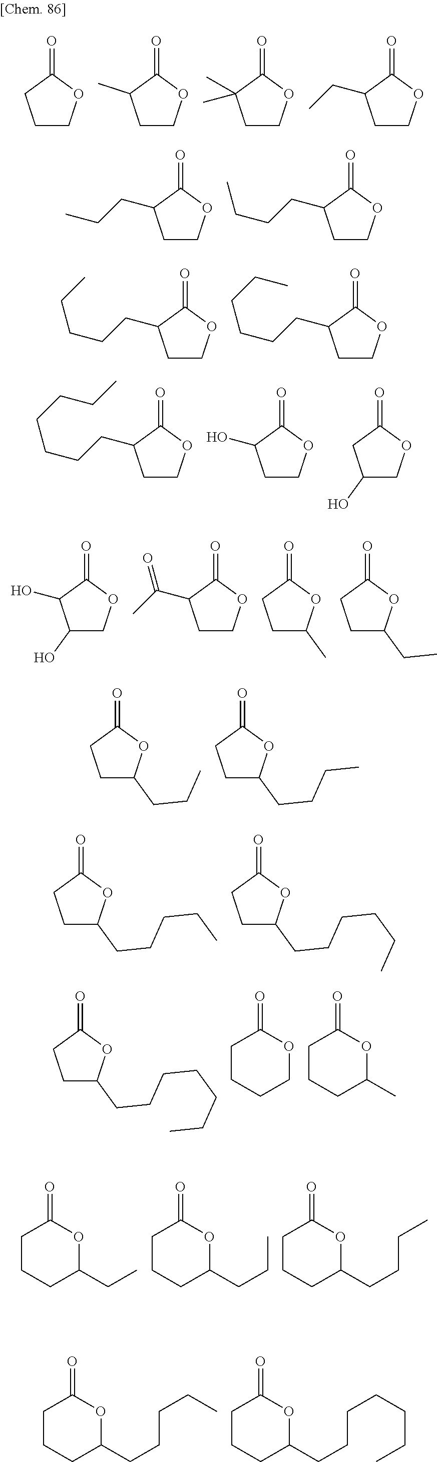

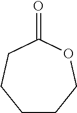

Examples of the solvent having formula (S-2) are shown below, but not limited thereto.

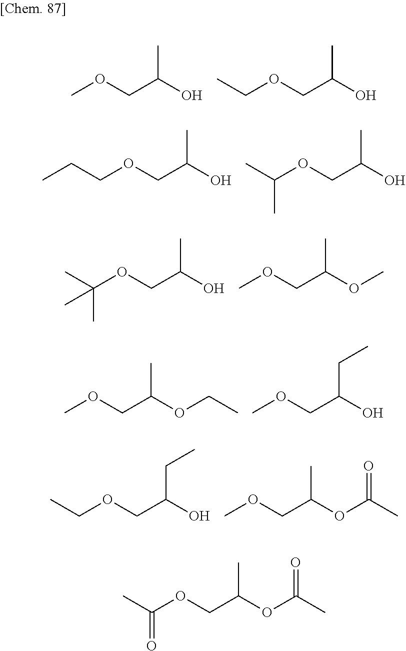

The amount of the solvent (S) used is preferably 1 to 100% by weight, more preferably 10 to 100% by weight based on the overall solvents used for polymerization. The use of solvent (S) permits monomer (A) to be dissolved in a high concentration, making it possible to set the monomer concentration of the monomer solution higher than in the prior art. Particularly the use of the solvent having formula (S-1) permits monomer (A) to be dissolved in a high concentration. This enables to elevate the conversion rate of monomers in the polymerization reaction and to reduce residual monomers at the end of polymerization reaction.

Besides, examples of the organic solvent which can be used in polymerization include toluene, benzene, tetrahydrofuran (THF), diethyl ether, dioxane and methyl ethyl ketone (MEK), other than the above-mentioned examples of solvent (S). Any of these solvents may be used in admixture with solvent (S). If necessary, the step of bubbling nitrogen stream or vacuum pumping may be carried out prior to polymerization reaction to remove any dissolved oxygen in the solvent out of the reaction system.

In step (1), the monomer concentration of the monomer solution is preferably set at 30 to 60% by weight. The living radical polymerization under such conditions makes it possible that the monomers be fully consumed within such a reaction time as not to detract from the production efficiency and the contents of residual monomers after polymerization and after purification be held at low levels.

The living radical polymerization may be carried out by a method which is selected from methods (1) to (3):
method (1) of admitting the monomers, polymerization initiator and RAFT agent all at once to solvent (S) in a reactor, dissolving them, heating the reactor to initiate reaction;
method (2) of charging a reactor with part of solvent (S), preheating the reactor, and feeding a solution of the monomers, polymerization initiator and RAFT agent in solvent (S) to the reactor to initiate reaction; and
method (3) of charging a reactor with RAFT agent and part of solvent (S), preheating the reactor, and feeding a solution of the monomers and polymerization initiator in solvent (S) to the reactor to initiate reaction.

When solutions of monomers, initiator and RAFT agent used in methods (2) and (3) are prepared, it is acceptable to prepare separate solutions of components and independently feed them to the reactor. Since there is a possibility that polymerization reaction take place with radicals generated from the initiator in the standby time, to form ultra-high molecular weight polymers, it is preferred from the standpoint of quality control to prepare at least the monomer solution and the initiator solution independently and add them dropwise.

In the living radical polymerization, the reaction temperature is preferably 50 to 150° C., more preferably 60 to 100° C., and the reaction time is preferably 2 to 24 hours, and more preferably 2 to 12 hours from the aspect of production efficiency. The amounts of monomers (A) to (C) remaining in the reaction solution containing polymer P-1 at the end of living radical polymerization are preferably less than 2.0%, less than 1.0% and less than 2.0% by weight, respectively. It is generally known that in living radical polymerization with repeat units (B) having phenolic hydroxy group such as hydroxystyrene, since active species are deactivated, the living ability of polymerization reaction and the consumption rate of monomers are difficultly promoted. By setting the polymerization conditions according to the invention, the consumption rate of monomers can be increased in a short time while maintaining high living ability. It is noted that the amounts of monomers (A) to (C) remaining in the reaction solution can be quantitatively determined by high-performance liquid chromatography.

If necessary, the step of living radical polymerization may be followed by the purification step of adding the reaction solution to a poor solvent and allowing the polymer to reprecipitate. The poor solvent used herein may be selected depending on the type of the polymer. Typical examples of the poor solvent include, but are not limited to, hydrocarbons such as toluene, xylene, hexane, and heptane, ethers such as diethyl ether, tetrahydrofuran, and dibutyl ether, ketones such as acetone and 2-butanone, esters such as ethyl acetate and butyl acetate, and water. These solvents may be used alone or in admixture.

### [Step (2)]

The subsequent step (2) is to add a radical generator and a thiol compound to the solution containing polymer P-1 resulting from step (1), and heating the solution to remove the end structure from the backbone of polymer P-1, yielding a polymer P. Through this step, the end structure of polymer P-1 is replaced by hydrogen. Although an undecomposed portion of the radical generator used in step (1) may be present in the solution at this point of time, it is recommended to supplement the radical generator at the same time as the addition of the thiol compound for the purpose of quickly and efficiently replacing the end structure by hydrogen.

The radical generator used in step (2) may be selected from the same ones as exemplified in step (1). The amount of the radical generator used is preferably 0.5 to 10 moles, more preferably 0.5 to 2 moles per mole of the RAFT agent used in step (1).

The thiol compound used in step (2) is preferably a compound having the formula (SH-1) or (SH-2).

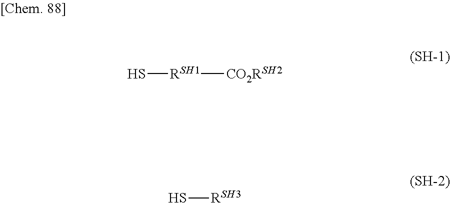

In formula (SH-1), R^{SH1} is a C₁-C₃ hydrocarbylene group. Examples of the hydrocarbylene group include methanediyl, ethane-1,1-diyl, ethane-1,2-diyl, propane-1,1-diyl, propane-1,2-diyl, propane-1,3-diyl, and propane-2,2-diyl.

In formula (SH-1), R^{SH2} is a C₄-C₈ aliphatic hydrocarbyl group which may contain a heteroatom, C₇-C₁₈ aralkyl group or C₆-C₁₈ aryl group. Suitable heteroatoms include oxygen, nitrogen, sulfur and halogen.

The aliphatic hydrocarbyl group R^{SH2} may be saturated or unsaturated and straight, branched or cyclic. Examples thereof include straight or branched aliphatic hydrocarbyl groups such as n-butyl, isobutyl, sec-butyl, tert-butyl, n-pentyl, isopentyl, sec-pentyl, 3-pentyl, tert-pentyl, neopentyl, n-hexyl, 3-methylpentan-3-yl, 2,3-dimethylbutan-2-yl, n-heptyl, 2,3,4-trimethylpentan-3-yl, n-octyl, tetradecyl, hexadecyl, and octadecyl; and cyclic aliphatic hydrocarbyl groups such as cyclopentyl, 1-methylcyclopentyl, 1-ethylcyclopentyl, 1-vinylcyclopentyl, cyclohexyl, 1-methylcyclohexyl, 1-ethylcyclohexyl, 1-vinylcyclohexyl, norbornyl, 1-methylnorbornyl, cyclooctyl, cyclodecyl, cyclododecyl, 1-adamantyl, 2-adamantyl, 1-methyladamantyl, and 1-ethyladamantyl.

Examples of the C₇-C₁₈ aralkyl group R^{SH2} include benzyl, phenethyl, 4-methoxybenzyl, and 9-anthracenylmethyl. Examples of the C₆-C₁₈ aryl group R^{SH2} include phenyl, naphthyl, 4-methoxyphenyl, 2-anthracenyl and 9-anthracenyl.

In formula (SH-2), R^{SH3} is a C₆-C₂₀ saturated hydrocarbyl group which may contain a heteroatom, C₇-C₁₈ aralkyl group or C₆-C₁₈ aryl group.

The saturated hydrocarbyl group R^{SH3} may be straight, branched or cyclic. Examples thereof include n-hexyl, 3-methylpentyl, n-heptyl, n-octyl, 1-ethylhexyl, n-nonyl, n-decyl, n-undecyl, n-dodecyl, 2,2,4,6,6-pentamethylheptan-4-yl, n-tetradecyl, n-hexadecyl, n-octadecyl, n-eicosanyl, 2,3,3,4,4,5-hexamethylhexan-2-yl.

Examples of the C₇-C₁₈ aralkyl group R^{SH3} include benzyl, phenethyl, 4-methoxybenzyl, and 9-anthracenylmethyl. Examples of the C₆-C₁₈ aryl group R^{SH3} include phenyl, naphthyl, 4-methoxyphenyl, 2-anthracenyl and 9-anthracenyl.

In the co-presence of the radical initiator, the thiol compound plays the role of acting on the end of polymer P-1 resulting from step (1) to quickly convert the end to hydrogen. This mechanism is described in JP-A 2006-002096. Then, the re-generated RAFT agent, the active species (active species I) originating from the initiator, and the thio radicals (active species S) after release of hydrogen radicals are formed in the reaction system. Shown below is an exemplary reaction system wherein the end of polymer P-1 originates from trithiocarbonate, the radical initiator is dimethyl 2,2′-azobisisobutyrate, and the thiol is a compound having formula (SH-2).

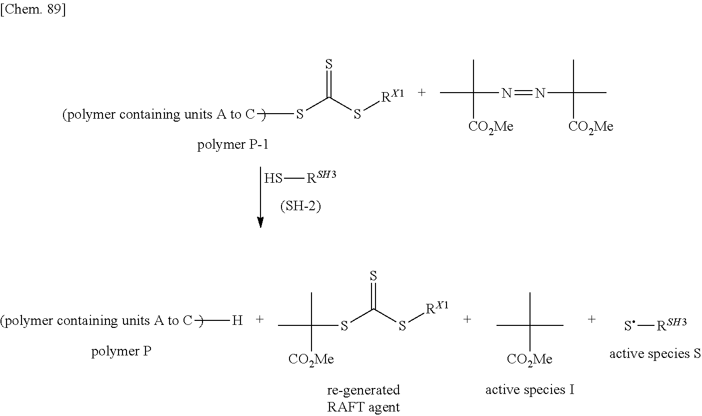

At the end of step (1), unreacted or residual monomers including monomers (A) to (C) remain in the solution containing polymer P-1, though in low concentrations. Conducting analysis and comparison of the polymer solutions during steps (1) and (2), the inventors have confirmed that side reactions take place along with the progress of step (2), that is, radical polymerization reaction steadily continues among the remaining monomers under the co-action of active species I, active species S, and re-generated RAFT agent as shown above, so that the amounts of residual monomers are further reduced.

When living radical polymerization is conducted to a full extent according to the method of step (1), the concentrations of residual monomers are quite low as compared with the concentrations of active species I originating from the initiator supplemented in step (2), active species S resulting from the thiol after conversion of the end of polymer P-1 to hydrogen, and the re-generated RAFT agent. For this reason, polymerization reaction among residual monomers taking place in step (2) does not form polymers having a high molecular weight, but forms oligomers mainly.

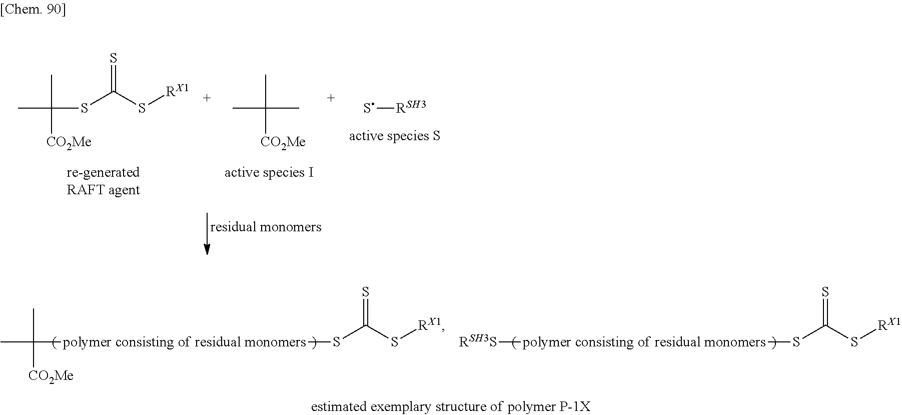

Since the polymer P-1X resulting from side reaction in step (2) has a low molecular weight, it is easily removed in the subsequent step (3). Due to the reaction mechanism involved, during polymerization of residual monomers, active species S originating from the thiol is incorporated at the end of polymer. Then, the substituent group on the thiol compound (SH-1) or (SH-2) is preferably selected such that the polymer is highly soluble in organic solvents and the polymer is readily recovered in the polymer purifying step.

Preferred examples of the compound having formula (SH-1) are shown below.

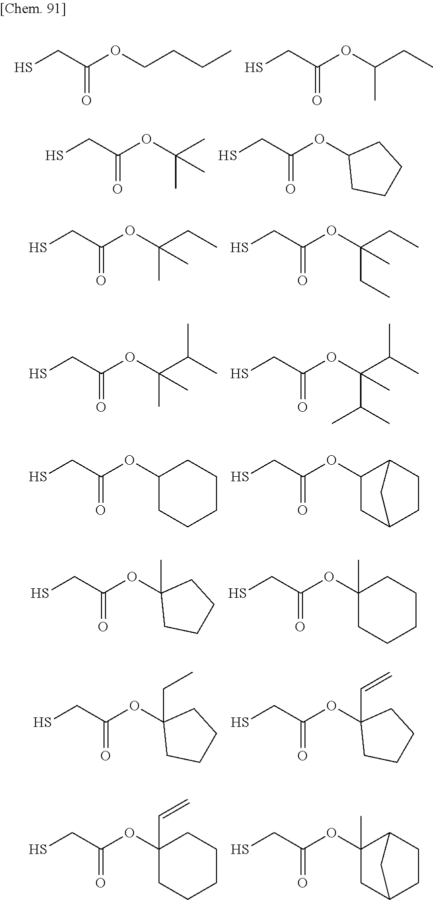

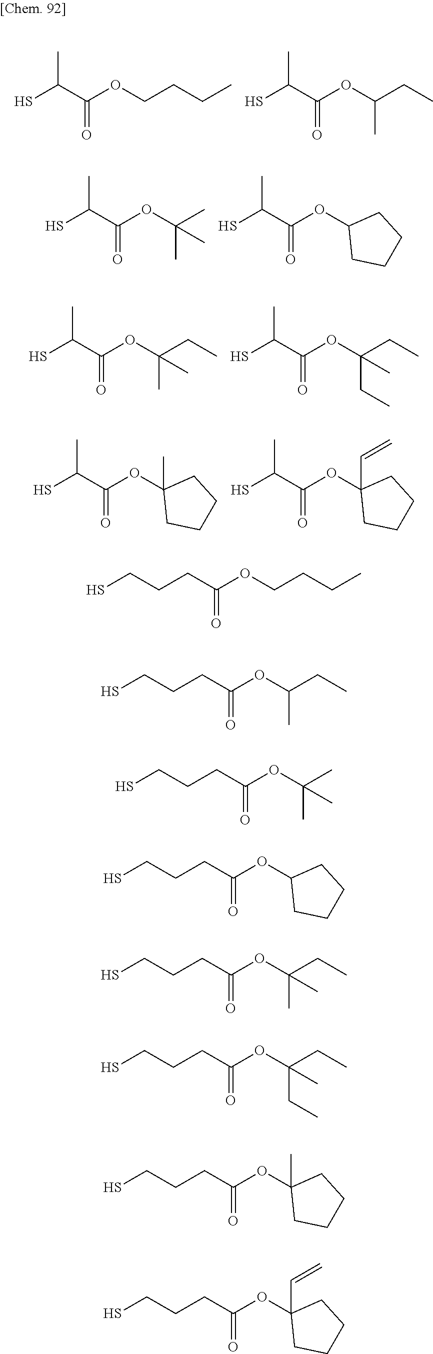

Preferred examples of the compound having formula (SH-2) are shown below.

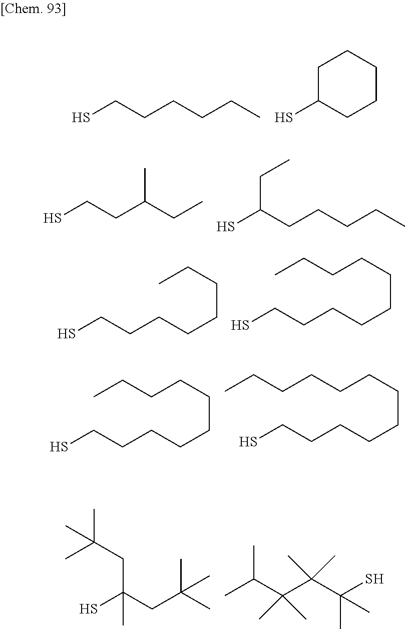

The amount of the thiol compound used in step (2) is preferably 1 to 20 moles, more preferably 1 to 4 moles per mole of the RAFT agent used in step (1). The radical initiator and thiol compound added in step (2) may be separately added to the solution containing polymer P-1. Alternatively, they may be mixed and concurrently added to the solution containing polymer P-1. From the aspect of operational efficiency, it is preferred to add a solution of the radical initiator and thiol compound in the solvent (S) to the polymer P-1 solution. More preferably, to the reaction solution resulting from living radical polymerization in step (1) in the solvent (S), the mixed solution of the initiator and thiol compound is added subsequent to step (1).

The reaction temperature in step (2) is preferably 50 to 150° C., more preferably 60 to 100° C. The reaction time in step (2) is preferably 2 to 24 hours, more preferably 2 to 5 hours from the aspect of production efficiency. Also, the solution containing polymer P in step (2) is preferably such that the amounts of monomers (A), (B), and (C) remaining therein may be less than 0.05%, less than 0.01%, and less than 0.05% by weight, respectively.

In step (2), the conversion rate (referred to as “end conversion rate,” hereinafter) from the end structure originating from the RAFT agent to hydrogen is preferably at least 95%, more preferably at least 98%, most preferably 100%. It is noted that the end conversion rate (%) is computed from the data of ¹H-NMR spectroscopy and represented by the following formula (Z):

$$end conversion rate = 100 - [ \{ ( A 1 / R 1 ) / ( A 2 / R 2 ) \} \times 100 ] \qquad ( Z )$$

wherein A1 is the integrated value of peaks assigned to the end group after contact of polymer T with thiol-containing compound, A2 is the integrated value of peaks assigned to the end group before contact of polymer P-1 with thiol-containing compound, R1 is the integrated value of peaks assigned to the overall polymer excluding the end group after contact of polymer P-1 with thiol-containing compound, and R2 is the integrated value of peaks assigned to the overall polymer excluding the end group before contact of polymer P-1 with thiol-containing compound.

### [Step (3)]

The subsequent step (3) is a purification step of mixing the polymer P-containing solution resulting from step (2) with a poor solvent and allowing polymer P to precipitate as solids.

The method of obtaining the polymer as solids may be selected from the following methods:
method (A) of obtaining solids (or powder) directly from the reaction solution at the end of step (2), that is, by directly adding the polymer P-containing solution to a poor solvent,
method (B) of obtaining solids (or powder) by dissolving the polymer in another solvent while removing the solvent (S) used in steps (1) and (2) by vacuum distillation and adding the solution to a poor solvent,
method (C) of obtaining solids (or powder) by adding another solvent to the polymer solution, then adding water thereto, allowing the mixture to separate into the polymer solution as the upper layer and the mixture of solvent (S) and water as the lower layer, removing the lower layer, adjusting the concentration of the polymer solution, and adding it to a poor solvent, and
method (D) of obtaining solids (or powder) by adding the polymer P-containing solution to water, allowing solids to precipitate, recovering the powder by filtration, dissolving the powder in another solvent, and adding the solution to a poor solvent.

Among these methods, method (A) or (C) is preferred from the aspects of operating time and precision.

The poor solvent may be selected depending on the type of the polymer. Typical examples of the poor solvent include, but are not limited to, hydrocarbons such as toluene, xylene, hexane, and heptane, ethers such as diethyl ether, tetrahydrofuran, diisopropyl ether, and dibutyl ether, ketones such as acetone and 2-butanone, esters such as ethyl acetate and butyl acetate, and water. These solvents may be used alone or in admixture.

The purification method of obtaining a powder by adding the polymer solution to a poor solvent is employed for the purpose of removing low-molecular-weight polymers formed in steps (1) and (2) and unreacted monomers. If necessary, similar purification may be repeated by dissolving the resulting powder to prepare a solution again.

In the polymer thus obtained from the inventive method, preferably the amount of monomer (A) remaining therein is up to 0.05% by weight, the amount of monomer (B) remaining therein is up to 0.01% by weight, and the amount of monomer (C) to be decomposed under the action of acid remaining therein is up to 0.05% by weight.

The polymer obtained from the inventive method preferably has a weight average molecular weight (Mw) of 1,000 to 30,000, more preferably 3,000 to 20,000. It is noted that Mw is as measured by gel permeation chromatography (GPC) versus polystyrene standards. Also, the polymer preferably has a dispersity (Mw/Mn) of 1.0 to 1.5, more preferably 1.0 to 1.35.

### [Preparation of Polymer Solution]

Preferably the polymer P obtained from the inventive method is dissolved in a solvent to form a polymer solution (referred to as polymer solution PS, hereinafter), which is handled as the final product. The solvent contains at least propylene glycol monomethyl ether acetate (PGMEA). The solvent may contain a solvent other than PGMEA. Examples of the other solvent include those described in JP-A 2008-111103, paragraphs [0144]-[0145], specifically ketones such as cyclohexanone and methyl-2-n-pentyl ketone; alcohols such as 3-methoxybutanol, 3-methyl-3-methoxybutanol, 1-methoxy-2-propanol, and 1-ethoxy-2-propanol; ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; lactones such as γ-butyrolactone (GBL); alcohols such as diacetone alcohol (DAA); and high-boiling alcohols such as diethylene glycol, propylene glycol, glycerin, 1,4-butanediol, and 1,3-butanediol. The other solvent may be used alone or in admixture. When the solvent contains the other solvent, the content of PGMEA is preferably 25 to 80% by weight, more preferably 30 to 70% by weight of the overall solvents.

After the polymer P is dissolved in the solvent, it is passed through a filter to yield a polymer solution PS. The filtration step is effective for quality stabilization because foreign particles or gel which cause defects can be removed.

Examples of the material of which the filter used for filtration is made include fluorocarbon, cellulose, nylon, polyester, and hydrocarbon based materials. In the step of filtering resist compositions, filters made of materials based on fluorocarbon, commonly known as Teflon (registered trademark), materials based on hydrocarbons such as polyethylene and polypropylene, or nylon are preferred. The pore size of the filter may be selected as appropriate so as to meet the desired degree of cleanness, and is preferably up to 100 nm, more preferably up to 20 nm. The filter may be used alone or in a combination of two or more.

The filtration step may be performed by passing the solution only once through the filter, but preferably by circulating the solution so as to pass through the filter plural times. The filtration step may be performed in any order and any times in the method of preparing the polymer. It is preferred to filter the reaction solution after polymerization reaction, polymer solution PS or both.

The concentration of polymer P in the polymer solution PS is preferably 0.01 to 30% by weight, more preferably 0.1 to 20% by weight.

### [Preparation of Chemically Amplified Resist Composition]

A further embodiment of the invention is a method for preparing a chemically amplified resist composition. The resist composition contains several components, which are described below.

### <Base Polymer>

The chemically amplified resist composition contains a base polymer containing the polymer obtained from the aforementioned method. The polymer may be used alone or in a combination of two or more polymers which are different in compositional ratio, Mw and dispersity or molecular weight distribution. In the base polymer, the content of the polymer is preferably at least 40% by weight, more preferably at least 80% by weight, most preferably 100% by weight.

### <Quencher of Onium Salt Type>

Preferably the chemically amplified resist composition further comprises a quencher of onium salt type. As used herein, the “quencher” refers to a compound capable of trapping the strong acid generated by the PAG to prevent the acid from diffusing into the unexposed region of resist film, for forming the desired pattern. The term “strong acid” refers to a compound having a sufficient acidity to induce deprotection reaction of an acid labile group.

Preferred examples of the onium salt type quencher include onium salts having the formulae (Q-1) and (Q-2). It is noted that the onium salts having formula (Q-2) are exclusive of onium salts having the formula (Q-3).

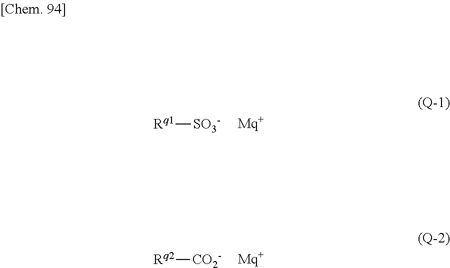

In formula (Q-1), R^{q1} is hydrogen or a C₁-C₄₀ hydrocarbyl group which may contain a heteroatom, exclusive of the group wherein hydrogen bonded to the carbon atom at α-position relative to the sulfo group is substituted by fluorine or fluoroalkyl.

Examples of the C₁-C₄₀ hydrocarbyl group R^{q1} include C₁-C₄₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl; C₃-C₄₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decyl, adamantyl and adamantylmethyl; C₆-C₄₀ aryl groups such as phenyl, naphthyl, alkylphenyl groups (e.g., 2-methylphenyl, 3-methylphenyl, 4-methylphenyl, 4-ethylphenyl, 4-tert-butylphenyl, 4-n-butylphenyl), di- or trialkylphenyl groups (e.g., 2,4-dimethylphenyl and 2,4,6-triisopropylphenyl), alkylnaphthyl groups (e.g., methylnaphthyl and ethylnaphthyl), dialkylnaphthyl groups (e.g., dimethylnaphthyl and diethylnaphthyl), and anthracenyl, and C₇-C₄₀ aralkyl groups such as benzyl, 1-phenylethyl and 2-phenylethyl.

In the hydrocarbyl group, some or all hydrogen may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, fluorine, chlorine, bromine, iodine, cyano moiety, carbonyl moiety, ether bond, ester bond, sulfonic ester bond, carbonate bond, lactone ring, sultone ring, carboxylic anhydride (—C(═O)—O—C(═O)—), or haloalkyl moiety. Suitable heteroatom-containing hydrocarbyl groups include heteroaryl groups such as thienyl; alkoxyphenyl groups such as 4-hydroxyphenyl, 4-methoxyphenyl, 3-methoxyphenyl, 2-methoxyphenyl, 4-ethoxyphenyl, 4-tert-butoxyphenyl, 3-tert-butoxyphenyl; alkoxynaphthyl groups such as methoxynaphthyl, ethoxynaphthyl, n-propoxynaphthyl and n-butoxynaphthyl; dialkoxynaphthyl groups such as dimethoxynaphthyl and diethoxynaphthyl; and aryloxoalkyl groups, typically 2-aryl-2-oxoethyl groups such as 2-phenyl-2-oxoethyl, 2-(1-naphthyl)-2-oxoethyl and 2-(2-naphthyl)-2-oxoethyl.

In formula (Q-2), R^{q2} is a C₁-C₄₀ hydrocarbyl group which may contain a heteroatom. Examples of the hydrocarbyl group R^{q2} are as exemplified above for the hydrocarbyl group R^{q1}. Other examples include fluorinated alkyl groups such as trifluoromethyl, trifluoroethyl, 2,2,2-trifluoro-1-methyl-1-hydroxyethyl, and 2,2,2-trifluoro-1-(trifluoromethyl)-1-hydroxyethyl; and fluorinated aryl groups such as pentafluorophenyl and 4-trifluoromethylphenyl.

Examples of the anion in the onium salt having formula (Q-1) are shown below, but not limited thereto.

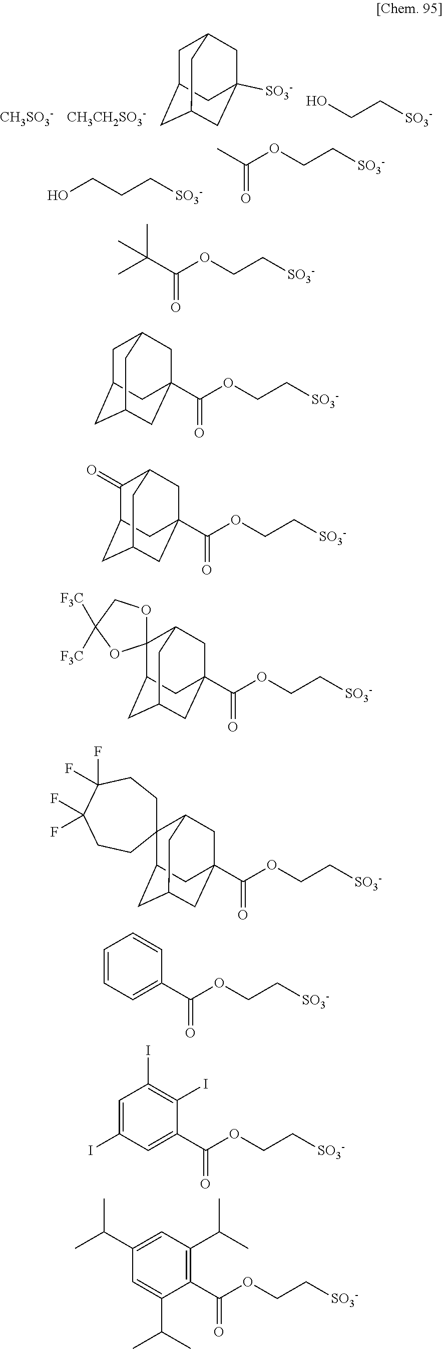

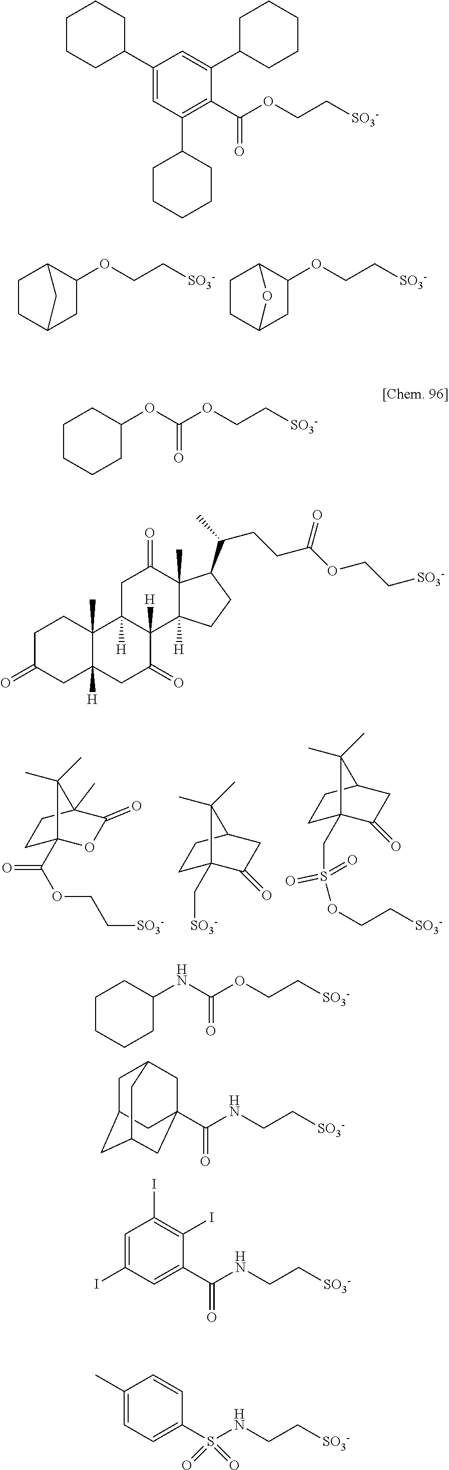

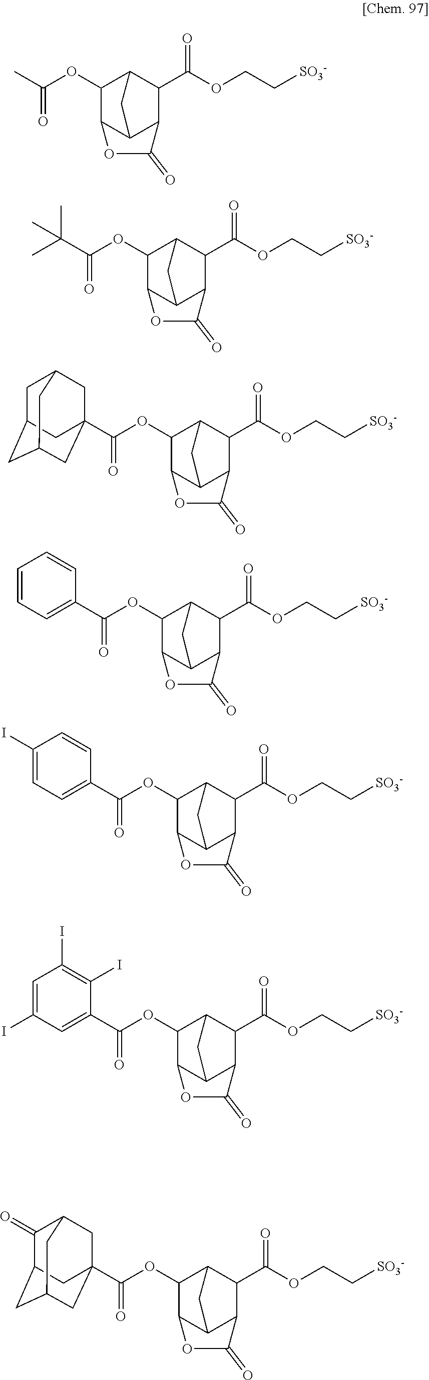

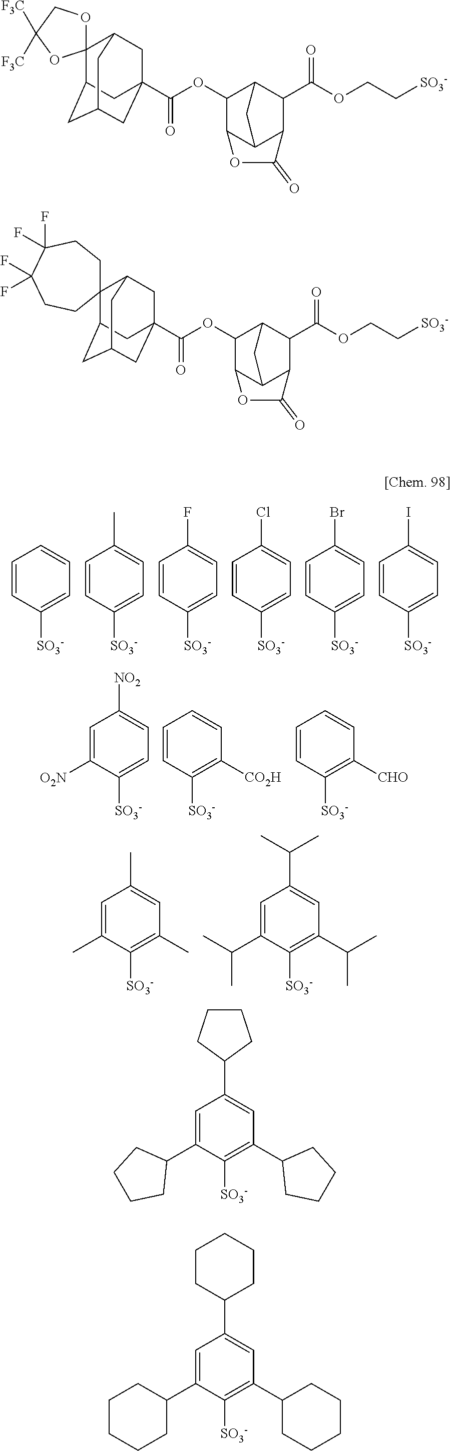

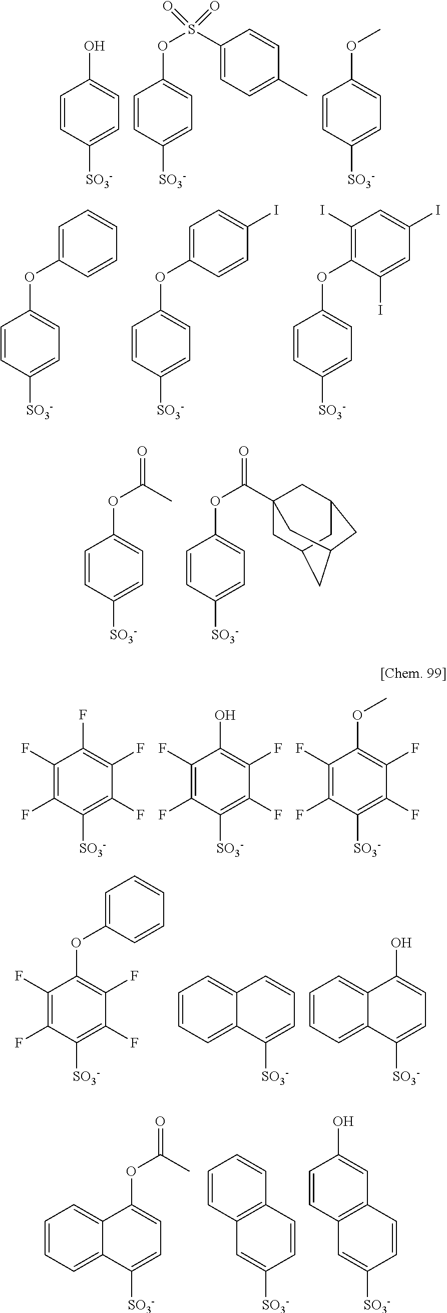

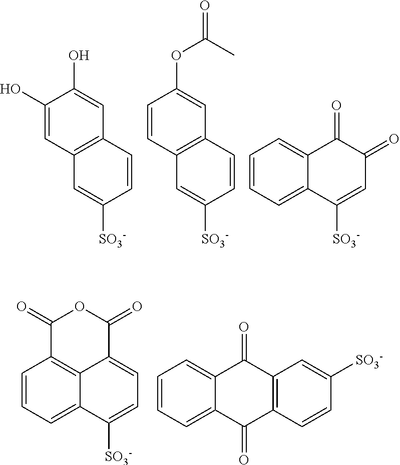

Examples of the anion in the onium salt having formula (Q-2) are shown below, but not limited thereto.

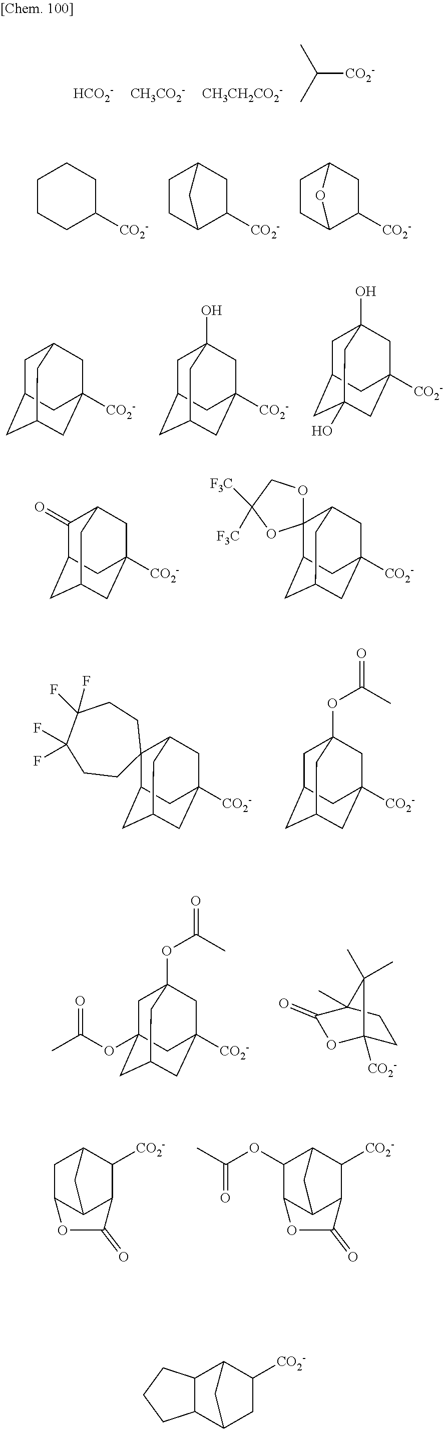

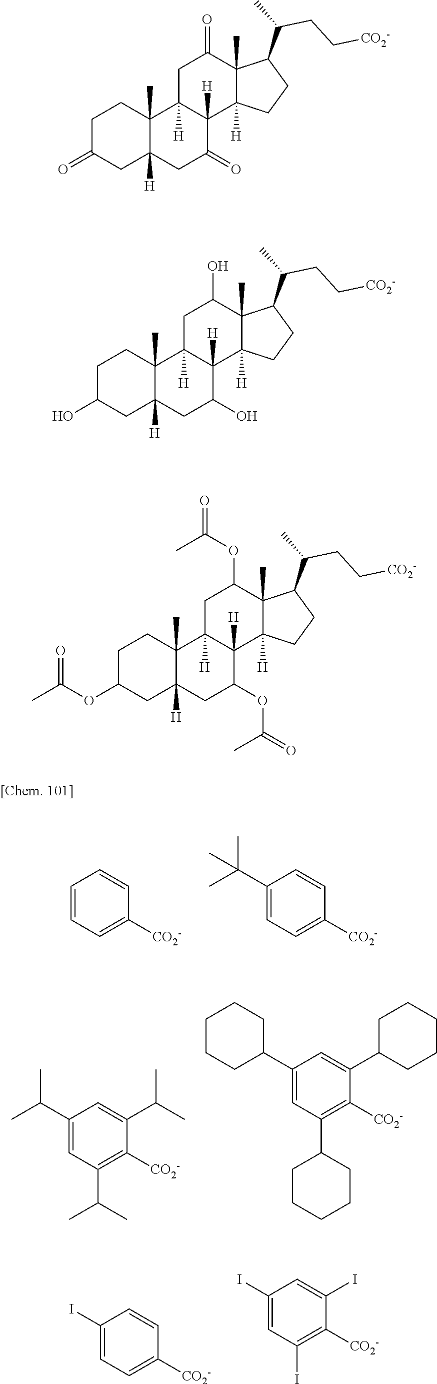

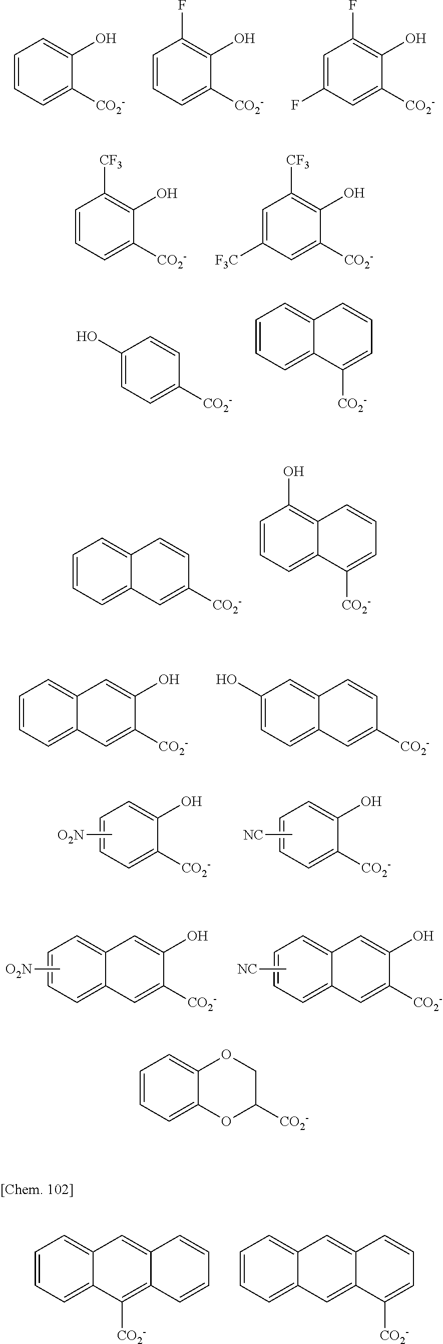

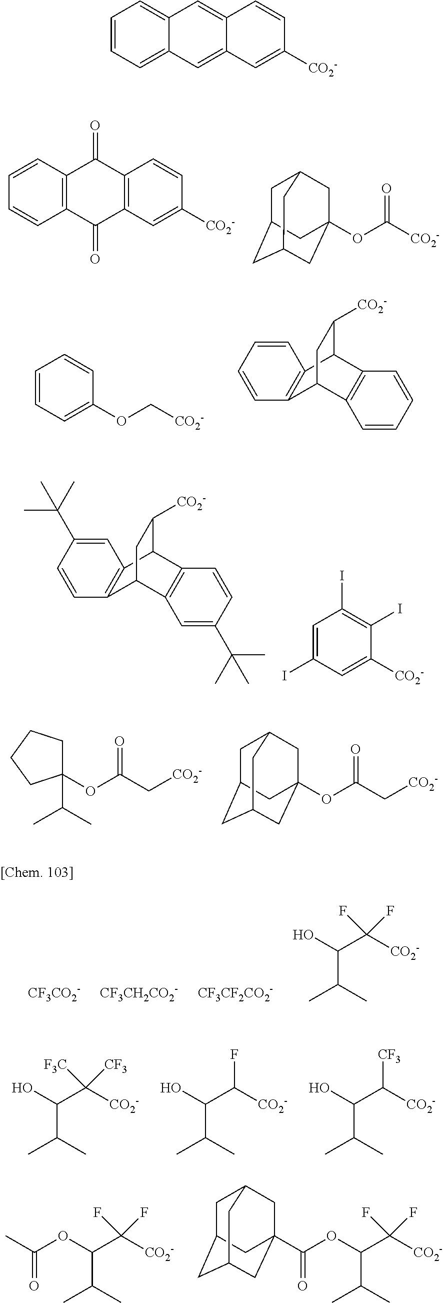

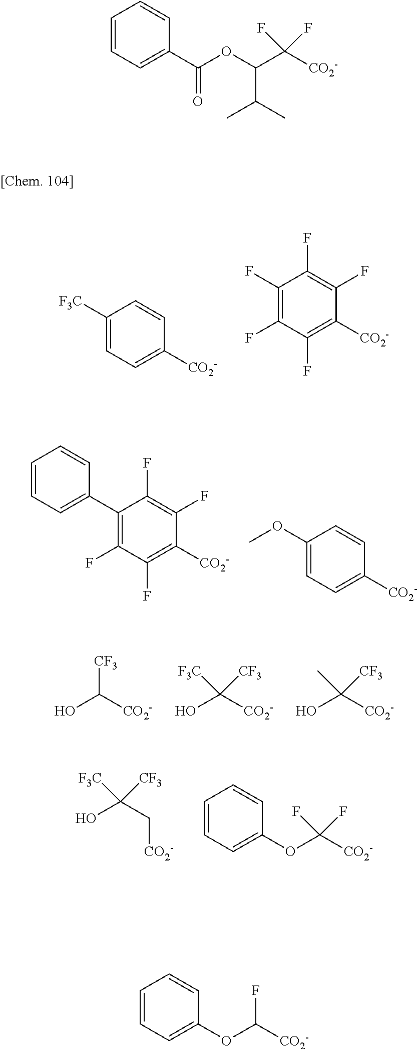

In formulae (Q-1) and (Q-2), Mq⁺ is an onium cation. The onium cation is typically selected from sulfonium cations, iodonium cations, and ammonium cations. As the sulfonium cation, those having formula (cation-1) are preferred, and examples thereof are as exemplified above for the sulfonium cation having formula (cation-1). As the iodonium cation, those having formula (cation-2) are preferred, and examples thereof are as exemplified above for the iodonium cation having formula (cation-2).

Onium salts having the formula (Q-3) are also preferred as the onium salt type quencher.

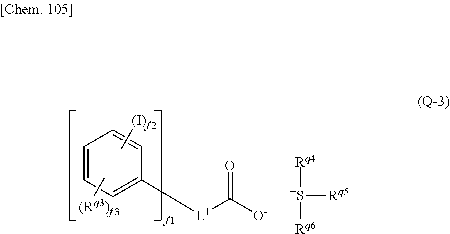

In formula (Q-3), f1 is 1, 2 or 3, f2 is 1, 2, 3, 4 or 5, f3 is 0, 1, 2 or 3, and 1≤f2+f3≤5.

In formula (Q-3), R^{q3} is hydroxy, fluorine, chlorine, bromine, amino, nitro, cyano, a C₁-C₆ saturated hydrocarbyl group, C₁-C₆ saturated hydrocarbyloxy group, C₂-C₆ saturated hydrocarbylcarbonyloxy group, C₁-C₄ saturated hydrocarbylsulfonyloxy group, —N(R^{q3A})—C(═O)—R^{q3B}, or —N(R^{q3A})—C(═O)—O—R^{q3B}. In the saturated hydrocarbyl group, saturated hydrocarbyloxy group, saturated hydrocarbylcarbonyloxy group, and saturated hydrocarbylsulfonyloxy group, some or all of the hydrogen atoms may be substituted by halogen. R^{q3A} is hydrogen or a C₁-C₆ saturated hydrocarbyl group. R^{q3B} is a C₁-C₆ saturated hydrocarbyl group or C₂-C₈ unsaturated aliphatic hydrocarbyl group. When f1 and/or f2 is 2 or more, a plurality of R²¹¹ may be identical or different.

In formula (Q-3), L¹ is a single bond or a C₁-C₂₀ (f1+1)-valent linking group which may contain at least one moiety selected from ether bond, carbonyl moiety, ester bond, amide bond, sultone ring, lactam ring, carbonate bond, halogen, hydroxy moiety, and carboxy moiety. The saturated hydrocarbyl group, saturated hydrocarbyloxy group, saturated hydrocarbylcarbonyloxy group, and saturated hydrocarbylsulfonyloxy group may be straight, branched or cyclic.

In formula (Q-3), R^{q4}, R^{q5} and R^{q6} are each independently halogen or a C₁-C₂₀ hydrocarbyl group which may contain a heteroatom. The hydrocarbyl group may be saturated or unsaturated and straight, branched or cyclic. Examples thereof include C₁-C₂₀ alkyl groups, C₂-C₂₀ alkenyl groups, C₆-C₂₀ aryl groups, and C₇-C₂₀ aralkyl groups. In the hydrocarbyl group, some or all of the hydrogen atoms may be substituted by hydroxy, carboxy, halogen, oxo, cyano, nitro, sultone ring, sulfo or sulfonium salt-containing moiety, and some —CH₂— may be replaced by ether bond, ester bond, carbonyl, amide bond, carbonate bond or sulfonate ester bond. A pair of R^{q4} and R^{q5} may bond together to form a ring with the sulfur atom to which they are attached.

As the cation in the onium salt having formula (Q-3), those having formula (cation-1) are preferred. Examples thereof are as exemplified for the sulfonium cation having formula (cation-1).

Examples of the anion in the onium salt having formula (Q-3) are shown below, but not limited thereto.

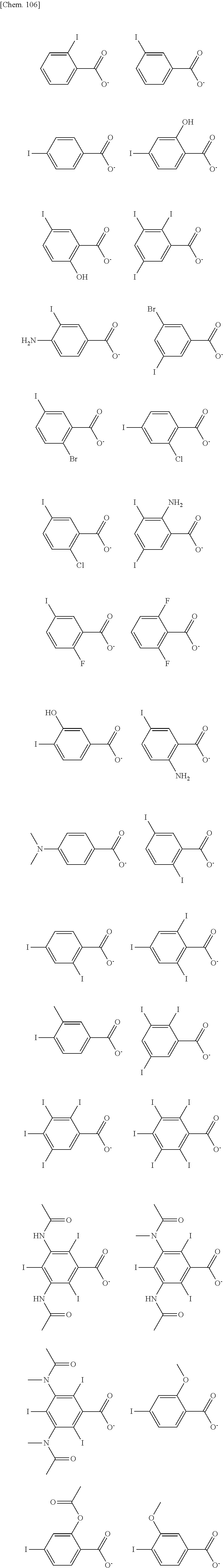

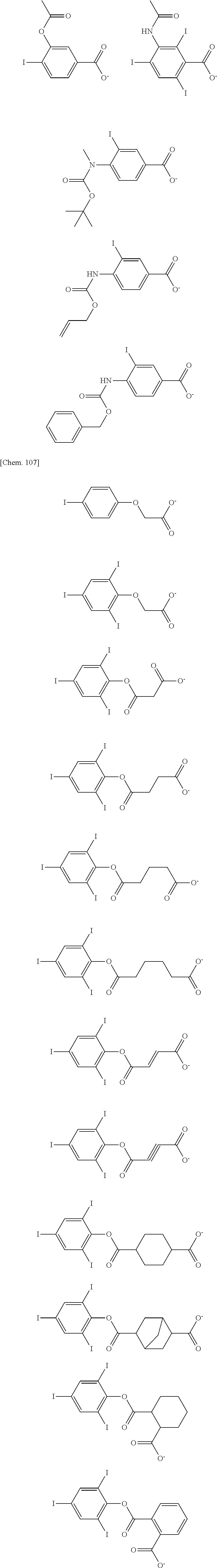

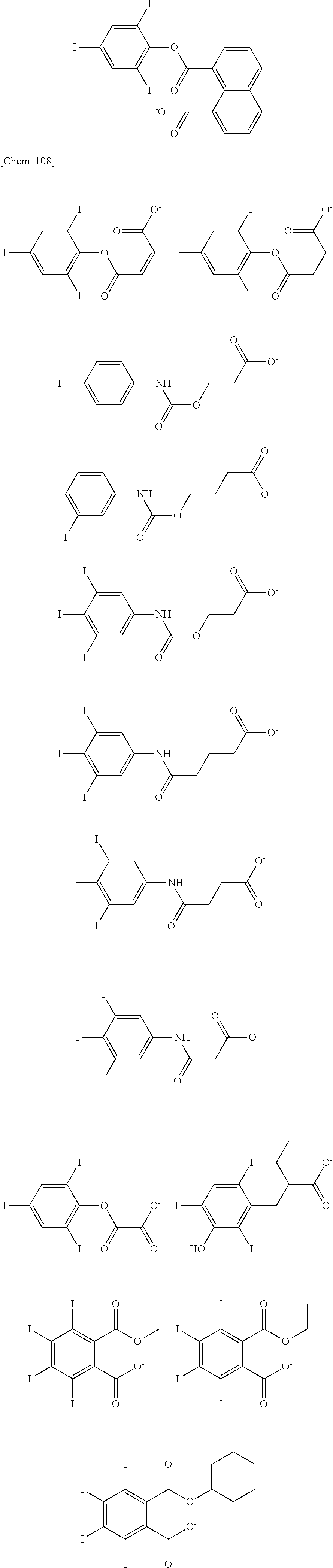

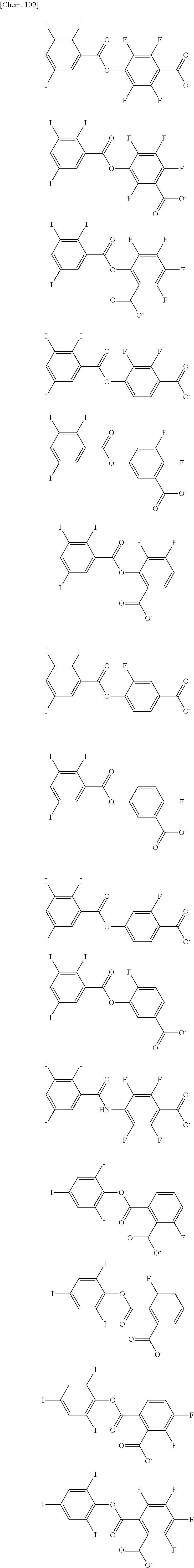

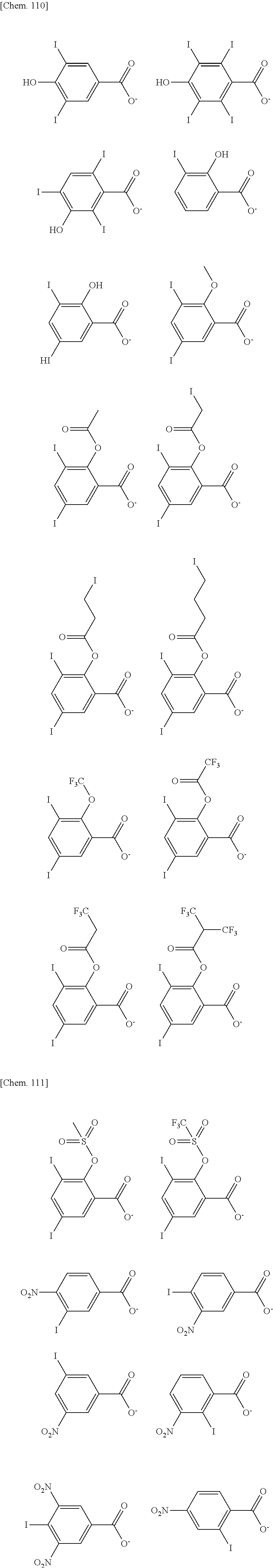

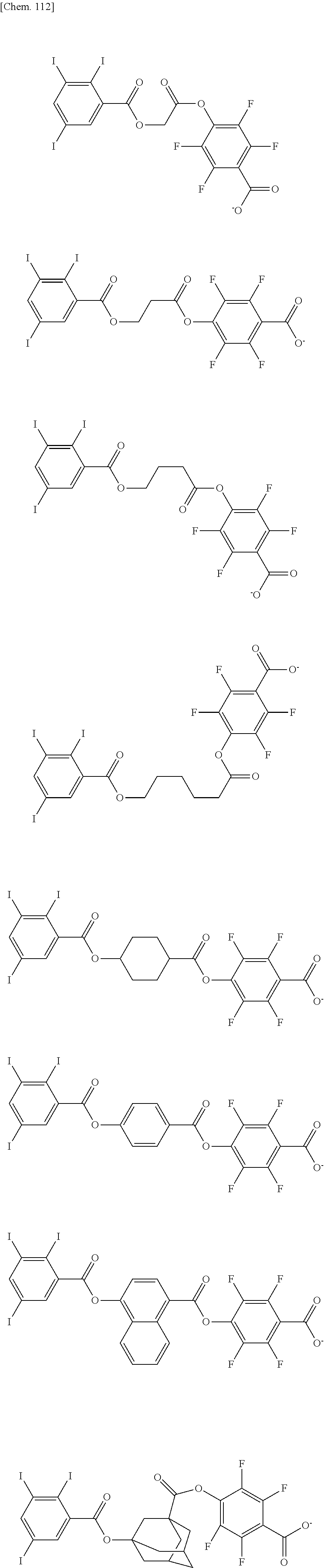

The compound having formula (Q-3) is fully absorptive and has a high sensitizing effect and high acid diffusion controlling effect.

When the chemically amplified resist composition contains the quencher, the amount thereof is preferably 0.001 to 12 parts by weight, more preferably 0.01 to 8 parts by weight per 80 parts by weight of the base polymer. When the quencher is blended, the sensitivity of a resist film can be easily adjusted, the diffusion of acid in the resist film is controlled, which leads to an improvement in resolution, minimization of sensitivity changes after exposure, mitigation of substrate or environment dependency, and improvements in exposure latitude and pattern profile. The addition of the quencher is also effective for enhancing the substrate adhesion. The quencher may be used alone or in admixture.

### <Organic Solvent>

The chemically amplified resist composition typically contains an organic solvent. The organic solvents used herein are described in JP-A 2008-111103, paragraphs [0144]-[0145]. Exemplary solvents include ketones such as cyclohexanone, cyclopentanone, methyl-2-n-pentyl ketone and 2-heptanone; alcohols such as 3-methoxybutanol, 3-methyl-3-methoxybutanol, 1-methoxy-2-propanol, 1-ethoxy-2-propanol and diacetone alcohol; ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as PGMEA, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; lactones such as GBL; and mixtures thereof. When acid labile groups of acetal type are used, high-boiling alcohols may be added to accelerate deprotection reaction of acetal. For example, diethylene glycol, propylene glycol, glycerin, 1,4-butanediol or 1,3-butanediol may be added.

The amount of the organic solvent is preferably 100 to 10,000 parts by weight, more preferably 300 to 8,000 parts by weight per 80 parts by weight of the base polymer. The organic solvent may be used alone or in admixture.

### [Other Components]

In addition to the foregoing components, the chemically amplified resist composition may contain an acid generator, surfactant, dissolution inhibitor, crosslinker, water repellency improver, and acetylene alcohol.

Typical of the acid generator are compounds (photoacid generators) capable of generating acid in response to actinic ray or radiation. As the PAG, any compounds capable of generating acid upon exposure to high-energy radiation may be used. Acid generators capable of generating a sulfonic acid, imide acid or methide acid are preferred. Examples of the preferred acid generator include sulfonium salt, iodonium salt, sulfonyldiazomethane, N-sulfonyloxyimide, and oxime-O-sulfonate type acid generators. Illustrative examples of the acid generator are described in JP-A 2008-111103, paragraphs [0122]-[0142], JP-A 2018-005224, and JP-A 2018-025789. When the chemically amplified resist composition contains the other acid generator, the amount thereof is preferably 0 to 200 parts by weight, more preferably 0.1 to 100 parts by weight per 80 parts by weight of the base polymer.

Exemplary surfactants are described in JP-A 2008-111103, paragraphs [0165]-[0166]. Inclusion of a surfactant may improve or control the coating characteristics of the chemically amplified resist composition. When the resist composition contains the surfactant, the amount thereof is preferably 0.0001 to 10 parts by weight per 80 parts by weight of the base polymer. The surfactant may be used alone or in admixture.

The inclusion of a dissolution inhibitor in the chemically amplified resist composition leads to an increased difference in dissolution rate between exposed and unexposed regions and a further improvement in resolution. The dissolution inhibitor is a compound having at least two phenolic hydroxy groups on the molecule, in which an average of from 0 to 100 mol % of all the hydrogen atoms on the phenolic hydroxy groups are replaced by acid labile groups or a compound having at least one carboxy group on the molecule, in which an average of 50 to 100 mol % of all the hydrogen atoms on the carboxy groups are replaced by acid labile groups, both the compounds having a molecular weight of 100 to 1,000, and preferably 150 to 800. Typical are bisphenol A, trisphenol, phenolphthalein, cresol novolac, naphthalenecarboxylic acid, adamantanecarboxylic acid, and cholic acid derivatives in which the hydrogen atom on the hydroxy or carboxy group is replaced by an acid labile group, as described in JP-A 2008-122932, paragraphs [0155]-[0178].

When the chemically amplified resist composition contains a dissolution inhibitor, the amount thereof is preferably 0 to 50 parts, more preferably 5 to 40 parts by weight per 80 parts by weight of the base polymer. The dissolution inhibitor may be used alone or in admixture.

The water repellency improver serves to improve the water repellency on surface of a resist film and may be used in the topcoatless immersion lithography. Suitable water repellency improvers include polymers having a fluoroalkyl group and polymers of specific structure having a 1,1,1,3,3,3-hexafluoro-2-propanol residue and are described in JP-A 2007-297590 and JP-A 2008-111103, for example. The water repellency improver should be soluble in the alkaline developer and organic solvent developer. The water repellency improver of specific structure having a 1,1,1,3,3,3-hexafluoro-2-propanol residue is well soluble in the developer. A polymer comprising repeat units having an amino group or amine salt may serve as the water repellent additive and is effective for preventing evaporation of acid during PEB, thus preventing any hole pattern opening failure after development. When the resist composition contains the water repellency improver, the amount thereof is preferably 0 to 20 parts, more preferably 0.5 to 10 parts by weight per 80 parts by weight of the base polymer. The water repellency improver may be used alone or in admixture.

Examples of the acetylene alcohol are described in JP-A 2008-122932, paragraphs [0179]-[0182]. When the chemically amplified resist composition contains the acetylene alcohol, the amount thereof is preferably 0 to 5 parts by weight per 80 parts by weight of the base polymer. The acetylene alcohol may be used alone or in admixture.

A further embodiment of the invention is a method for preparing a chemically amplified resist composition comprising the step of dissolving starting compounds comprising a base polymer containing the polymer obtained from the aforementioned method in the organic solvent. The starting compounds may contain the quencher and at least one compound selected from the other components, if necessary.

The starting compounds are added to the organic solvent simultaneously or in any desired order, dissolved and mixed such that the contents of respective components may fall in the aforementioned ranges.

After mixing, the solution is preferably passed through a filter. Suitable materials of which the filter is made include fluorocarbon, cellulose, nylon, polyester, and hydrocarbon base materials. Preferred for the filtration of a chemically amplified resist composition are filters made of fluorocarbons commonly known as Teflon (registered trademark), hydrocarbons such as polyethylene and polypropylene, and nylon. While the pore size of the filter may be selected appropriate to comply with the desired cleanness, the filter preferably has a pore size of up to 200 nm, more preferably up to 100 nm, even more preferably up to 20 nm. A single filter may be used or a plurality of filters may be used in combination. Although the filtering method may be single pass of the solution, preferably the filtering step is repeated by circulating the solution.

### [Pattern Forming Process]

A further embodiment of the invention is a pattern forming process comprising the steps of applying the chemically amplified resist composition onto a substrate to form a resist film thereon, exposing the resist film to high-energy radiation, and developing the exposed resist film in a developer.

As the substrate, for example, a substrate on which an integrated circuit is to be formed (e.g., Si, SiO₂, SiN, SiON, TiN, WSi, BPSG, SOG, or organic antireflective coating) or a substrate on which a mask circuit is to be formed (e.g., Cr, CrO, CrON, MoSi₂, or SiO₂) may be used.

The resist film may be formed by applying the chemically amplified resist composition onto a substrate by such means as spin coating, and prebaking the coating on a hotplate preferably at a temperature of 60 to 150° C. for 1 to 10 minutes, more preferably at 80 to 140° C. for 1 to 5 minutes. The resulting resist film is generally 0.05 to 2 μm thick.

Examples of the high-energy radiation used for the exposure of a resist film include KrF excimer laser radiation, ArF excimer laser radiation, EUV of wavelength 3 to 15 nm, and EB. When KrF excimer laser radiation, ArF excimer laser radiation or EUV is used, the resist film is exposed thereto through a mask having a desired pattern in a dose of preferably 1 to 200 mJ/cm², more preferably 10 to 100 mJ/cm². When EB is used, the resist film is exposed thereto directly or through a mask having a desired pattern in a dose of preferably 0.1 to 100 μC/cm², more preferably 0.5 to 50 μC/cm².

The exposure may be performed by conventional lithography whereas the immersion lithography of holding a liquid having a refractive index of at least 1.0 between the resist film and the projection lens may be employed. The liquid is typically water, and in this case, a protective film which is insoluble in water may be formed on the resist film.

While the water-insoluble protective film serves to prevent any components from being leached out of the resist film and to improve water sliding on the film surface, it is generally divided into two types. The first type is an organic solvent-strippable protective film which must be stripped, prior to alkaline development, with an organic solvent in which the resist film is not dissolvable. The second type is an alkali-soluble protective film which is soluble in an alkaline developer so that it can be removed simultaneously with the removal of solubilized regions of the resist film. The protective film of the second type is preferably of a material comprising a polymer having a 1,1,1,3,3,3-hexafluoro-2-propanol residue (which is insoluble in water and soluble in an alkaline developer) as a base in an alcohol solvent of at least 4 carbon atoms, an ether solvent of 8 to 12 carbon atoms or a mixture thereof. Alternatively, the aforementioned surfactant which is insoluble in water and soluble in an alkaline developer may be dissolved in an alcohol solvent of at least 4 carbon atoms, an ether solvent of 8 to 12 carbon atoms or a mixture thereof to form a material from which the protective film of the second type is formed.

After the exposure, the resist film may be baked (PEB), for example, on a hotplate preferably at 60 to 150° C. for 1 to 5 minutes, more preferably at 80 to 140° C. for 1 to 3 minutes.

The resist film is then developed with a developer in the form of an aqueous base solution, for example, 0.1 to 5 wt %, preferably 2 to 3 wt % aqueous solution of tetramethylammonium hydroxide (TMAH) for 0.1 to 3 minutes, preferably 0.5 to 2 minutes by conventional techniques such as dip, puddle and spray techniques. In this way, a desired resist pattern is formed on the substrate.

Also, after the resist film is formed, a step of rinsing with pure water may be introduced to extract the acid generator or the like from the film surface or wash away particles. After exposure, a step of rinsing may be introduced to remove any water remaining on the film after exposure.

In the pattern forming process, negative tone development may also be used. That is, an organic solvent may be used instead of the aqueous alkaline solution as the developer for developing and dissolving away the unexposed region of the resist film.

The organic solvent used as the developer is preferably selected from 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, isopentyl acetate, butenyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, and 2-phenylethyl acetate. These organic solvents may be used alone or in admixture of two or more.

### EXAMPLES

Examples and Comparative Examples are given below by way of illustration and not by way of limitation. It is noted that Mw is measured by gel permeation chromatography (GPC) versus polystyrene standards using N,N-dimethylformamide solvent.

The reagents used in Examples are shown below.
CTA-1: 2-cyano-2-propyl benzodithioate
CTA-2: 2-cyano-2-propyl dodecyltrithiocarbonate
I-1: dimethyl 2,2′-azobisisobutyrate
I-2: 2,2′-azobisisobutyronitrile
SH-1: 1-dodecanethiol
SH-2: tert-butyl thioglycolate
SH-3: tert-dodecylmercaptan

Monomers MA-1 to MA-14, MB-1 to MB-7, and MC-1 to MC-7 used in Examples are shown below.

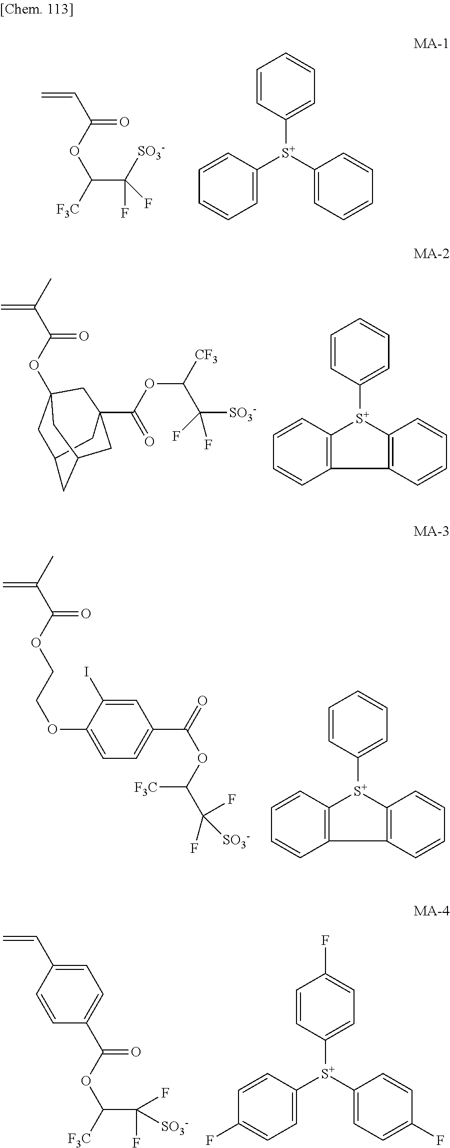

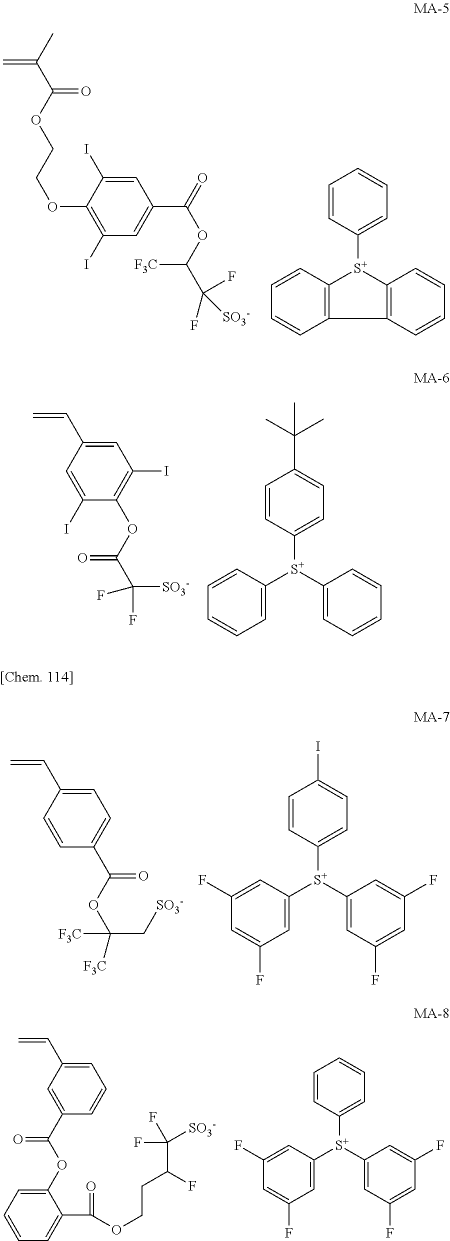

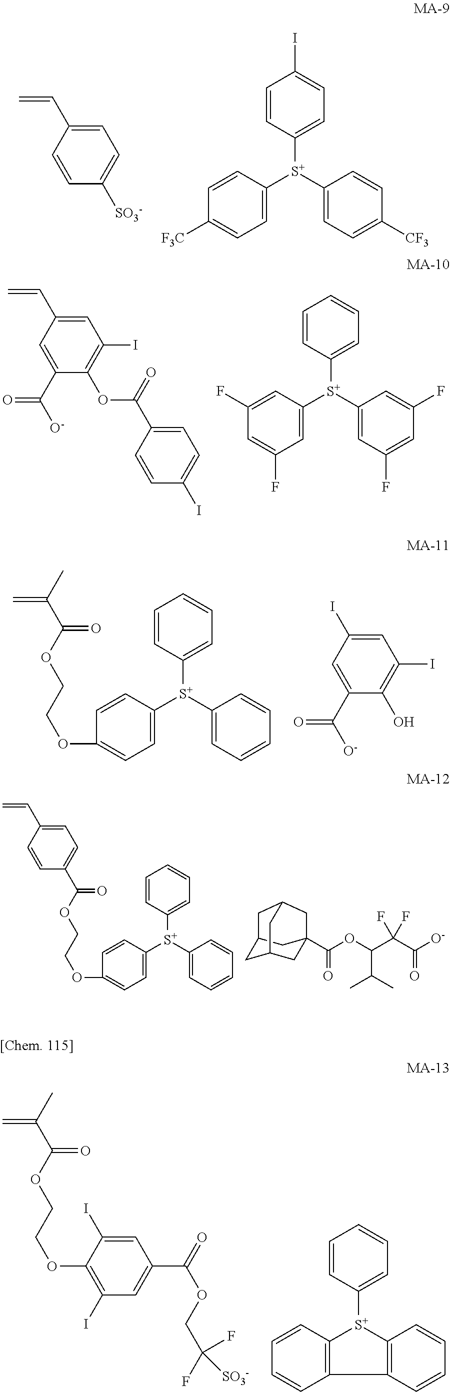

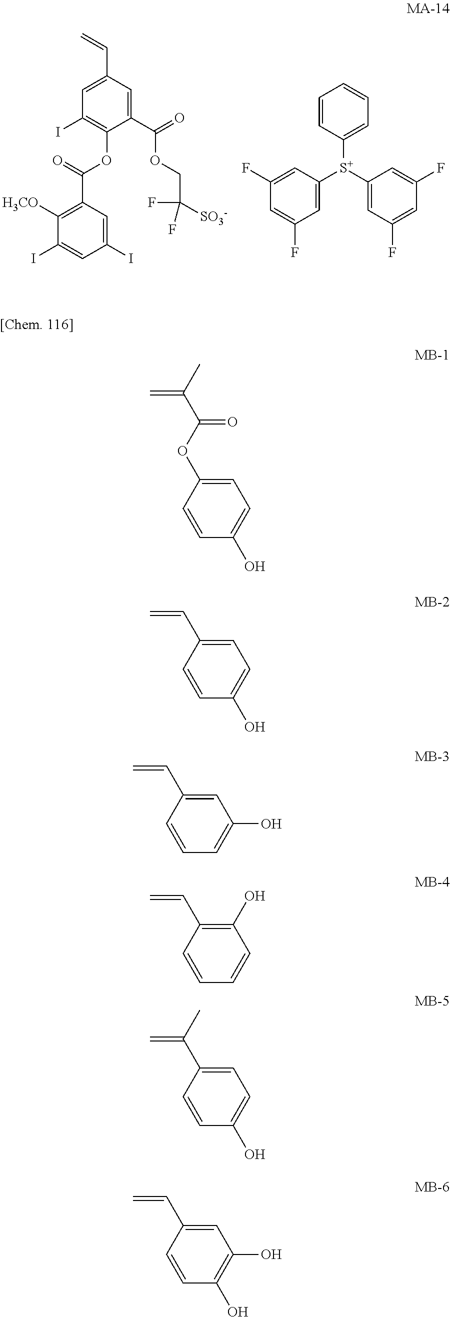

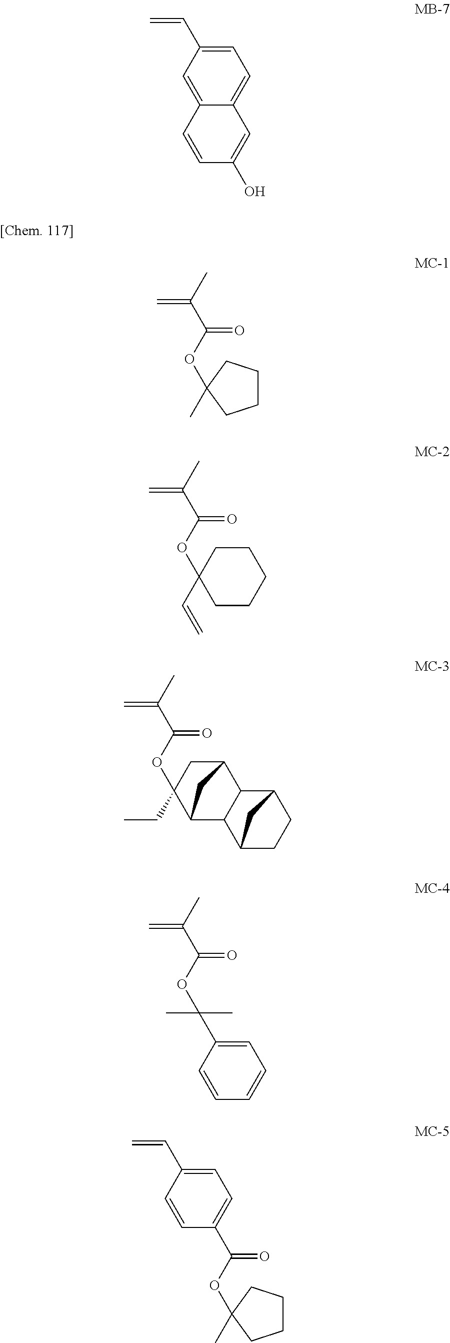

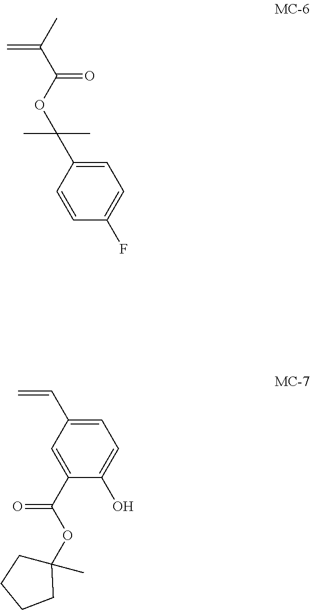 [SMILES: C=C(C)C(=O)OC(C)(C)c1ccc(F)cc1 ; C=Cc1ccc(O)c(C(=O)OC2(C)CCCC2)c1]

### [1] Preparation of Polymer

### [Example 1-1] Preparation of Polymer P-1

Solution A was prepared under nitrogen atmosphere by dissolving 11.5 g of MA-1, 20.2 g of MB-2 (50 wt % PGMEA solution), 12.3 g of MC-1, and 6.1 g of MC-2 in 21 g of GBL, and repeating 3 cycles of vacuum pumping for 20 minutes and nitrogen purging. Separately, Solution B was prepared by dissolving 0.97 g of dimethyl 2,2′-azobisisobutyrate (I-1) in 9.0 g of GBL, and repeating 3 cycles of vacuum pumping for 20 minutes and nitrogen purging. Further, Solution C was prepared by dissolving 2.79 g of CTA-1 in 20.0 g of GBL, and repeating 3 cycles of vacuum pumping for 20 minutes and nitrogen purging. The reactor containing Solution C was heated until the internal temperature reached 80° C. Using syringe pumps, Solution A and Solution B were independently added dropwise to the reactor over 2 hours. At the end of addition, the polymerization solution was stirred for 6 hours while keeping the temperature of 80° C. and then cooled to room temperature. The foregoing procedure is referred to as step RM-1. The reaction solution of step RM-1 had a solid concentration of 40% by weight.

Subsequently, Solution D was prepared by dissolving 2.90 g of I-1 and 5.10 g of SH-1 in 33.3 g of GBL, and repeating 3 cycles of vacuum pumping for 20 minutes and nitrogen purging. Using a syringe pump, Solution D was added dropwise to the reaction solution of step RM-1 over 5 minutes. At the end of addition, the reactor was heated again until the internal temperature reached 80° C. The solution was stirred for 2 hours while keeping the temperature of 80° C. and then cooled to room temperature. The foregoing procedure is referred to as step RM-2.

Thereafter, the solution of step RM-2 was diluted with 250 g of methyl isobutyl ketone, mixed with 400 g of ultrapure water, and transferred to a separatory funnel, in which the liquid separated into two layers. After the lower layer was discarded, the upper layer was recovered and concentrated at 40° C. until 160 g of the solution was obtained. The solution was added dropwise to 1,000 g of diisopropyl ether. The precipitated solids were collected by filtration and dried in vacuum at 50° C. for 20 hours, obtaining Polymer P-1 as white solids (amount 35 g, yield 88%).

Polymer P-1 had a Mw of 9,500 and a Mw/Mn of 1.32. In step RM-1, the amount of residual MA-1 was 0.85 wt %, the amount of residual MB-2 was 0.46 wt %, the amount of residual MC-1 was 1.05 wt %, and the amount of residual MC-2 was 0.90 wt %. In step RM-2, the amount of residual MA-1 was 0.03 wt %, the amount of residual MB-2 was less than the lower limit of quantification (less than 0.01 wt %), the amount of residual MC-1 was 0.04 wt %, the amount of residual MC-2 was 0.02 wt %, and the end conversion rate was 100%. In Polymer P-1 after reprecipitation, the amount of residual MA-1 was 0.01 wt %, the amount of residual MB-2 was less than the lower limit of quantification (less than 0.01 wt %), the amount of residual MC-1 was less than the lower limit of quantification (less than 0.01 wt %), and the amount of residual MC-2 was less than the lower limit of quantification (less than 0.01 wt %).

### [Example 1-2] Preparation of Polymer P-2

Solution A was prepared in a reactor under nitrogen atmosphere by dissolving 17.2 g of MA-2, 9.7 g of MB-1, 13.1 g of MC-1, and 3.23 g of CTA-2 in 30.0 g of GBL. The reactor was heated until the internal temperature reached 70° C. Separately, Solution B was prepared by dissolving 0.51 g of I-2 in 10.0 g of GBL, and repeating 3 cycles of vacuum pumping for 20 minutes and nitrogen purging. Using a syringe pump, Solution B was added dropwise to Solution A over 2 hours. At the end of addition, the polymerization solution was stirred for 6 hours while keeping the temperature of 70° C. and then cooled to room temperature. The foregoing procedure is referred to as step RM-1. The reaction solution of step RM-1 had a solid concentration of 50% by weight.

Subsequently, Solution C was prepared by dissolving 1.53 g of I-2 and 2.79 g of SH-2 in 20.0 g of GBL, and repeating 3 cycles of vacuum pumping for 20 minutes and nitrogen purging. Using a syringe pump, Solution C was added dropwise to the reaction solution of step RM-1 over 5 minutes. At the end of addition, the reactor was heated again until the internal temperature reached 70° C. The solution was stirred for 2 hours while keeping the temperature of 70° C. and then cooled to room temperature. The foregoing procedure is referred to as step RM-2.

Thereafter, the solution of step RM-2 was diluted with 250 g of methyl isobutyl ketone, mixed with 400 g of ultrapure water, and transferred to a separatory funnel, in which the liquid separated into two layers. After the lower layer was discarded, the upper layer was recovered and concentrated at 40° C. until 200 g of the solution was obtained. The solution was added dropwise to 1,000 g of diisopropyl ether. The precipitated solids were collected by filtration and dried in vacuum at 50° C. for 20 hours, obtaining Polymer P-2 as white solids (amount 37 g, yield 93%).

Polymer P-2 had a Mw of 10,000 and a Mw/Mn of 1.31. In step RM-1, the amount of residual MA-2 was 0.95 wt %, the amount of residual MB-1 was 0.40 wt %, the amount of residual MB-1 was 0.40 wt %, and the amount of residual MC-1 was 1.00 wt %. In step RM-2, the amount of residual MA-2 was 0.04 wt %, the amount of residual MB-1 was less than the lower limit of quantification (less than 0.01 wt %), the amount of residual MC-1 was 0.03 wt %, and the end conversion rate was 100%. In Polymer P-2 after reprecipitation, the amount of residual MA-2 was 0.01 wt %, the amount of residual MB-1 was less than the lower limit of quantification (less than 0.01 wt %), and the amount of residual MC-1 was less than the lower limit of quantification (less than 0.01 wt %).

### [Example 1-3] Preparation of Polymer P-3

Solution A was prepared in a reactor under nitrogen atmosphere by dissolving 17.7 g of MA-5, 6.9 g of MB-3, 15.4 g of MC-4, and 3.14 g of CTA-1 in 48.9 g of GBL and repeating 3 cycles of vacuum pumping for 20 minutes and nitrogen purging. Then 0.50 g of I-2 was added to solution A and confirmed dissolved at room temperature. The reactor was heated until the internal temperature reached 70° C. The polymerization solution was stirred for 8 hours while keeping the temperature of 70° C. and then cooled to room temperature. The foregoing procedure is referred to as step RM-1. The reaction solution of step RM-1 had a solid concentration of 45% by weight.

Subsequently, Solution B was prepared by dissolving 1.49 g of I-1 and 2.71 g of SH-2 in 25.4 g of PGME, and repeating 3 cycles of vacuum pumping for 20 minutes and nitrogen purging. Using a syringe pump, Solution B was added dropwise to the reaction solution of step RM-1 over 5 minutes. At the end of addition, the reactor was heated again until the internal temperature reached 70° C. The solution was stirred for 2 hours while keeping the temperature of 70° C. and then cooled to room temperature. The foregoing procedure is referred to as step RM-2.

Thereafter, the solution of step RM-2 was diluted with 36.8 g of PGME, which was added dropwise to 1,000 g of diisopropyl ether. The precipitated solids were collected by filtration and dried in vacuum at 50° C. for 20 hours, obtaining Polymer P-3 as white solids (amount 33 g, yield 83%).

Polymer P-3 had a Mw of 10,500 and a Mw/Mn of 1.28. In step RM-1, the amount of residual MA-5 was 0.98 wt %, the amount of residual MB-3 was 0.30 wt %, and the amount of residual MC-4 was 1.05 wt %. In step RM-2, the amount of residual MA-5 was 0.02 wt %, the amount of residual MB-3 was less than the lower limit of quantification (less than 0.01 wt %), the amount of residual MC-4 was 0.01 wt %, and the end conversion rate was 100%. In Polymer P-1 after reprecipitation, the amount of residual MA-5 was less than the lower limit of quantification (less than 0.01 wt %), the amount of residual MB-3 was less than the lower limit of quantification (less than 0.01 wt %), and the amount of residual MC-4 was less than the lower limit of quantification (less than 0.01 wt %).

### [Comparative Example 1-1] Study 1 on Preparation Conditions of Polymer P-3

An attempt was made to prepare a monomer solution of the same composition as in Example 1-3 in the concentration described in Example 4 of Patent Document 7. Specifically, 14.6 g of MA-5, 5.7 g of MB-3, and 12.7 g of MC-4 were mixed with 9.8 g of propylene glycol monomethyl ether. Monomer MA-5 could not be dissolved.

### [Comparative Example 1-2] Study 2 on Preparation Conditions of Polymer P-3

An attempt was made to prepare a monomer solution of the same composition as in Example 1-3 in the concentration described in Example 4 of Patent Document 7. Specifically, 14.6 g of MA-5, 5.7 g of MB-3, and 12.7 g of MC-4 were mixed with 9.8 g of GBL. Monomer MA-5 could not be dissolved.

### [Comparative Example 1-3] Preparation of Polymer CP-1

Solution A was prepared in a reactor under nitrogen atmosphere by dissolving 17.7 g of MA-5, 6.9 g of MB-3, 15.4 g of MC-4, and 3.14 g of CTA-2 in 42.8 g of GBL and repeating 3 cycles of vacuum pumping for 20 minutes and nitrogen purging. Subsequently, Solution B was prepared by dissolving 0.50 g of I-2 in 6.1 g of GBL and repeating 3 cycles of vacuum pumping for 20 minutes and nitrogen purging. The subsequent step was carried out with reference to the method described in Example 4 of Patent Document 7. That is, 3.5 g of solution B was added to solution A in the reactor at room temperature. The flask was heated at a temperature of 80° C. to start polymerization. While the reactor was kept at the temperature of 80° C., the remainder (3.1 g) of solution B was added until the lapse of 3 hours. Stirring was continued for a further 3 hours at 80° C. for reaction. The polymerization solution was then cooled. The foregoing procedure is referred to as step RM-1. The reaction solution of step RM-1 had a solid concentration of 45% by weight.

Subsequently, 3.03 g of SH-3 was added to the solution of step RM-1, which was heated at 80° C. for 3 hours and then cooled. The foregoing procedure is referred to as step RM-2.

Thereafter, the solution of step RM-2 was diluted with 36.8 g of PGME, which was added dropwise to 1,000 g of diisopropyl ether. The precipitated solids were collected by filtration and dried in vacuum at 50° C. for 20 hours, obtaining Polymer CP-1 as orange yellow solids (amount 28 g, yield 70%).

Polymer CP-1 had a Mw of 9,500 and a Mw/Mn of 1.52. In step RM-1, the amount of residual MA-5 was 1.90 wt %, the amount of residual MB-3 was 0.78 wt %, and the amount of residual MC-4 was 1.28 wt %. In step RM-2, the amount of residual MA-5 was 1.52 wt %, the amount of residual MB-3 was 0.26 wt %), the amount of residual MC-4 was 0.78 wt %, and the end conversion rate was 72%. In Polymer P-3 after reprecipitation, the amount of residual MA-5 was 1.30 wt %, the amount of residual MB-3 was 0.10 wt %, and the amount of residual MC-4 was 0.48 wt %. Polymer CP-1 in solid form had an end conversion rate of 88%.

### [Comparative Example 1-4] Preparation of Polymer CP-2

Solution A was prepared in a reactor under nitrogen atmosphere by dissolving 11.5 g of MA-1, 20.2 g of MB-2 (50% PGMEA solution), 12.3 g of MC-1, 6.1 g of MC-2, and 2.79 g of CTA-1 in 30.0 g of GBL and repeating 3 cycles of vacuum pumping for 20 minutes and nitrogen purging. Separately, Solution B was prepared by dissolving 0.97 g of I-1 in 19.9 g of GBL and repeating 3 cycles of vacuum pumping for 20 minutes and nitrogen purging. The reactor containing solution A was heated so that the internal temperature reached 80° C. The subsequent step was carried out with reference to the method described in Example 1 of Patent Document 8. That is, using a syringe pump, solution B was added to solution A in the reactor at 80° C. over 5 minutes. The solution was stirred for 5 hours while keeping the temperature of 80° C. The foregoing procedure is referred to as step RM-1.

Subsequently, solution C which was prepared by dissolving 28.97 g of I-1 in 50 g of GBL was added to the solution of step RM-1, which was stirred at 80° C. for 2 hours and then cooled. The foregoing procedure is referred to as step RM-2.

Thereafter, the solution of step RM-2 was diluted with 250 g of methyl isobutyl ketone, mixed with 400 g of ultrapure water, and transferred to a separatory funnel, in which the liquid separated into two layers. After the lower layer was discarded, the upper layer was recovered and concentrated at 40° C. until 160 g of the solution was obtained. The solution was added dropwise to 1,000 g of diisopropyl ether. The precipitated solids were collected by filtration and dried in vacuum at 50° C. for 20 hours, obtaining Polymer CP-2 as white solids (amount 38 g, yield 95%).

Polymer CP-2 had a Mw of 9,300 and a Mw/Mn of 1.45. In step RM-1, the amount of residual MA-1 was 1.20 wt %, the amount of residual MB-2 was 0.78 wt %, the amount of residual MC-1 was 1.25 wt %, and the amount of residual MC-2 was 1.00 wt %. In step RM-2, the amount of residual MA-1 was 0.03 wt %, the amount of residual MB-2 was less than the lower limit of qualification (less than 0.01 wt %), the amount of residual MC-1 was 0.04 wt %, the amount of residual MC-2 was 0.02 wt %, and the end conversion rate was 90%. In Polymer CP-2 after reprecipitation, the amount of residual MA-1 was 0.01 wt %, the amount of residual MB-2 was less than the lower limit of quantification (less than 0.01 wt %), the amount of residual MC-1 was less than the lower limit of quantification (less than 0.01 wt %), and the amount of residual MC-2 was less than the lower limit of quantification (less than 0.01 wt %). Polymer CP-2 in solid form had an end conversion rate of 94%.

### [Comparative Example 1-5] Preparation of Polymer CP-3

Solution A was prepared in a reactor under nitrogen atmosphere by dissolving 17.7 g of MA-5, 6.9 of MB-3, and 15.4 g of MC-4 in 39.5 g of GBL and repeating 3 cycles of vacuum pumping for 20 minutes and nitrogen purging. Separately, Solution B was prepared by dissolving 4.96 g of 2,2′-azobisisobutyronitrile in 20.0 g of GBL and repeating 3 cycles of vacuum pumping for 20 minutes and nitrogen purging. A reactor was charged with 24.8 g of GBL, followed by repetition of 3 cycles of vacuum pumping for 20 minutes and nitrogen purging. The reactor was heated until the internal temperature reached 80° C. Using syringe pumps, solution A and solution B were independently added to the reactor over 4 hours. The polymerization solution was stirred for 4 hours while keeping the temperature of 80° C., and then cooled to room temperature. The foregoing procedure is referred to as step RM-1.

Thereafter, the solution of step RM-1 was diluted with 250 g of methyl isobutyl ketone, mixed with 400 g of ultrapure water, and transferred to a separatory funnel, in which the liquid separated into two layers. After the lower layer was discarded, the upper layer was recovered and concentrated at 40° C. until 160 g of the solution was obtained. The solution was added dropwise to 1,000 g of diisopropyl ether. The precipitated solids were collected by filtration and dried in vacuum at 50° C. for 20 hours, obtaining Polymer CP-3 as white solids (amount 36 g, yield 90%).

Polymer CP-3 had a Mw of 10,000 and a Mw/Mn of 1.64. In step RM-1, the amount of residual MA-5 was 1.20 wt %, the amount of residual MB-3 was 0.37 wt %, and the amount of residual MC-4 was 0.78 wt %. In Polymer P-3 after reprecipitation, the amount of residual MA-5 was 0.96 wt %, the amount of residual MB-3 was 0.18 wt %, and the amount of residual MC-4 was 0.24 wt %.

### Examples 1-4 to 1-12 and Comparative Examples 1-6 and 1-7

Polymers P-4 to P-12 and Comparative Polymers CP-4 and CP-5 were prepared according to the procedure of the foregoing examples except that the monomers and compositional ratios were changed. Table 1 tabulates the starting materials and post-treatment conditions for the polymers prepared in Examples and Comparative Examples. Table 2 tabulates the analytical values, end conversion rate, Mw and Mw/Mn at the end of each step.

TABLE 1

| | | | | | | | | | Poly- | | | |
|---|---|---|---|---|---|---|---|---|---|---|---|---|
| | | | | | | | | | merization | | | |
| | | | | | | | | Chain | solvent S | Reaction | | Reaction |
| | | Monomer | Monomer | Monomer | Monomer | Monomer | Initiator | transfer | (solids | temperature | | temperature |
| | | A1 | A2 | B | C1 | C2 | I | agent | concen- | of step | | of step |
| | | (molar | (molar | (molar | (molar | (molar | (molar | (molar | tration, | RM-1 | Initiator | RM-2 |
| | Polymer | ratio) | ratio) | ratio) | ratio) | ratio) | ratio) | ratio) | wt %) | (° C.) | Thiol | (° C.) |
| Example | P-1 | MA-1 | | MB-2 | MC-1 | MC-2 | I-1 | CTA-1 | GBL | 80 | I-1 | 70 |
| 1-1 | | (10) | | (40) | (35) | (15) | (2) | (6) | (40) | | SH-1 | |
| Example | P-2 | MA-2 | | MB-1 | MC-1 | — | I-2 | CTA-2 | GBL | 70 | I-2 | 70 |
| 1-2 | | (15) | | (35) | (50) | | (2) | (6) | (50) | | SH-2 | |
| Example | P-3 | MA-5 | | MB-3 | MC-4 | — | I-2 | CTA-1 | GBL | 70 | I-2 | 70 |
| 1-3 | | (12) | | (38) | (50) | — | (2) | (6) | (45) | | SH-2 | |
| Example | P-4 | MA-3 | MA-4 | MB-4 | MC-3 | — | I-1 | CTA-1 | GBL | 80 | I-1 | 80 |
| 1-4 | | (10) | (5) | (35) | (50) | | (2) | (6) | (45) | | SH-3 | |
| Example | P-5 | MA-6 | | MB-5 | MC-5 | MC-7 | I-2 | CTA-1 | GBL | 80 | I-2 | 70 |
| 1-5 | | (12) | | (38) | (35) | (15) | (2) | (6) | (45) | | SH-3 | |
| Example | P-6 | MA-5 | | MB-3 | MC-6 | — | I-1 | CTA-1 | GBL | 70 | I-1 | 70 |
| 1-6 | | (12) | | (38) | (50) | | (2) | (6) | (45) | | SH-3 | |
| Example | P-7 | MA-7 | MA-9 | MB-6 | MB-2 | — | I-1 | CTA-2 | GBL | 80 | I-1 | 80 |
| 1-7 | | (12) | (3) | (30) | (55) | | (2) | (6) | (55) | | SH-1 | |
| Example | P-8 | MA-8 | MA-10 | MB-2 | MC-1 | — | I-1 | CTA-2 | GBL | 70 | I-1 | 70 |
| 1-8 | | (12) | (3) | (30) | (55) | | (2) | (6) | (60) | | SH-3 | |
| Example | P-9 | MA-2 | MA-11 | MB-7 | MC-1 | — | I-2 | CTA-1 | GBL | 70 | I-1 | 70 |
| 1-9 | | (7) | (3) | (40) | (50) | | (2) | (6) | (45) | | SH-2 | |
| Example | P-10 | MA-2 | MA-12 | MB-6 | MC-1 | — | I-2 | CTA-1 | GBL | 70 | I-1 | 70 |
| 1-10 | | (7) | (3) | (40) | (50) | | (2) | (6) | (45) | | SH-2 | |
| Example | P-11 | MA-13 | — | MB-3 | MC-6 | — | I-1 | CTA-2 | GBL | 70 | I-1 | 70 |
| 1-11 | | (10) | | (40) | (50) | | (2) | (6) | (45) | | SH-3 | |
| Example | P-12 | MA-14 | — | MB-3 | MC-1 | — | I-1 | CTA-2 | GBL | 70 | I-1 | 70 |
| 1-12 | | (12) | | (35) | (53) | | (2) | (6) | (45) | | SH-2 | |
| Comp. | CP-1 | MA-5 | | MB-3 | MC-4 | | I-2 | CTA-2 | GBL | 80 | — | 80 |
| Example | | (12) | | (38) | (50) | | (2) | (6) | (45) | | SH-3 | |
| 1-3 | | | | | | | | | | | | |
| Comp. | CP-2 | MA-1 | | MB-2 | MC-1 | MC-2 | I-1 | CTA-1 | GBL | 80 | I-1 | 80 |
| Example | | (10) | | (40) | (35) | (15) | (2) | (6) | (40) | | — | |
| 1-4 | | | | | | | | | | | | |
| Comp. | CP-3 | MA-5 | | MB-3 | MC-4 | — | I-2 | — | GBL | 80 | — | — |
| Example | | (12) | | (38) | (50) | | (20) | | (40) | | — | |
| 1-5 | | | | | | | | | | | | |
| Comp. | CP-4 | MA-13 | — | MB-3 | MC-6 | — | I-2 | | GBL | 80 | — | — |
| Example | | (10) | | (40) | (50) | | (20) | | (40) | | — | |
| 1-6 | | | | | | | | | | | | |
| Comp. | CP-5 | MA-14 | — | MB-3 | MC-1 | — | I-2 | | GBL | 80 | — | — |
| Example | | (12) | | (35) | (53) | | (20) | | (40) | | — | |
| 1-7 | | | | | | | | | | | | |

TABLE 2

| | | Step RM-1 | | | | | Step RM-2 | | | | |
|---|---|---|---|---|---|---|---|---|---|---|---|
| | | Amount of residual monomer (wt %) | | | | | Amount of residual monomer (wt %) | | | | |
| | Polymer | A1 | A2 | B | C1 | C2 | A1 | A2 | B | C1 | C2 |
| Example | P-1 | MA-1 | — | MB-2 | MC-1 | MC-2 | MA-1 | — | MB-2 | MC-1 | MC-2 |
| 1-1 | | (0.85) | | (0.46) | (1.05) | (0.9) | (0.03) | | (<0.01) | (0.04) | (0.02) |
| Example | P-2 | MA-2 | — | MB-1 | MC-1 | — | MA-2 | — | MB-1 | MC-1 | — |
| 1-2 | | (0.95) | | (0.40) | (1.0) | | (0.04) | | (<0.01) | (0.03) | |
| Example | P-3 | MA-5 | — | MB-3 | MC-4 | — | MA-5 | — | MB-3 | MC-4 | — |
| 1-3 | | (0.98) | | (0.30) | (1.05) | | (0.01) | | (<0.01) | (0.01) | |
| Example | P-4 | MA-3 | MA-4 | MB-4 | MC-3 | — | MA-3 | MA-4 | MB-4 | MC-3 | — |
| 1-4 | | (0.80) | (0.45) | (0.35) | (1.0) | | (0.03) | (0.01) | (<0.01) | (0.03) | |
| Example | P-5 | MA-6 | — | MB-5 | MC-5 | MC-7 | MA-6 | — | MB-5 | MC-5 | MC-7 |
| 1-5 | | (0.80) | | (0.34) | (0.95) | (0.86) | (0.02) | | (0.01) | (0.03) | (0.02) |
| Example | P-6 | MA-5 | — | MB-3 | MC-6 | — | MA-5 | — | MB-3 | MC-6 | — |
| 1-6 | | (0.88) | | (0.25) | (1.0) | | (0.03) | | (0.01) | (0.06) | |
| Example | P-7 | MA-7 | MA-9 | MB-6 | MC-2 | — | MA-7 | MA-9 | MB-6 | MC-2 | — |
| 1-7 | | (0.90) | (0.40) | (0.20) | (0.85) | | (0.04) | (0.02) | (0.01) | (0.02) | |
| Example | P-8 | MA-8 | MA-10 | MB-2 | MC-1 | — | MA-8 | MA-10 | MB-2 | MC-1 | — |
| 1-8 | | (0.90) | (0.37) | (0.22) | (0.90) | | (0.03) | (0.02) | (<0.01) | (0.01) | |
| Example | P-9 | MA-2 | MA-11 | MB-7 | MC-1 | — | MA-2 | MA-11 | MB-7 | MC-1 | — |
| 1-9 | | (0.88) | (0.40) | (0.22) | (0.80) | | (0.01) | (0.01) | (<0.01) | (0.01) | |
| Example | P-10 | MA-2 | MA-12 | MB-6 | MC-1 | — | MA-2 | MA-12 | MB-6 | MC-1 | — |
| 1-10 | | (0.90) | (0.45) | (0.24) | (0.80) | | (0.01) | (0.01) | (<0.01) | (0.01) | |
| Example | P-11 | MA-13 | — | MB-3 | MC-6 | — | MA-13 | — | MB-3 | MC-6 | — |
| 1-11 | | (0.83) | | (0.24) | (1.10) | | (0.01) | | (0.01) | (0.02) | |
| Example | P-12 | MA-14 | — | MB-3 | MC-1 | — | MA-14 | — | MB-3 | MC-1 | — |
| 1-12 | | (0.92) | | (0.22) | (1.00) | | (0.01) | | (0.01) | (0.02) | |
| Comp. | CP-1 | MA-5 | — | MB-3 | MC-4 | — | MA-5 | — | MB-3 | MC-4 | — |
| Example | | (1.90) | | (0.78) | (1.28) | | (1.52) | | (0.26) | (0.78) | |
| 1-3 | | | | | | | | | | | |
| Comp. | CP-2 | MA-1 | — | MB-2 | MC-1 | MC-2 | MA-1 | — | MB-2 | MC-1 | MC-2 |
| Example | | (1.20) | | (0.78) | (1.25) | (1.0) | (0.03) | | (<0.01) | (0.04) | (0.02) |
| 1-4 | | | | | | | | | | | |
| Comp. | CP-3 | MA-5 | — | MB-3 | MC-4 | — | — | — | — | — | — |
| Example | | (1.20) | | (0.37) | (0.78) | | | | | | |
| 1-5 | | | | | | | | | | | |
| Comp. | CP-4 | MA-13 | — | MB-3 | MC-6 | — | — | — | — | — | — |
| Example | | (2.12) | | (0.39) | (0.94) | | | | | | |
| 1-6 | | | | | | | | | | | |
| Comp. | CP-5 | MA-14 | — | MB-3 | MC-1 | — | — | — | — | — | — |
| Example | | (1.83) | | (0.38) | (0.80) | | | | | | |
| 1-7 | | | | | | | | | | | |

| | End | | | | | | |
|---|---|---|---|---|---|---|---|
| | conversion | Mw/Mn | Amount of residual monomer | | | | |
| | rate | after | after purification (wt %) | | | | |
| | (%) | purifycation | A1 | A2 | B | C1 | C2 |
| Example | 100 | 9,500 | MA-1 | — | MB-2 | MC-1 | MC-2 |
| 1-1 | | 1.32 | (0.01) | | (<0.01) | (<0.01) | (<0.01) |
| Example | 100 | 10,000 | MA-2 | — | MB-1 | MC-1 | — |
| 1-2 | | 1.31 | (0.01) | | (<0.01) | (<0.01) | |
| Example | 100 | 10,500 | MA-5 | — | MB-3 | MC-4 | — |
| 1-3 | | 1.28 | (<0.01) | | (<0.01) | (<0.01) | |
| Example | 100 | 12,000 | MA-3 | MA-4 | MB-4 | MC-3 | — |
| 1-4 | | 1.30 | (<0.01) | (<0.01) | (<0.01) | (0.01) | |
| Example | 100 | 10,500 | MA-6 | — | MB-5 | MC-5 | MC-7 |
| 1-5 | | 1.33 | (0.01) | | (<0.01) | (<0.01) | (0.01) |
| Example | 100 | 9,800 | MA-5 | — | MB-3 | MC-6 | — |
| 1-6 | | 1.27 | (<0.01) | | (<0.01) | (<0.01) | |
| Example | 100 | 9,900 | MA-7 | MA-9 | MB-6 | MC-2 | — |
| 1-7 | | 1.34 | (<0.01) | (<0.01) | (<0.01) | (<0.01) | |
| Example | 100 | 10,000 | MA-8 | MA-10 | MB-2 | MC-1 | — |
| 1-8 | | 1.32 | (<0.01) | (<0.01) | (<0.01) | (<0.01) | |
| Example | 100 | 9,900 | MA-2 | MA-11 | MB-7 | MC-1 | — |
| 1-9 | | 1.35 | (<0.01) | (<0.01) | (<0.01) | (<0.01) | |
| Example | 100 | 9,800 | MA-2 | MA-12 | MB-6 | MC-1 | — |
| 1-10 | | 1.34 | (<0.01) | (<0.01) | (<0.01) | (<0.01) | |
| Example | 100 | 9,800 | MA-13 | — | MB-3 | MC-6 | — |
| 1-11 | | 1.22 | (<0.01) | | (<0.01) | (<0.01) | |
| Example | 100 | 9,700 | MA-14 | — | MB-3 | MC-1 | — |
| 1-12 | | 1.25 | (<0.01) | | (<0.01) | (<0.01) | |
| Comp. | 72 | 9,500 | MA-5 | — | MB-3 | MC-4 | — |
| Example | | 1.52 | (1.3) | | (0.10) | (0.48) | |
| 1-3 | | | | | | | |
| Comp. | 90 | 9,300 | MA-1 | — | MB-2 | MC-1 | MC-2 |
| Example | | 1.38 | (0.01) | | (<0.01) | (<0.01) | (<0.01) |
| 1-4 | | | | | | | |
| Comp. | — | 10,000 | MA-5 | — | MB-3 | MC-4 | — |
| Example | | 1.64 | (0.96) | | (0.18) | (0.24) | |
| 1-5 | | | | | | | |
| Comp. | — | 9,800 | MA-13 | — | MB-3 | MC-6 | — |
| Example | | 1.53 | (0.68) | | (0.11) | (0.10) | |
| 1-6 | | | | | | | |
| Comp. | — | 9,700 | MA-14 | — | MB-3 | MC-1 | — |
| Example | | 1.49 | (0.62) | | (0.09) | (0.09) | |
| 1-7 | | | | | | | |

### [2] Preparation of Polymer Solution

### Example 2-1

Polymer P-3 in wet powder form was prepared by performing the preparation procedure according to the method of Example 1-3, adding dropwise the polymerization solution to diisopropyl ether, and filtering the precipitated solids. The wet powder was placed in a flask, PGME was added to the flask to dissolve the powder, and the solution was concentrated in vacuum at 40° C. to remove diisopropyl ether. After concentration, the amount of PGME was quantitatively determined by gas chromatography. A suitable amount of PGMEA was added, obtaining a PGME/PGMEA solution of Polymer P-3 (polymer concentration 10 wt %, PGME:PGMEA=70:30 in weight ratio). The solution was passed through a conduit having a nylon filter with a pore size of 5 nm and a polyethylene filter with a pore size of 1 nm arranged therein, obtaining the filtered solution.

### Comparative Example 2-1

Polymer CP-2 in wet powder form was prepared by performing the preparation procedure according to the method of Comparative Example 1-4, adding dropwise the polymerization solution to diisopropyl ether, and filtering the precipitated solids. The wet powder was placed in a flask, PGME was added to the flask to dissolve the powder, and the solution was concentrated in vacuum at 40° C. to remove diisopropyl ether. After concentration, the amount of PGME was quantitatively determined by gas chromatography. A suitable amount of PGMEA was added, obtaining a PGME/PGMEA solution of Polymer CP-2 (polymer concentration 10 wt %, PGME:PGMEA=70:30 in weight ratio). The solution was passed through a conduit having a nylon filter with a pore size of 5 nm and a polyethylene filter with a pore size of 1 nm arranged therein, obtaining the filtered solution.

### Examples 2-2 to 2-6 and Comparative Examples 2-2 to 2-4

Polymer solutions were prepared according to the procedure of the foregoing examples except that the polymer and solvent were changed. Table 3 tabulates the composition of the polymer solutions.

### [Measurement of Concentration of Particles in Polymer Solution]

The concentration (count/mL) of particles with a particle size of 0.15 m or more in the polymer solution was compared. The analyzer was particle counter KS-41A (Rion Co., Ltd.). A smaller count indicates that the polymer solution contains a smaller number of particles and has a higher cleanness. The results are also shown in Table 3.

TABLE 3

| | | | | | | Concentration |
|---|---|---|---|---|---|---|
| | Polymer | | | | Polymer | of ≥0.15 μm |
| | preparation | | Solvent A | Solvent B | concentration | particles |
| | method | Polymer | (wt %) | (wt %) | (wt %) | (count/mL) |
| Example | Example | P-3 | PGME | PGMEA | 10 | 5 |
| 2-1 | 1-3 | | (70) | (30) | | |
| Example | Example | P-3 | EL | PGMEA | 10 | 7 |
| 2-2 | 1-3 | | (60) | (40) | | |
| Example | Example | P-3 | DAA | PGMEA | 12 | 8 |
| 2-3 | 1-3 | | (45) | (55) | | |
| Example | Example | P-1 | PGME | PGMEA | 10 | 9 |
| 2-4 | 1-1 | | (70) | (30) | | |
| Example | Example | P-11 | EL | PGMEA | 10 | 6 |
| 2-5 | 1-11 | | (60) | (40) | | |
| Example | Example | P-12 | EL | PGMEA | 10 | 5 |
| 2-6 | 1-12 | | (60) | (40) | | |
| Comparative | Comparative | CP-2 | PGME | PGMEA | 10 | 27 |
| Example | Example | | (70) | (30) | | |
| 2-1 | 1-4 | | | | | |
| Comparative | Comparative | CP-3 | EL | PGMEA | 10 | 30 |
| Example | Example | | (60) | (40) | | |
| 2-2 | 1-5 | | | | | |
| Comparative | Comparative | CP-1 | DAA | PGMEA | 12 | 28 |
| Example | Example | | (45) | (55) | | |
| 2-3 | 1-3 | | | | | |
| Comparative | Comparative | CP-2 | PGME | PGMEA | 10 | 26 |
| Example | Example | | (70) | (30) | | |
| 2-4 | 1-24 | | | | | |

It is evident from the results in Tables 1 and 2 that according to the preparation method of the invention, there are obtained polymers having minimal contents of residual monomers and a narrow dispersity, from which end groups originating from the RAFT agent have been completely removed. The polymer preparation method of the invention is an effective method for preparing a polymer which overcomes the outstanding problems of the prior art living radical polymerization methods, that is, achieves both complete removal of end groups and substantial reduction of acid-generating monomer. It is evident from the results in Table 3 that the polymer solutions obtained from the inventive method have a low concentration or count of particles, indicating a uniform clean solution. The polymers obtained from the inventive method are expected useful as a base polymer for resist compositions or as a resist material with a less risk of defectiveness.

### [3] Evaluation of Stability with Time of Polymer Solution

Two bottles of brown glass were filled with each of the polymer solutions of Examples 2-3 and 2-4 and Comparative Examples 2-3 and 2-4. The bottles were stored for 2 weeks, with one in an environment at 5° C. and the other at 40° C. After the storage, the polymer solutions were allowed to stand in an environment at 23° C. for 8 hours. Using a coater/developer Clean Track Lithius Pro Z (Tokyo Electron Limited), the polymer solution was coated onto a 12-inch silicon wafer substrate and baked on a hotplate at 130° C. for 60 seconds to form a polymer film. The film was measured for thickness using a spectroscopic film thickness measurement system VM-3500 (Screen Semiconductor Solutions Co., Ltd.). On Clean Track Lithius Pro Z, the wafer after film thickness measurement was developed in a 2.38 wt % aqueous solution of tetramethylammonium hydroxide for a total time of 30 seconds while spinning. The alkaline developer was washed away with water and the wafer was rotated at a high speed to spin off water. The polymer film after development was measured for thickness. The difference of film thickness before and after development treatment was determined. The results are shown in Table 4.

TABLE 4

| | | | | Film | Film | |
|---|---|---|---|---|---|---|
| | | | | thick- | thick- | Film |
| | | | | ness | ness | thick- |
| | | | | after | after | ness |
| | | Storage | | coating | development | difference |
| | Polymer | temperature | | (Å) | (Å) | (Å) |
| Example | P-3 | 5° | C. | 3,282 | 3,267 | 15 |
| 2-3 | | 30° | C. | 3,281 | 3,265 | 16 |
| Example | P-1 | 5° | C. | 3,164 | 3,147 | 17 |
| 2-4 | | 30° | C. | 3,163 | 3,147 | 16 |
| Comparative | CP-1 | 5° | C. | 3,278 | 3,262 | 16 |
| Example | | 30° | C. | 3,271 | 3,193 | 78 |
| 2-3 | | | | | | |
| Comparative | CP-2 | 5° | C. | 3,166 | 3,150 | 16 |
| Example | | 30° | C. | 3,163 | 3,128 | 35 |
| 2-4 | | | | | | |

The polymers of Examples having a high end conversion rate kept the film thickness difference before and after development unchanged even when the storage temperature was 40° C. The polymers of Comparative Examples having a low end conversion rate experienced a substantial difference of film thickness before and after development when the storage temperature was 40° C. In the polymer solution during 40° C. storage, the dissociation of functional groups (originating from the RAFT agent) from the polymer end takes place along with decomposition thereof. Then an organic acid component is created in the polymer solution, which causes decomposition of acid labile groups on the polymer to promote the solubility of the polymer in the alkaline developer. It is seen from the results of Table 4 that the polymers with a high end conversion rate are superior in stability with time.

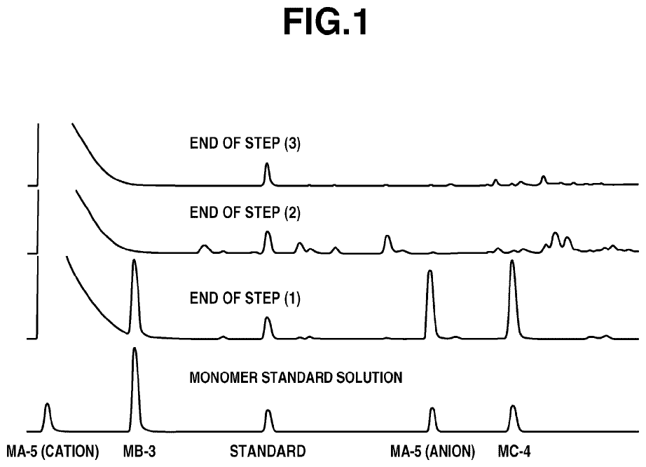

FIG. 1 illustrates the results of HPLC analysis on the polymer of Example 1-3 at the end of each step. In FIG. 1, the bottom stage shows the chromatogram obtained by analysis on HPLC (column: ODS, mobile phase:water/acetonitrile 80:20→1:99, detector UV 220 nm) using a standard sample (obtained by mixing 0.20 g of monomer MA-5, 0.20 g of monomer MB-4, 0.10 g of monomer MC-3 and 0.20 g of 3-hydroxy-1-adamantyl methacrylate as internal standard), and computing the ratio of detection sensitivity of monomers. The second stage from the bottom shows the chromatogram obtained by HPLC analysis on the polymerization solution at the end of reaction of step (1) in the polymer preparation method, after adding thereto the internal standard in an amount corresponding to 200 ppm based on the total weight of all monomers charged. The second stage from the top shows the chromatogram obtained by HPLC analysis on the polymerization solution at the end of reaction of step (2) in the polymer preparation method, after adding thereto the internal standard in an amount corresponding to 200 ppm based on the total weight of all monomers charged. The top stage shows the chromatogram obtained by HPLC analysis on the powder sample of the polymer of step (3) in the polymer preparation method as purified by crystallization, after adding thereto the internal standard in an amount corresponding to 200 ppm based on the powder.

### [4] Preparation of Resist Composition

### Examples 4-1 and 4-2 and Comparative Examples 4-1 and 4-2

A chemically amplified positive resist composition was prepared by dissolving selected components in an organic solvent according to the formulation shown in Table 5, and passing the solution through a nylon filter with a pore size of 5 nm and then a UPE filter with a pore size of 1 nm. The organic solvent was a mixture of 1,639 parts by weight of PGMEA, 2,166 parts by weight of ethyl lactate, and 445 parts by weight of diacetone alcohol.

TABLE 5

| | Resist | Polymer | Quencher |
|---|---|---|---|
| | composition | (pbw) | (pbw) |
| Example 4-1 | R-1 | P-11 (80) | Q-1 (12.5) |
| Example 4-1 | R-2 | P-12 (80) | Q-2 (12.5) |
| Comparative | CR-1 | CP-4 (80) | Q-1 (12.5) |
| Example 4-1 | | | |
| Comparative | CR-2 | CP-5 (80) | Q-2 (12.5) |
| Example 4-2 | | | |

Quenchers Q-1 and Q-2 in Table 4 are identified below.

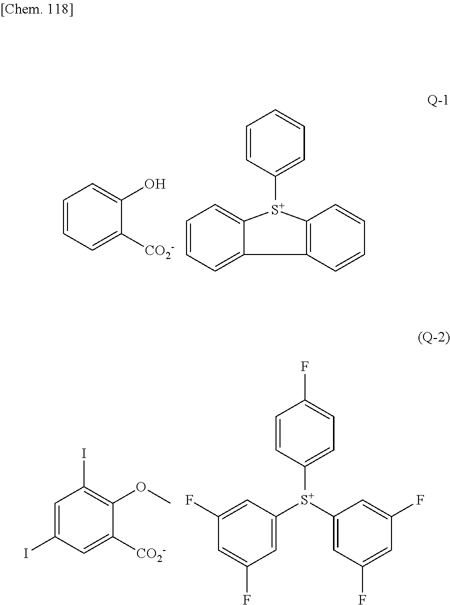

### [5] EUV Lithography Test

### Examples 5-1 and 5-2 and Comparative Examples 5-1 and 5-2

Each of the resist compositions (R-1, R-2, CR-1 and CR-2) was spin coated on a silicon substrate having a 20-nm coating of silicon-containing spin-on hard mask SHB-A940 (Shin-Etsu Chemical Co., Ltd., silicon content 43 wt %) and prebaked on a hotplate at 130° C. for 60 seconds to form a resist film of 50 nm thick. Using an EUV scanner NXE3300 (ASML, NA 0.33, σ 0.9/0.6, dipole illumination), the resist film was exposed to EUV of wavelength 13.5 nm through a mask bearing a line-and-space (LS) pattern having a width of 18 nm and a pitch of 36 nm (on-wafer size) while changing the dose at a pitch of 1 mJ/cm² and the focus at a pitch of 0.020 μm. The resist film was post-exposure baked (PEB) at 95° C. for 60 seconds. This was followed by puddle development in a 2.38 wt % TMAH aqueous solution for 30 seconds, rinsing with ultrapure water, and spin drying. A positive LS pattern was obtained.

The LS pattern as developed was observed under CD-SEM (CG6300, Hitachi High-Technologies Corp.). The optimum dose Eop (mJ/cm²) which provided an LS pattern with a line width of 18 nm and a pitch of 36 nm was determined and reported as sensitivity. A 3-fold value (3σ) of the standard deviation (σ) computed from the measurement of LS pattern size was reported as the roughness of line width (LWR, nm). The results are shown in Table 6.

TABLE 6

| | Resist | Eop | LWR |
|---|---|---|---|
| | composition | (mJ/cm²) | (nm) |
| Example 5-1 | R-1 | 17.7 | 3.05 |
| Example 5-2 | R-2 | 16.5 | 3.02 |
| Comparative | CR-1 | 18.1 | 4.52 |
| Example 5-1 | | | |
| Comparative | CR-2 | 17.2 | 4.61 |
| Example 5-2 | | | |

It is demonstrated from the results in Table 6 that the resist compositions within the scope of the invention show reduced edge roughness and are best suited for the EUV lithography.

1. A method for preparing a polymer comprising repeat units (A) derived from a monomer (A) structured so as to generate an acid upon light exposure, represented by any one of the formulae (A1) to (A6), repeat units (B) derived from a monomer (B) having a phenolic hydroxy group, represented by the formula (B1), and repeat units (C) derived from a monomer (C) which is decomposed under the action of acid, the method comprising the steps of:
(1) polymerizing starting monomers including monomer (A), monomer (B) and monomer (C) in a solution through living radical polymerization using a radical initiator and a reversible addition-fragmentation chain transfer agent (RAFT agent), to form a polymer P-1 having an end structure selected from structures having the formulae (X-1) and (X-2) derived from the RAFT agent at the end of the backbone,
(2) adding a radical generator and a thiol compound to the solution containing polymer P-1, and heating the solution to remove the end structure from the backbone of polymer P-1 to form a polymer P, and
(3) mixing the solution containing polymer P with a poor solvent and allowing polymer P to precipitate as solids for purification, 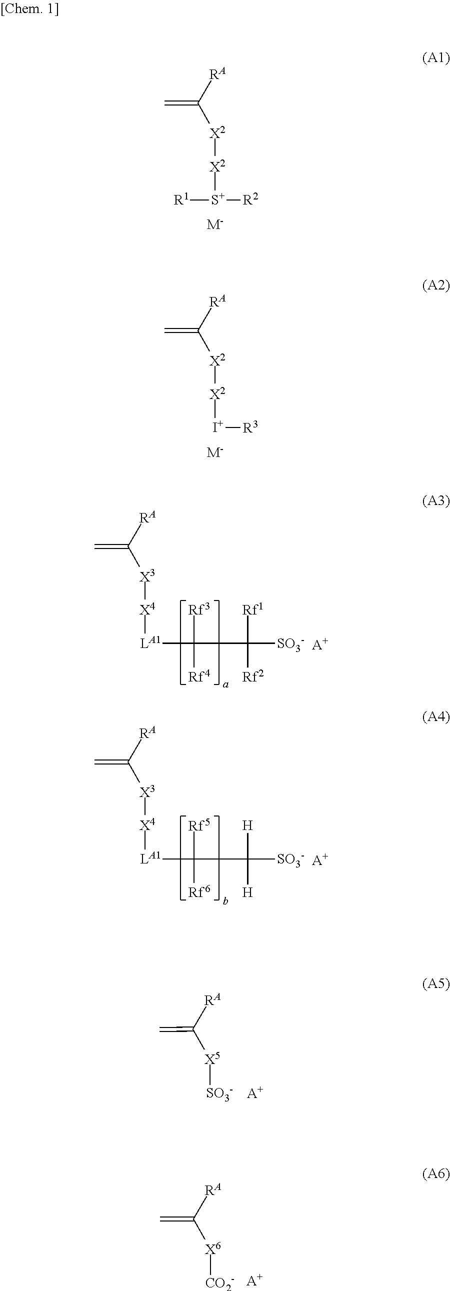
wherein R^{A} is each independently hydrogen, fluorine, methyl or trifluoromethyl,
R¹, R² and R³ are each independently a C₁-C₂₀ hydrocarbyl group which may contain a heteroatom, R¹ and R² may bond together to form a ring with the sulfur atom to which they are attached,
X¹ is each independently a single bond or phenylene group,
X² is each independently *—C(═O)—O—X²¹—, *—C(═O)—NH—X²¹— or *—O—X²¹—, X²¹ is a C₁-C₆ aliphatic hydrocarbyl group, phenylene or a divalent group obtained by combining the foregoing, which may contain at least one moiety selected from carbonyl, ester bond, ether bond and hydroxy,
X³ is each independently a single bond, a phenylene group which may be substituted with at least one moiety selected from halogen and a hydrocarbylcarbonyloxy moiety which may contain a heteroatom, a naphthylene group which may be substituted with at least one moiety selected from halogen and a hydrocarbylcarbonyloxy moiety which may contain a heteroatom, or *—C(═O)—O—X³¹—, X³¹ is a C₁-C₂₀ aliphatic hydrocarbylene group which may contain at least one moiety selected from hydroxy, ether bond, ester bond and lactone ring, an optionally halogenated phenylene group, or an optionally halogenated naphthylene group,
X⁴ is each independently a single bond, —X⁴¹—C(═O)—O—, or —O—X⁴¹—O—C(═O)—, X⁴¹ is a C₁-C₂₀ aliphatic hydrocarbylene group which may contain a heteroatom, optionally halogenated phenylene group or optionally halogenated naphthylene group,
X⁵ is a single bond, methylene group, ethylene group, optionally halogenated phenylene group, optionally halogenated naphthylene group, *—C(═O)—O—X⁵¹—, *—C(═O)—N(H)—X⁵¹— or *—O—X⁵¹—, X⁵¹ is a C₁-C₂₀ aliphatic hydrocarbylene group which may contain at least one moiety selected from carbonyl, ester bond, ether bond and hydroxy, optionally halogenated phenylene group or optionally halogenated naphthylene group, * designates a point of attachment to the carbon atom in the backbone,
X⁶ is a single bond, methylene group, ethylene group, a phenylene group which may be substituted with at least one moiety selected from halogen and hydrocarbylcarbonyloxy moiety which may contain a heteroatom, a naphthylene group which may be substituted with at least one moiety selected from halogen and hydrocarbylcarbonyloxy moiety which may contain a heteroatom, *—C(═O)—O—X⁶¹—, *—C(═O)—N(H)—X⁶¹— or *—O—X⁶¹—, X⁶¹ is a C₁-C₂₀ aliphatic hydrocarbylene group which may contain at least one moiety selected from carbonyl, ester bond, ether bond and hydroxy, optionally halogenated phenylene group or optionally halogenated naphthylene group, * designates a point of attachment to the carbon atom in the backbone,
L^{A1} is each independently a single bond, ether bond, ester bond, carbonyl group, sulfonate ester bond, carbonate bond or carbamate bond,
Rf¹ and Rf² are each independently fluorine or a C₁-C₆ fluorinated alkyl group, Rf³ and Rf⁴ are each independently hydrogen, fluorine or a C₁-C₆ fluorinated alkyl group,
Rf⁵ and Rf⁶ are each independently hydrogen, fluorine or a C₁-C₆ fluorinated alkyl group, excluding that all Rf⁵ and Rf⁶ are hydrogen at the same time,
M⁻ is each independently a non-nucleophilic counter ion,
A⁺ is each independently an onium cation, and
a and b are each independently 0, 1, 2 or 3. 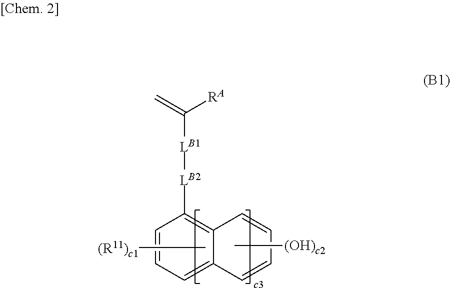
wherein R^{A} is hydrogen, fluorine, methyl or trifluoromethyl,
R¹¹ is halogen or a C₁-C₆ saturated hydrocarbyl group which may contain at least one moiety selected from ether bond and carbonyl,
L^{B1} is a single bond, cabonyloxy group or amide group,
L^{B2} is a single bond or a C₁-C₇ alkanediyl group which may contain at least one moiety selected from ether bond and carbonyl,
c1 is an integer meeting 0≤c1≤5+2(c3)−c2,
c2 is 1, 2, 3, 4 or 5,
c3 is 0, 1 or 2, 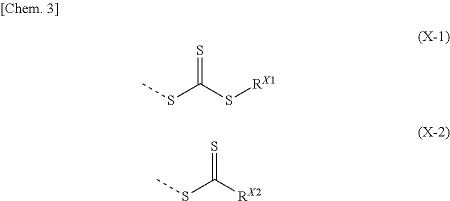
wherein R^{X1} and R^{X2} are each independently a C₂-C₂₀ saturated hydrocarbyl group which may contain a heteroatom, C₇-C₂₀ aralkyl group, or C₆-C₂₀ aryl group, the broken line designates a point of attachment to the carbon atom in the backbone.

2. The method of claim 1 wherein the amounts of monomer (A), monomer (B), and monomer (C) remaining in the polymer P-1 solution resulting from step (1) are less than 2% by weight, less than 1% by weight, and less than 2% by weight based on the total weight of the monomers charged, respectively.

3. The method of claim 1 wherein the thiol compound used in step (2) is a compound having the formula (SH-1) or (SH-2): 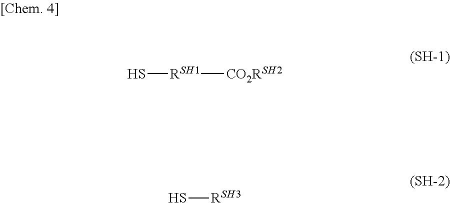
wherein R^{SH1} is a C₁-C₃ hydrocarbylene group,
R^{SH2} is a C₄-C₈ aliphatic hydrocarbyl group which may contain a heteroatom, C₇-C₁₈ aralkyl group or C₆-C₁₈ aryl group, and
R^{SH3} is a C₆-C₂₀ saturated hydrocarbyl group which may contain a heteroatom, C₇-C₁₈ aralkyl group or C₆-C₁₈ aryl group.

4. The method of claim 1 wherein the amounts of monomer (A), monomer (B), and monomer (C) remaining in the polymer P-1 solution resulting from step (2) are less than 0.05% by weight, less than 0.01% by weight, and less than 0.05% by weight based on the total weight of the monomers charged.

5. The method of claim 1 wherein the molar fractions of the structure having formula (X-1) and the structure having formula (X-2) in the polymer are each less than 1%.

6. The method of claim 1 wherein in step (1), the living radical polymerization is carried out by mixing monomer (A), monomer (B), monomer (C), the radical initiator, and the RAFT agent into a single solution, and then heating the solution.

7. The method of claim 1 wherein in step (1), the living radical polymerization is carried out by preparing monomer (A), monomer (B), monomer (C), and the radical initiator into a single solution or independent solutions, and then adding the solution or solutions to a preheated solution of the RAFT agent.

8. The method of claim 1 wherein in step (1), the amount of the radical initiator charged is 0.5 to 5 moles and the amount of the RAFT agent charged is 0.5 to 20 moles per 100 moles of all the monomers charged.

9. A method for preparing a polymer solution comprising the steps of dissolving the polymer obtained from the method of claim 1 in a solvent containing at least propylene glycol monomethyl ether acetate and filtrating the solution through a filter.

10. A method for preparing a chemically amplified resist composition comprising the step of dissolving in an organic solvent a raw material comprising a base polymer containing the polymer obtained from the method of claim 1.

11. The method of claim 10 wherein the raw material further contains a quencher of onium salt type.

12. A pattern forming process comprising the steps of applying the chemically amplified resist composition obtained from the method of claim 10 onto a substrate to form a resist film thereon, exposing the resist film to high-energy radiation, and developing the exposed resist film in a developer.

13. The pattern forming process of claim 12 wherein the high-energy radiation is EUV of wavelength 3 to 15 nm or EB.

14. A polymer obtained from living radical polymerization using a reversible addition-fragmentation chain transfer agent (RAFT agent), wherein
said polymer comprises repeat units (A) derived from a monomer (A) structured so as to generate an acid upon light exposure, represented by any one of the formulae (A1) to (A6), repeat units (B) derived from a monomer (B) having a phenolic hydroxy group, represented by the formula (B1), and repeat units (C) derived from a monomer (C) which is decomposed under the action of acid,
at least 98% of the end structure in the polymer, selected from structures having the formulae (X-1) and (X-2) derived from the RAFT agent has been converted to hydrogen,
the amount of monomer (A) remaining in the polymer is up to 0.05% by weight, the amount of monomer (B) remaining in the polymer is up to 0.01% by weight, and the amount of monomer (C) remaining in the polymer is up to 0.05% by weight,
the polymer has a dispersity of up to 1.5, 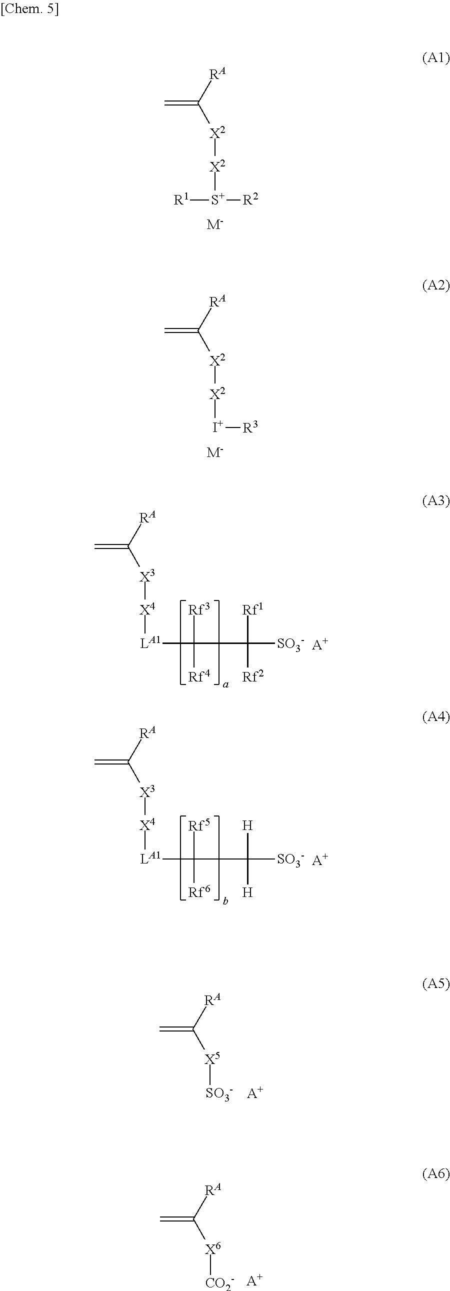
wherein R^{A} is each independently hydrogen, fluorine, methyl or trifluoromethyl,
R¹, R² and R³ are each independently a C₁-C₂₀ hydrocarbyl group which may contain a heteroatom, R¹ and R² may bond together to form a ring with the sulfur atom to which they are attached,
X¹ is each independently a single bond or phenylene group,
X² is each independently *—C(═O)—O—X²¹—, *—C(═O)—NH—X²¹— or *—O—X²¹—, X²¹ is a C₁-C₆ aliphatic hydrocarbyl group, phenylene or a divalent group obtained by combining the foregoing, which may contain at least one moiety selected from carbonyl, ester bond, ether bond and hydroxy,
X³ is each independently a single bond, a phenylene group which may be substituted with at least one moiety selected from halogen and a hydrocarbylcarbonyloxy moiety which may contain a heteroatom, a naphthylene group which may be substituted with at least one moiety selected from halogen and a hydrocarbylcarbonyloxy moiety which may contain a heteroatom, or *—C(═O)—O—X³¹—, X³¹ is a C₁-C₂₀ aliphatic hydrocarbylene group which may contain at least one moiety selected from hydroxy, ether bond, ester bond and lactone ring, an optionally halogenated phenylene group, or an optionally halogenated naphthylene group,
X⁴ is each independently a single bond, —X⁴¹—C(═O)—O—, or —O—X⁴¹—O—C(═O)—, X⁴¹ is a C₁-C₂₀ aliphatic hydrocarbylene group which may contain a heteroatom, optionally halogenated phenylene group or optionally halogenated naphthylene group,
X⁵ is a single bond, methylene group, ethylene group, optionally halogenated phenylene group, optionally halogenated naphthylene group, *—C(═O)—O—X⁵¹—, *—C(═O)—N(H)—X⁵¹— or *—O—X⁵¹—, X⁵¹ is a C₁-C₂₀ aliphatic hydrocarbylene group which may contain at least one moiety selected from carbonyl, ester bond, ether bond and hydroxy, optionally halogenated phenylene group or optionally halogenated naphthylene group, * designates a point of attachment to the carbon atom in the backbone,
X⁶ is a single bond, methylene group, ethylene group, a phenylene group which may be substituted with at least one moiety selected from halogen and hydrocarbylcarbonyloxy moiety which may contain a heteroatom, a naphthylene group which may be substituted with at least one moiety selected from halogen and hydrocarbylcarbonyloxy moiety which may contain a heteroatom, *—C(═O)—O—X⁶¹—, *C(═O)—N(H)—X⁶¹— or *—O—X⁶¹—, X⁶¹ is a C₁-C₂₀ aliphatic hydrocarbylene group which may contain at least one moiety selected from carbonyl, ester bond, ether bond and hydroxy, optionally halogenated phenylene group or optionally halogenated naphthylene group, * designates a point of attachment to the carbon atom in the backbone,
L^{A1} is each independently a single bond, ether bond, ester bond, carbonyl group, sulfonate ester bond, carbonate bond or carbamate bond,
Rf¹ and Rf² are each independently fluorine or a C₁-C₆ fluorinated alkyl group, Rf³ and Rf⁴ are each independently hydrogen, fluorine or a C₁-C₆ fluorinated alkyl group,
Rf⁵ and Rf⁶ are each independently hydrogen, fluorine or a C₁-C₆ fluorinated alkyl group, excluding that all Rf⁵ and Rf⁶ are hydrogen at the same time,
M⁻ is each independently a non-nucleophilic counter ion,
A⁺ is each independently an onium cation, and
a and b are each independently 0, 1, 2 or 3. 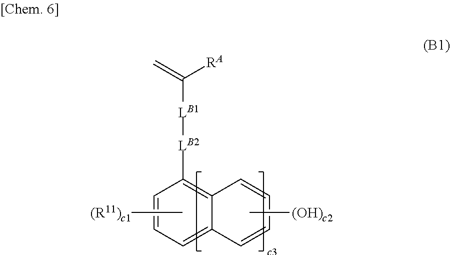
wherein R^{A} is hydrogen, fluorine, methyl or trifluoromethyl,
R¹¹ is halogen or a C₁-C₆ saturated hydrocarbyl group which may contain at least one moiety selected from ether bond and carbonyl,
L^{B1} is a single bond, cabonyloxy group or amide group,
L^{B2} is a single bond or a C₁-C₇ alkanediyl group which may contain at least one moiety selected from ether bond and carbonyl,
c1 is an integer meeting 0≤c1≤5+2(c3)−c2,
c2 is 1, 2, 3, 4 or 5,
c3 is 0, 1 or 2, 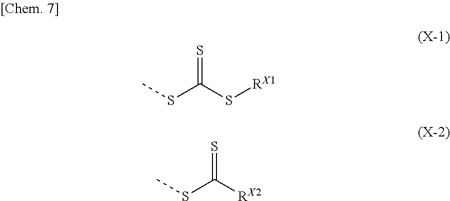
wherein R^{X1} and R^{X2} are each independently a C₂-C₂₀ saturated hydrocarbyl group which may contain a heteroatom, C₇-C₂₀ aralkyl group, or C₆-C₂₀ aryl group, the broken line designates a point of attachment to the carbon atom in the backbone.

15. A chemically amplified resist composition comprising a base polymer containing the polymer of claim 14.

16. The chemically amplified resist composition of claim 15, further comprising an onium salt type quencher.
